(19) United States
(12) Patent Application Publication
(10) Pub. No.: US 2014/0127626 A1
(43) Pub. Date: May 8, 2014

(54) RESIST COMPOSITION FOR NEGATIVE DEVELOPMENT WHICH IS USED FOR FORMATION OF GUIDE PATTERN, GUIDE PATTERN FORMATION METHOD, AND METHOD FOR FORMING PATTERN ON LAYER CONTAINING BLOCK COPOLYMER

(71) Applicants: Takahiro Senzaki, Kawasaki-shi (JP); Takahiro Dazai, Kawasaki-shi (JP); Ken Miyagi, Kawasaki-shi (JP); Shigenori Fujikawa, Fukuoka-shi (JP); Mari Koizumi, Wako-shi (JP); Harumi Hayakawa, Wako-shi (JP)

(72) Inventors: Takahiro Senzaki, Kawasaki-shi (JP); Takahiro Dazai, Kawasaki-shi (JP); Ken Miyagi, Kawasaki-shi (JP); Shigenori Fujikawa, Fukuoka-shi (JP); Mari Koizumi, Wako-shi (JP); Harumi Hayakawa, Wako-shi (JP)

(73) Assignees: RIKEN, Wako-shi (JP); TOKYO OHKA KOGYO CO., LTD., Kawasaki-shi (JP)

(21) Appl. No.: 13/877,563

(22) PCT Filed: Oct. 5, 2011
(86) PCT No.: PCT/JP2011/072986

§ 371 Date: Jan. 16, 2014

(30) Foreign Application Priority Data
Oct. 7, 2010 (JP) 2010-227858

(51) Int. Cl. G03F 7/038

(52) U.S. Cl. CPC G03F 7/038
USPC 430/281.1; 430/325

(57) ABSTRACT

A negative tone-development resist composition for forming a guide pattern, including a base component (A) and an acid generator component (B), the base component (A) including a resin component (A1) having a structural unit (a1) derived from an acrylate ester containing an acid dissociable group, and at least one of the following structural units (a2): a structural unit derived from an acrylic acid ester containing a lactone-containing cyclic group, a structural unit derived from an acrylic acid ester containing an ether-containing cyclic group and a structural unit derived from an acrylic acid ester containing a carbonate-containing cyclic group, and a constituent unit (a1) derived from an acrylic acid ester containing an acid-labile group, the acid generator component (B) including an acid generator (B1) including at least one compound represented by general formula (b1) or (b2) shown below

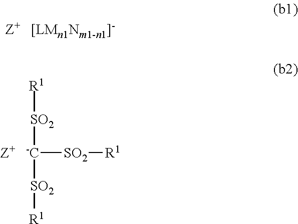

### TECHNICAL FIELD

The present invention relates to a negative tone-development resist composition for forming a guide pattern usable in phase separation of a layer containing block copolymer formed on a substrate, the block copolymer having a plurality of polymers bonded; a method of forming a guide pattern; and a method of forming a pattern of a layer containing a block copolymer.

Priority is claimed on Japanese Patent Application No. 2010-227858, filed Oct. 7, 2010, the content of which is incorporated herein by reference.

### DESCRIPTION OF RELATED ART

Recently, as further miniaturization of large scale integrated circuits (LSI) proceeds, a technology for processing a more delicate structure is demanded. In response to such demand, attempts have been started on forming a fine pattern using a phase-separated structure formed by self-assembly of polymers having mutually incompatible blocks bonded together.

For using a phase separation of a block copolymer, it is necessary to form a self-organized nano structure by a microphase separation only in specific regions, and arrange the nano structure in a desired direction. For realizing position control and orientational control, graphoepitaxy to control phase-separated pattern by a guide pattern and chemical epitaxy to control phase-separated pattern by difference in the chemical state of the substrate are proposed (see, for example, Non-Patent Document 1).

As a preferable method, there is disclosed a method in which an intermediate layer having a surface free energy of a mean value of the surface free energy of 2 block chains is formed, so as to form a plurality of guide patterns on a substrate in which the surface free energy of a side face has a surface free energy close to the surface free energy of one of the 2 block chains (for example, see Patent Document 1).

### DOCUMENTS OF RELATED ART

[Patent Document]
[Patent Document 1] Japanese Unexamined Patent Application, First Publication No. 2008-36491
[Non-Patent Documents]
[Non-Patent Document 1] Proceedings of SPIE (U.S.), vol. 7637, pp. 76370G-1 (2010)

### SUMMARY OF THE INVENTION

However, with respect to a guide pattern used in phase separation of a layer containing a block copolymer, since the block copolymer is coated after forming the guide pattern, the guide pattern is required to have an excellent solvent resistance. Further, when the block copolymer is subjected to phase separation, an anneal treatment at a high temperature is necessary; therefore, the guide pattern is required to have an excellent heat resistance. In view of the above, there was still room for improvement in the guide pattern disclosed in Patent Document 1.

The present invention takes the above circumstances into consideration, with an object of providing a negative tone-development resist composition for forming a guide pattern capable of producing a substrate provided with a nano structure on the substrate surface by using phase separation of a block copolymer, wherein the nanostructure is designed more freely with respect to the position and the orientation; a method of forming a guide pattern; and a method of forming a pattern of a layer containing a block copolymer.

For solving the above-mentioned problems, the present invention employs the following aspects.

Specifically, a first aspect of the present invention is a negative tone-development resist composition for forming a guide pattern usable in a phase separation of a layer containing a block copolymer having a plurality of polymers bonded formed on a substrate, the negative tone-development resist composition including: a base component (A) which exhibits increased polarity by action of acid and an acid-generator component (B) which generates acid upon exposure, the base component (A) containing a resin component (A1) having a structural unit (a1) derived from an acrylate ester which contains an acid dissociable group and which may have an atom or a substituent other than hydrogen bonded to the carbon atom on the α-position, and at least one structural unit (a2) selected from the group consisting of a structural unit derived from an acrylate ester which contains a 4- to 12-membered, lactone-containing cyclic group and which may have an atom or a substituent other than hydrogen bonded to the carbon atom on the α-position, a structural unit a structural unit derived from an acrylate ester which contains a 3- to 7-membered, ether-containing cyclic group and which may have an atom or a substituent other than hydrogen bonded to the carbon atom on the α-position, and a structural unit derived from an acrylate ester which contains a 5- to 7-membered, carbonate-containing cyclic group and which may have an atom or a substituent other than hydrogen bonded to the carbon atom on the α-position, and the acid generator-component (B) including an acid generator (B1) containing at least one compound represented by general formula (b1) or (b2) shown below.

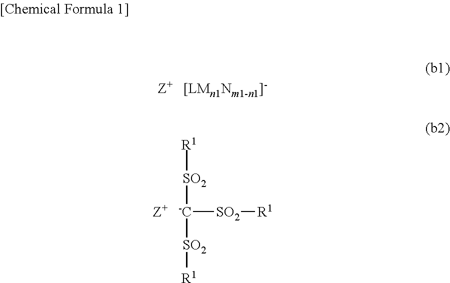

In the formulae, L represents an antimony atom, a boron atom or a phosphor atom; M and N each independently represents a fluorine atom, a pentafluorophenyl group or a perfluoroalkyl group of 1 to 5 carbon atoms; when L represents an antimony atom or a boron atom, m1 is 6, and when L represents a phosphorous atom, m1 is 4; n1 represents an integer of 0 to m1; each R¹ independently represents an alkyl group of 1 to 10 carbon atoms having at least one hydrogen atom substituted with fluorine, provided that two R¹ may be mutually bonded to form a ring; and Z⁺ represents an organic cation.

A second aspect of the present invention is a method of forming a guide pattern, including: using a negative-tone development resist composition for forming a guide pattern according to the first aspect to form a resist film on a substrate; exposing the resist film; and developing the resist film using a developing solution containing the organic solvent to form a guide pattern.

A third aspect of the present invention is a method of forming a pattern of a layer containing a block copolymer, the method including: applying an undercoat agent to a substrate to form a layer of the undercoat agent; using a negative-tone development resist composition for forming a guide pattern according to the first aspect to form a resist film on a surface of the layer of the undercoat agent; exposing the resist film; developing the resist film using a developing solution containing the organic solvent to form a guide pattern; forming a layer containing a block copolymer having a plurality of polymers bonded on a surface of the layer of the undercoat agent having the guide pattern formed thereon, followed by subjecting the layer containing the block copolymer to phase separation; and selectively removing a phase of at least one polymer of the plurality of copolymers constituting the block copolymer.

In the present description and claims, an “alkyl group” includes linear, branched or cyclic, monovalent saturated hydrocarbon, unless otherwise specified.

The term “alkylene group” includes linear, branched or cyclic divalent saturated hydrocarbon, unless otherwise specified.

A “lower alkyl group” is an alkyl group of 1 to 5 carbon atoms.

A “halogenated alkyl group” is a group in which part or all of the hydrogen atoms of an alkyl group is substituted with a halogen atom. Examples of the halogen atom include a fluorine atom, a chlorine atom, a bromine atom and an iodine atom.

The term “aliphatic” is a relative concept used in relation to the term “aromatic”, and defines a group or compound that has no aromaticity.

The term “structural unit” refers to a monomer unit that contributes to the formation of a polymeric compound (polymer, copolymer).

The term “exposure” is used as a general concept that includes irradiation with any form of radiation.

The term “(meth)acrylic acid” is a generic term that includes either or both of acrylic acid having a hydrogen atom bonded to the α-position and methacrylic acid having a methyl group bonded to the α-position.

The term “(meth)acrylate ester” is a generic term that includes either or both of the acrylate ester having a hydrogen atom bonded to the α-position and the methacrylate ester having a methyl group bonded to the α-position.

The term “(meth)acrylate” is a generic term that includes either or both of the acrylate having a hydrogen atom bonded to the α-position and the methacrylate having a methyl group bonded to the α-position.

According to the present invention, there can be produced a substrate provided with a nano structure on the substrate surface by using phase separation of a block copolymer, wherein the nanostructure is designed more freely with respect to the position and the orientation.

### BRIEF DESCRIPTION OF THE DRAWINGS

FIG. 1 is a diagram showing each step of the method of forming a pattern of a layer containing a block copolymer according to the present embodiment.

### DETAILED DESCRIPTION OF THE INVENTION

<Method of Forming Layer Containing Block Copolymer>

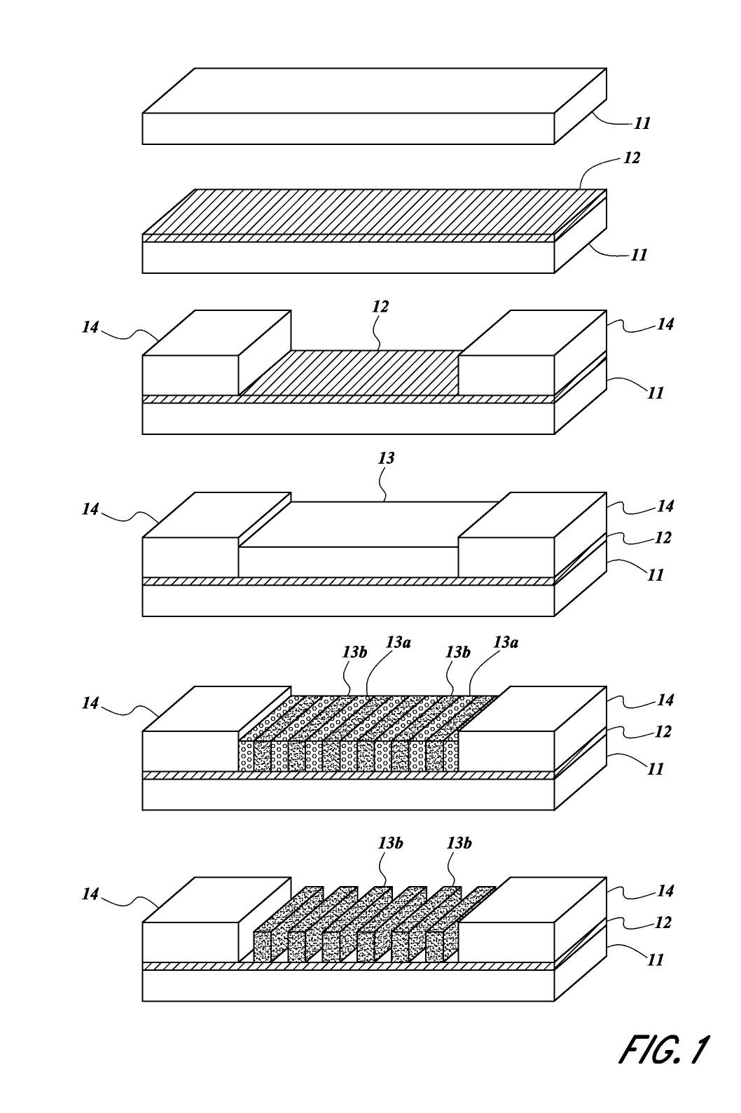

As shown in FIG. 1, the method of forming a pattern of a layer containing a block copolymer according to the present invention includes: applying an undercoat agent to a substrate 11 to form a layer 12 of the undercoat agent; using a negative-tone development resist composition for forming a guide pattern according to the first aspect to form a resist film on a surface of the layer 12 of the undercoat agent; exposing the resist film; developing the resist film using a developing solution containing the organic solvent to form a guide pattern 14; forming a layer 13 containing a block copolymer having a plurality of polymers bonded on a surface of the layer 12 of the undercoat agent having the guide pattern formed thereon, followed by subjecting the layer 13 containing the block copolymer to phase separation; and selectively removing a phase 13a of at least one polymer of the plurality of copolymers constituting the block copolymer.

Therefore, the position and the orientation of the metal nanostructure on the surface of the substrate are determined by the position and the orientation of the phase selectively removed from the phase-separated structure of the layer containing the block copolymer. In other words, by appropriately adjusting the position and orientation of the phase-separated structure to be formed on the surface of the substrate, a nanostructure having the desired position and orientation can be formed on the surface of the substrate. In particular, by using a phase-separated structure capable of forming a finer pattern than conventional resist patterns as a template, it becomes possible to form a substrate provided with a nanostructure having an extremely minute shape.

Hereafter, each of the steps and the materials used will be explained in detail.

<Block Copolymer>

A block copolymer is a polymeric material in which plurality of polymers are bonded. As the polymers constituting the block copolymer, 2 types of polymers may be used, or 3 or more types of polymers may be used.

In the present invention, the plurality of polymers constituting the block copolymer are not particularly limited, as long as they are combinations capable of causing phase separation. However, it is preferable to use a combination of polymers which are mutually incompatible. Further, it is preferable to use a combination in which a phase of at least one polymer amongst the plurality of polymers constituting the block copolymer can be easily subjected to selective removal as compared to the phases of other polymers.

Examples of the block copolymer include a block copolymer having a polymer with a structural unit of styrene or a derivative thereof bonded to a polymer with a structural unit of a (meth)acrylate ester, a block copolymer having a polymer with a structural unit of styrene or a derivative thereof bonded to a polymer with a structural unit of a siloxane or a derivative thereof, and a block copolymer having a polymer with a structural unit of an alkylene oxide bonded to a polymer with a structural unit of a (meth)acrylate ester. Here, the term “(meth)acrylate ester” is a generic term that includes either or both of the acrylate ester having a hydrogen atom bonded to the α-position and the methacrylate ester having a methyl group bonded to the α-position.

As the (meth)acrylate ester, for example, (meth)acrylic acid having a substituent such as an alkyl group or a hydroxyalkyl group bonded to the carbon atom of the (meth)acrylic acid can be used. Examples of the alkyl group as the substituent include linear, branched or cyclic alkyl groups of 1 to 10 carbon atoms. Specific examples of the (meth)acrylate ester include methyl (meth)acrylate, ethyl (meth)acrylate, propyl (meth)acrylate, cyclohexyl (meth)acrylate, octyl (meth)acrylate, nonyl (meth)acrylate, hydroxyethyl (meth)acrylate, hydroxypropyl (meth)acrylate, benzyl (meth)acrylate, anthracene (meth)acrylate, glycidyl (meth)acrylate, 3,4-epoxycyclohexylmethane (meth)acrylate, and propyltrimethoxysilane (meth)acrylate.

Examples of the styrene derivative include α-methylstyrene, 2-methylstyrene, 3-methylstyrene, 4-methylstyrene, 4-t-butylstyrene, 4-n-octylstyrene, 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, vinylcyclohexane, 4-vinylbenzylchloride, 1-vinylnaphthalene, 4-vinylbiphenyl, 1-vinyl-2-pyrolidone, 9-vinylanthracene, and vinylpyridine.

Examples of the siloxane derivative include dimethylsiloxane, diethylsiloxane, diphenylsiloxane, and methylphenylsiloxane.

Examples of the alkylene oxide include ethylene oxide, propylene oxide, isopropylene oxide and butylene oxide.

In the present invention, it is preferable to use a block copolymer having a polymer with a structural unit of styrene or a derivative thereof bonded to a polymer with a structural unit of a (meth)acrylate ester. Specific examples thereof include a styrene-polymethyl methacrylate (PS-PMMA) block copolymer, a styrene-polyethyl methacrylate block copolymer, a styrene-(poly-t-butyl methacrylate) block copolymer, a styrene-polymethacrylic acid block copolymer, a styrene-polymethyl acrylate block copolymer, a styrene-polyethyl acrylate block copolymer, a styrene-(poly-t-butyl acrylate) block copolymer, and a styrene-polyacrylic acid block copolymer. In the present invention, it is particularly preferable to use a PS-PMMA block copolymer.

The weight average molecular weight (Mw) (the polystyrene equivalent value determined by gel permeation chromatography) of each polymer constituting the block copolymer is not particularly limited as long as it is large enough to cause phase separation. The weight average molecular weight is preferably 5,000 to 500,000, more preferably 10,000 to 400,000, and still more preferably 20,000 to 300,000.

The polydispersity (Mw/Mn) of the block copolymer is preferably 1.0 to 3.0, more preferably 1.0 to 1.5, and still more preferably 1.0 to 1.2. Here, Mn is the number average molecular weight.

Hereafter, among the polymers constituting the block copolymer, a polymer which is not selectively removed in the later step is referred to as “polymer P_{A}”, and a polymer to be selectively removed is referred to as “polymer P_{B}”. For example, after the phase separation of a layer containing a PS-PMMA block copolymer, by subjecting the layer to an oxygen plasma treatment or a hydrogen plasma treatment, the phase of PMMA is selectively removed. In such a case, PS is the polymer P_{A}, and PMMA is the polymer P_{B}.

In the present invention, the shape and size of the phase to be selectively removed (i.e., the phase of polymer P_{B}) is determined by the compositional ratio of the respective polymers constituting the block copolymer and the molecular weight of the block copolymer. For example, by making the compositional ratio per volume of the polymer P_{B} within the block copolymer relatively small, a cylinder structure in which the phase of the P_{B} polymer is present within the phase of the polymer P_{A} in the form of a cylinder can be formed. On the other hand, by making the compositional ratio per volume of the polymer P_{B} within the block copolymer about the same as that of the polymer P_{A}, a lamellar structure in which the phase of the polymer P_{A} and the phase of the polymer P_{B} are alternately laminated can be formed. Further, by increasing the molecular weight of the block copolymer, the size of each phase can be increased.

<Substrate>

The substrate used in the present invention is not particularly limited as long as the substrate does not dissolve or admix when the undercoat agent and the block copolymer are applied. Examples thereof include a silicon wafer, a metal substrate such as copper, chromium, iron or aluminum, a metal oxide substrate such as a glass substrate, and a polymer film (such as polyethylene, polyethylene terephthalate, polyimide, benzocyclobutene or the like). Further, the size and the shape of the substrate is not particularly limited, and can be appropriately selected as long as it is plate-shaped.

<Substrate Washing Treatment>

Before forming a layer containing a block copolymer, the surface of the substrate may be washed. By washing the surface of the substrate, the neutralization reaction treatment in a later step may be satisfactorily performed.

As the washing treatment, a conventional method may be used, and examples thereof include an oxygen plasma treatment, an ozone oxidation treatment, an acid alkali treatment, and a chemical modification treatment. For example, the substrate is immersed in an acidic solution such as a sulfuric acid/hydrogen peroxide aqueous solution, followed by washing with water and drying. Thereafter, a layer containing a block copolymer can be formed on the surface of the substrate.

<Neutralization Treatment>

A neutralization treatment is a treatment in which the surface of the substrate is modified so as to have affinity for all polymers constituting the block copolymer. By the neutralization treatment, it becomes possible to prevent only phases of specific polymers to come into contact with the surface of the substrate by phase separation. In the present invention, before forming a layer containing a block copolymer, a neutralization treatment is conducted depending on the type of the block copolymer to be used. The neutralization treatment is necessary for forming a cylinder structure, a dot structure, a gyroid structure or the like which is freely oriented on the substrate surface by phase separation.

A specific example of the neutralization treatment includes a treatment in which a thin film (neutralization film) containing a base material having affinity for all polymers constituting the block copolymer is formed on the surface of the substrate.

As the neutralization film, a film composed of a resin composition can be used. The resin composition used as the base material can be appropriately selected from conventional resin compositions used for forming a thin film, depending on the type of polymers constituting the block copolymer. The resin composition used as the base material may be a heat-polymerizable resin composition, or a photosensitive resin composition such as a positive resist composition or a negative resist composition.

Alternatively, the neutralization film may be a non-polymerizable film. For example, a siloxane organic monomolecular film such as phenethyltrichlorosilane, octadecyltrichlorosilane or hexamethyldisilazane may be preferably used as a neutralization film.

The neutralization film composed of such base materials can be formed by a conventional method.

Examples of the base material include a resin composition containing all structural units of the polymers constituting the block copolymer, and a resin containing all structural units having high affinity for the polymers constituting the block copolymer.

For example, when a PS-PMMA block copolymer is used, as the base material, it is preferable to use a resin composition containing both PS and PMMA as the structural units, or a compound or a composition containing both a portion having a high affinity for PS such as an aromatic ring and a portion having a high affinity for PMMA such as a functional group with high polarity.

Examples of the resin composition containing both PS and PMMA as the structural units include a random copolymer of PS and PMMA, and an alternating polymer of PS and PMMA (a copolymer in which the respective monomers are alternately copolymerized).

Examples of the composition containing both a portion having a high affinity for PS and a portion having a high affinity for PMMA include a resin composition obtained by polymerizing at least a monomer having an aromatic ring and a monomer having a substituent with high polarity. Examples of the monomer having an aromatic ring include a monomer having a group in which one hydrogen atom has been removed from the ring of an aromatic hydrocarbon, such as a phenyl group, a biphenyl group, a fluorenyl group, a naphthyl group, an anthryl group or a phenanthryl group, or a monomer having a hetero aryl group such as the aforementioned group in which part of the carbon atoms constituting the ring of the group has been substituted with a hetero atom such as an oxygen atom, a sulfur atom or a nitrogen atom. Examples of the monomer having a substituent with high polarity include a monomer having a trimethoxysilyl group, a trichlorosilyl group, a carboxy group, a hydroxy group, a cyano group or a hydroxyalkyl group in which part of the hydrogen atoms of the alkyl group has been substituted with fluorine atoms.

Examples of the compound containing both a portion having a high affinity for PS and a portion having a high affinity for PMMA include a compound having both an aryl group such as a phenethyltrichlorosilane and a substituent with high polarity, and a compound having both an alkyl group and a substituent with high polarity, such as an alkylsilane compound.

<Formation of Guide Pattern (Graphoepitaxy)>

In the present invention, as shown in FIG. 1, after applying an undercoat agent to a substrate 11, and performing a step of forming a layer of the undercoat agent (neutralization treatment), a guide pattern 14 is formed on the surface of the layer 12 (neutralization film) of the undercoat agent. As a result, after forming the layer 13 containing a block copolymer, it becomes possible to control the arrangement of the phase separation structure, depending on the shape and surface properties of the guide pattern 14. Furthermore, by virtue of the highly polar carboxylic acid generated from the acid dissociable group upon exposure in the formation of the guide pattern 14 exhibiting high affinity for PMMA (13a) constituting the block copolymer, a phase separation structure having a lamellar structure arranged in the perpendicular direction of the surface of the substrate 11 can be more reliably formed.

As a substrate provided with a guide pattern 14 on the surface of the layer 12 (neutralization film) of an undercoat agent, a substrate in which a pattern is formed on the surface of the layer 12 (neutralization film) of an undercoat agent by a lithography method is used. For example, a film composed of a resist composition which has affinity for any of the polymers constituting the block copolymer is formed on the surface of the layer 12 (neutralization film) of an undercoat agent. Then, a selective exposure is conducted using a radial ray such as light or electron beam through a mask pattern having a predetermined pattern, followed by a development treatment, thereby forming a guide pattern 14.

More specifically, for example, a resist composition is applied to the surface of the substrate using a spinner or the like, and a prebake (post applied bake (PAB)) is conducted under temperature conditions of 80 to 150° C. for 40 to 120 seconds, preferably 60 to 90 seconds to form a resist film. Then, for example, using an ArF exposure apparatus or the like, the resist film is selectively exposed to an ArF excimer laser through a desired mask pattern, followed by post exposure bake (PEB) under temperature conditions of 80 to 150° C. for 40 to 120 seconds, preferably 60 to 90 seconds. Subsequently, the resist film is subjected to a developing treatment. As the developing method, an organic solvent such as butyl acetate or propylene glycol monomethylether acetate is used for the developing treatment. After the developing treatment, water rinsing is conducted using pure water, and drying may be conducted. If desired, bake treatment (post bake) can be conducted following the developing treatment. In this manner, a guide pattern 14 that is faithful to the mask pattern is formed.

The height of the guide pattern 14 from the surface of the layer 12 (the neutralization film) of the undercoat agent is preferably at least as large as the thickness of the layer containing the block copolymer which is formed on the surface of the substrate 11. The height of the guide pattern 14 from the surface of the layer 12 (the neutralization film) of the undercoat agent can be appropriately adjusted by the film thickness of the resist film formed by applying the resist composition for forming a guide pattern 14.

<<Negative Tone-Development Resist Composition for Forming Guide Pattern>>

In the present invention, the resist composition for forming the guide pattern 14 is a negative-tone development resist composition, and includes a base component (A) (hereafter, referred to as “component (A)”) which exhibits increased polarity and decreased solubility in a developing solution containing an organic solvent under action of acid, and an acid generator component (B) (hereafter, referred to as “component (B)”) which generates acid upon exposure.

In the resist composition, when radial rays are irradiated (when exposure is conducted), acid is generated from the component (B), and the solubility of the component (A) in an organic is decreased by the action of the generated acid. Therefore, in the formation of a resist pattern, by conducting selective exposure of a resist film formed by using the resist composition, the solubility of the exposed portions in a developing solution containing an organic developing solution is decreased, whereas the solubility of the unexposed portions in an organic developing solution is unchanged, and hence, a resist pattern can be formed by removing the unexposed portions by negative tone development using an organic developing solution.

<Component (A)>

In the present invention, the term “base component” refers to an organic compound capable of forming a film.

As the base component, an organic compound having a molecular weight of 500 or more is used. When the organic compound has a molecular weight of 500 or more, the organic compound exhibits a satisfactory film-forming ability, and a resist pattern of nano level can be easily formed.

The “organic compound having a molecular weight of 500 or more” is broadly classified into non-polymers and polymers.

In general, as a non-polymer, any of those which have a molecular weight in the range of 500 to less than 4,000 is used. Hereafter, a “low molecular weight compound” refers to a non-polymer having a molecular weight in the range of 500 to less than 4,000.

As a polymer, any of those which have a molecular weight of 1,000 or more is generally used. In the present description and claims, the term “polymeric compound” refers to a polymer having a molecular weight of 1,000 or more.

With respect to a polymeric compound, the “molecular weight” is the weight average molecular weight in terms of the polystyrene equivalent value determined by gel permeation chromatography (GPC).

[Resin component (A1)]

In the present invention, the component (A) contains a resin component (A1) (hereafter, referred to as “component (A1)”) having a structural unit (a1) derived from an acrylate ester which contains an acid dissociable group and which may have an atom or a substituent other than hydrogen bonded to the carbon atom on the α-position, and at least one structural unit (a2) selected from the group consisting of a structural unit derived from an acrylate ester which contains a 4- to 12-membered, lactone-containing cyclic group and which may have an atom or a substituent other than hydrogen bonded to the carbon atom on the α-position, a structural unit a structural unit derived from an acrylate ester which contains a 3- to 7-membered, ether-containing cyclic group and which may have an atom or a substituent other than hydrogen bonded to the carbon atom on the α-position, and a structural unit derived from an acrylate ester which contains a 5- to 7-membered, carbonate-containing cyclic group and which may have an atom or a substituent other than hydrogen bonded to the carbon atom on the α-position.

The component (A1) preferably includes, in addition to the structural units (a1) and (a2), a structural unit (a0) derived from an acrylate ester containing an —SO₂— containing cyclic group which may have an atom or a substituent other than hydrogen bonded to the carbon atom on the α-position.

The component (A1) may have, in addition to the structural units (a1) and (a2), or the structural units (a1), (a2) and (a0), a structural unit (a3) derived from an acrylate ester containing a polar group-containing aliphatic hydrocarbon group which may have an atom or a substituent other than hydrogen bonded to the carbon atom on the α-position.

In the present descriptions and the claims, the expression “structural unit derived from an acrylate ester” refers to a structural unit that is formed by the cleavage of the ethylenic double bond of an acrylate ester.

The term “acrylate ester” is a generic term that includes acrylate esters having a hydrogen atom bonded to the carbon atom on the α-position, and acrylate esters having a substituent (an atom other than a hydrogen atom or a group) bonded to the carbon atom on the α-position.

Examples of the substituent include an alkyl group of 1 to 5 carbon atoms and a halogenated alkyl group of 1 to 5 carbon atoms. With respect to the “structural unit derived from an acrylate ester”, the “α-position (the carbon atom on the α-position)” refers to the carbon atom having the carbonyl group bonded thereto, unless specified otherwise.

With respect to the acrylate ester, specific examples of the alkyl group of 1 to 5 carbon atoms for the substituent at the α-position include linear or branched alkyl groups of 1 to 5 carbon atoms such as a methyl group, an ethyl group, a propyl group, an isopropyl group, an n-butyl group, an isobutyl group, a tert-butyl group, a pentyl group, an isopentyl group, and a neopentyl group.

Specific examples of the halogenated alkyl group of 1 to 5 carbon atoms include groups in which part or all of the hydrogen atoms of the aforementioned “alkyl group of 1 to 5 carbon atoms for the substituent on the α-position” are substituted with halogen atoms. Examples of halogen atoms include fluorine atoms, chlorine atoms, bromine atoms and iodine atoms, and fluorine atoms are particularly desirable.

In the present invention, it is preferable that a hydrogen atom, an alkyl group of 1 to 5 carbon atoms or a halogenated alkyl group of 1 to 5 carbon atoms is bonded to the α-position of the acrylate ester, a hydrogen atom, an alkyl group of 1 to 5 carbon atoms or a fluorinated alkyl group of 1 to 5 carbon atoms is more preferable, and in terms of industrial availability, a hydrogen atom or a methyl group is the most desirable.

Structural Unit (a1)

The structural unit (a1) is a structural unit derived from an acrylate ester containing an acid dissociable group.

As the acid dissociable group for the structural unit (a1), any group which is decomposed by the action of an acid to form an acid decomposable group exhibiting increased hydrophilicity, and any of those which have been proposed as acid dissociable groups for a base resin of a chemically amplified resist may be used. Generally, groups in which the hydrogen atom on a carboxy group of (meth)acrylic acid or the like has been substituted with an acid dissociable group are widely used. Such acid decomposable groups are decomposed by the action of an acid to form a carboxy group.

As the acid decomposable group to be substituted with the hydrogen atom on a carboxy group, groups that form either a cyclic or chain-like tertiary alkyl ester with the carboxy group of the (meth)acrylic acid, and acetal-type acid dissociable groups such as alkoxyalkyl groups are widely known. Here, the term “(meth)acrylate ester” is a generic term that includes either or both of the acrylate ester having a hydrogen atom bonded to the α-position and the methacrylate ester having a methyl group bonded to the α-position.

Here, a tertiary alkyl ester describes a structure in which an ester is formed by substituting the hydrogen atom of a carboxyl group with a chain-like or cyclic tertiary alkyl group, and a tertiary carbon atom within the chain-like or cyclic tertiary alkyl group is bonded to the oxygen atom at the terminal of the carbonyloxy group (—C(O)—O—). In this tertiary alkyl ester, the action of acid causes cleavage of the bond between the oxygen atom and the tertiary carbon atom.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable groups”.

Examples of tertiary alkyl ester-type acid dissociable groups include aliphatic branched, acid dissociable groups and aliphatic cyclic group-containing acid dissociable groups.

In the present description and claims, the term “aliphatic” is a relative concept used in relation to the term “aromatic”, and defines a group or compound that has no aromaticity.

The term “aliphatic branched” refers to a branched structure having no aromaticity.

The “aliphatic branched, acid dissociable group” is not limited to be constituted of only carbon atoms and hydrogen atoms (not limited to hydrocarbon groups), but is preferably a hydrocarbon group.

Further, the “hydrocarbon group” may be either saturated or unsaturated, but is preferably saturated.

Examples of aliphatic branched, acid dissociable groups include tertiary alkyl groups of 4 to 8 carbon atoms, and specific examples include a tert-butyl group, tert-pentyl group and tert-heptyl group.

The term “aliphatic cyclic group” refers to a monocyclic group or polycyclic group that has no aromaticity.

The “aliphatic cyclic group” within the structural unit (a1) may or may not have a substituent. Examples of the substituent include an alkyl group of 1 to 5 carbon atoms, a fluorine atom, a fluorinated alkyl group of 1 to 5 carbon atoms, and an oxygen atom (═O).

The basic ring of the “aliphatic cyclic group” exclusive of substituents is not limited to be constituted from only carbon and hydrogen (not limited to hydrocarbon groups), but is preferably a hydrocarbon group. Further, the “hydrocarbon group” may be either saturated or unsaturated, but is preferably saturated. Furthermore, the “aliphatic cyclic group” is preferably a polycyclic group.

As such aliphatic cyclic groups, groups in which one or more hydrogen atoms have been removed from a monocycloalkane or a polycycloalkane such as a bicycloalkane, tricycloalkane or tetracycloalkane which may or may not be substituted with an alkyl group of 1 to 5 carbon atoms, a fluorine atom or a fluorinated alkyl group, may be used. Examples of such groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

As the aliphatic cyclic group-containing acid dissociable group, for example, a group which has a tertiary carbon atom on the ring structure of the cycloalkyl group can be used. Specific examples include 2-methyl-2-adamantyl group and a 2-ethyl-2-adamantyl group. Further, groups having an aliphatic cyclic group such as an adamantyl group, cyclohexyl group, cyclopentyl group, norbornyl group, tricyclodecyl group or tetracyclododecyl group, and a branched alkylene group having a tertiary carbon atom bonded thereto, as the groups bonded to the oxygen atom of the carbonyl group (—C(O)—O—) within the structural units represented by general formulas (a1″-1) to (a1″-6) shown below, can be used.

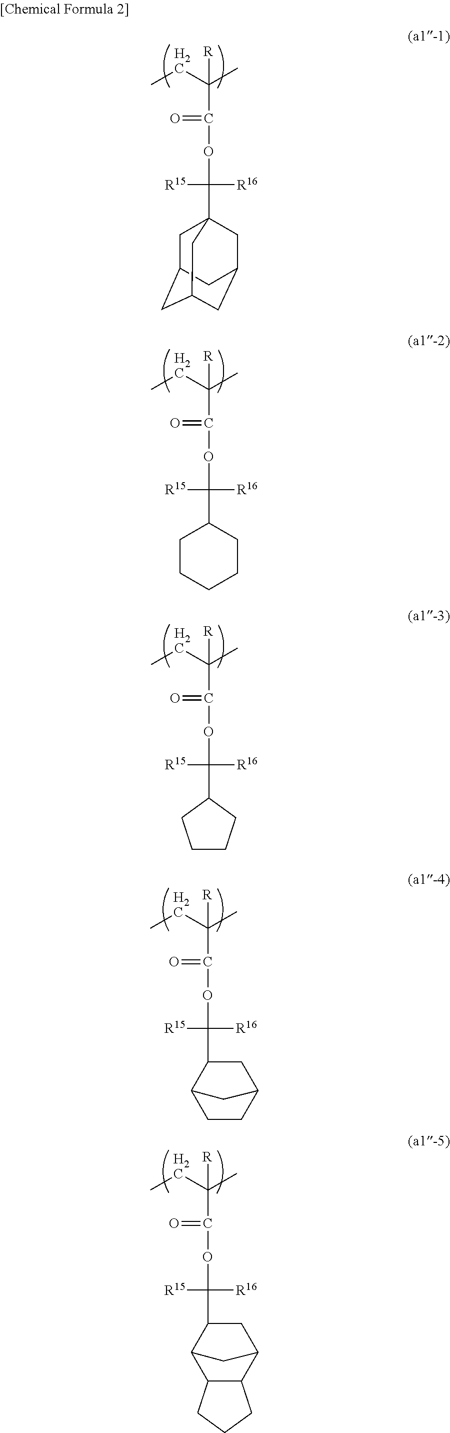

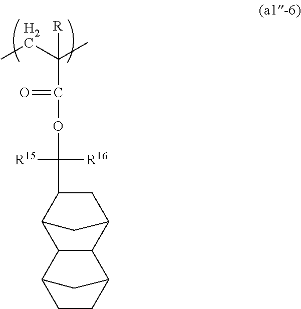

In the formulas, R represents a hydrogen atom, an alkyl group of 1 to 5 carbon atoms or a halogenated alkyl group of 1 to 5 carbon atoms; and R¹⁵ and R¹⁶ each independently represent an alkyl group (which may be linear or branched, and preferably has 1 to 5 carbon atoms).

In general formulas (a1″-1) to (a1″-6) above, the alkyl group of 1 to 5 carbon atoms or halogenated alkyl group of 1 to 5 carbon atoms for R are the same as the alkyl group of 1 to 5 carbon atoms or halogenated alkyl group of 1 to 5 carbon atoms which can be bonded to the α-position of the aforementioned acrylate ester.

An “acetal-type acid dissociable group” generally substitutes a hydrogen atom at the terminal of an alkali-soluble group such as a carboxy group or hydroxyl group, so as to be bonded with an oxygen atom. When acid is generated upon exposure, the generated acid acts to break the bond between the acetal-type acid dissociable group and the oxygen atom to which the acetal-type, acid dissociable group is bonded.

Examples of acetal-type acid dissociable groups include groups represented by general formula (p1) shown below.

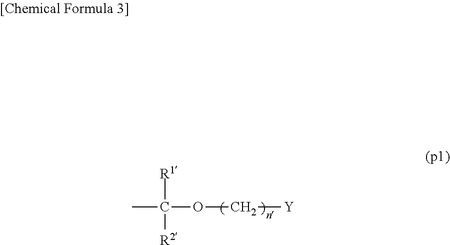

In the formula, R¹′ and R²′ each independently represent a hydrogen atom or an alkyl group of 1 to 5 carbon atoms; n′ represents an integer of 0 to 3; and Y represents an alkyl group of 1 to 5 carbon atoms or an aliphatic cyclic group.

In general formula (p1) above, n′ is preferably an integer of 0 to 2, more preferably 0 or 1, and most preferably 0.

As the alkyl group of 1 to 5 carbon atoms for R¹′ and R²′, the same alkyl groups of 1 to 5 carbon atoms as those described above for R can be used, although a methyl group or ethyl group is preferable, and a methyl group is particularly desirable.

In the present invention, it is preferable that at least one of R¹′ and R²′ be a hydrogen atom. That is, it is preferable that the acid dissociable group (p1) is a group represented by general formula (p1-1) shown below.

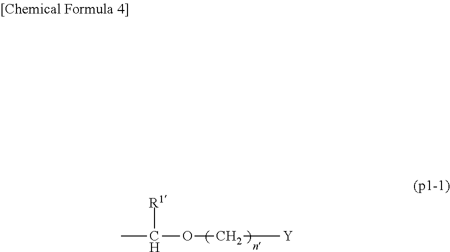

In the formula, R¹′, n′ and Y are the same as defined above.

As the alkyl group of 1 to 5 carbon atoms for Y, the same alkyl groups of 1 to 5 carbon atoms as those described above can be used.

As the aliphatic cyclic group for Y, any of the aliphatic monocyclic/polycyclic groups which have been proposed for conventional ArF resists and the like can be appropriately selected for use. For example, the same groups described above in connection with the “aliphatic cyclic group” can be used.

Further, as the acetal-type, acid dissociable group, groups represented by general formula (p2) shown below can also be used.

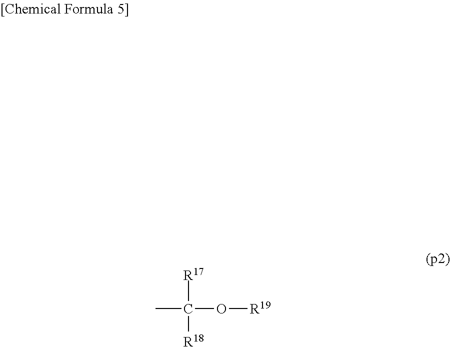

In the formula, R¹⁷ and R¹⁸ each independently represent a linear or branched alkyl group or a hydrogen atom; and R¹⁹ represents a linear, branched or cyclic alkyl group; or R¹⁷ and R¹⁹ each independently represents a linear or branched alkylene group, and the terminal of R¹⁷ is bonded to the terminal of R¹⁹ to form a ring.

The alkyl group for R¹⁷ and R¹⁸ preferably has 1 to 15 carbon atoms, and may be either linear or branched. As the alkyl group, an ethyl group or a methyl group is preferable, and a methyl group is most preferable.

It is particularly desirable that either one of R¹⁷ and R¹⁸ be a hydrogen atom, and the other be a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cycloalkyl group, it preferably has 4 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Examples of such groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane. Among these, a group in which one or more hydrogen atoms have been removed from adamantane is preferable.

In general formula (p2) above, R¹⁷ and R¹⁹ may each independently represent a linear or branched alkylene group (preferably an alkylene group of 1 to 5 carbon atoms), and the terminal of R¹⁹ may be bonded to the terminal of R¹⁷.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4- to 7-membered ring, and more preferably a 4- to 6-membered ring. Specific examples of the cyclic group include tetrahydropyranyl group and tetrahydrofuranyl group.

As the structural unit (a1), it is preferable to use at least one member selected from the group consisting of structural units represented by formula (a1-0-1) shown below and structural units represented by formula (a1-0-2) shown below.

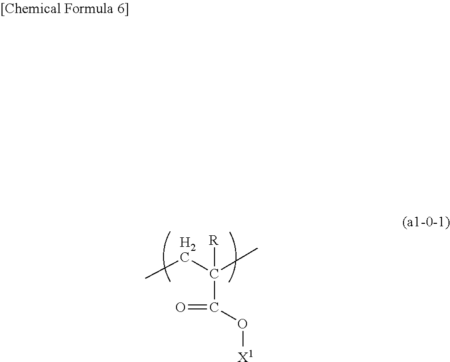

In the formula, R represents a hydrogen atom, an alkyl group of 1 to 5 carbon atoms or a halogenated alkyl group of 1 to 5 carbon atoms; and X¹ represents an acid dissociable group.

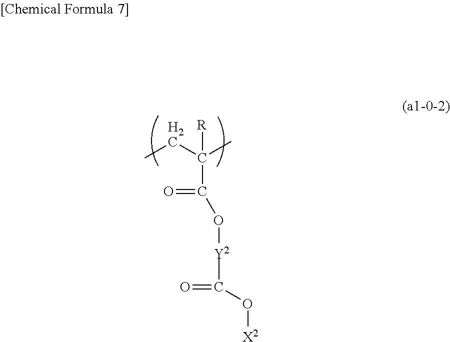

In the formula, R represents a hydrogen atom, an alkyl group of 1 to 5 carbon atoms or a halogenated alkyl group of 1 to 5 carbon atoms; X² represents an acid dissociable group; and Y² represents a divalent linking group.

In general formula (a1-0-1) above, the alkyl group of 1 to 5 carbon atoms or halogenated alkyl group of 1 to 5 carbon atoms for R are the same as the alkyl group of 1 to 5 carbon atoms or halogenated alkyl group of 1 to 5 carbon atoms which can be bonded to the α-position of the aforementioned acrylate ester.

X¹ is not particularly limited as long as it is an acid dissociable group. Examples thereof include the aforementioned tertiary alkyl ester-type acid dissociable groups and acetal-type acid dissociable groups, and tertiary alkyl ester-type acid dissociable groups are preferable.

In general formula (a1-0-2), R is the same as defined above.

X² is the same as defined for X¹ in general formula (a1-0-1).

As the divalent linking group for Y², an alkylene group, a divalent aliphatic cyclic group or a divalent linking group containing a hetero atom can be mentioned.

As the aliphatic cyclic group, the same as those used above in connection with the explanation of “aliphatic cyclic group” can be used, except that two hydrogen atoms have been removed therefrom.

When Y² represents an alkylene group, it preferably has 1 to 10 carbon atoms, more preferably 1 to 6, still more preferably 1 to 4, and most preferably 1 to 3.

When Y² represents a divalent aliphatic cyclic group, it is particularly desirable that the divalent aliphatic cyclic group be a group in which two or more hydrogen atoms have been removed from cyclopentane, cyclohexane, norbornane, isobornane, adamantane, tricyclodecane or tetracyclododecane.

When Y² represents a divalent linking group containing a hetero atom, examples thereof include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O—, “-A-O—B— (wherein O is an oxygen atom, and each of A and B independently represents a divalent hydrocarbon group which may have a substituent)” and “-A-O—C(═O)—B—”.

When Y² represents a divalent linking group —NH— and the H in the formula is replaced with a substituent such as an alkyl group or an acyl group, the substituent preferably has 1 to 10 carbon atoms, more preferably 1 to 8 carbon atoms, and most preferably 1 to 5 carbon atoms.

When Y² is “A-O—B” or “-A-O—C(═O)—B—”, A and B each independently represents a divalent hydrocarbon group which may have a substituent.

A hydrocarbon “has a substituent” means that part or all of the hydrogen atoms within the hydrocarbon group is substituted with groups or atoms other than hydrogen atom.

The hydrocarbon group for A may be either an aliphatic hydrocarbon group, or an aromatic hydrocarbon group. An “aliphatic hydrocarbon group” refers to a hydrocarbon group that has no aromaticity.

The aliphatic hydrocarbon group for A may be either saturated or unsaturated. In general, the aliphatic hydrocarbon group is preferably saturated.

As specific examples of the aliphatic hydrocarbon group for A, a linear or branched aliphatic hydrocarbon group, and an aliphatic hydrocarbon group having a ring in the structure thereof can be given.

The linear or branched aliphatic hydrocarbon group preferably has 1 to 10 carbon atoms, more preferably 1 to 8, still more preferably 2 to 5, and most preferably 2.

As a linear aliphatic hydrocarbon group, a linear alkylene group is preferable, and specific examples include a methylene group, an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable, and specific examples include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkylethylene groups such as —CH(CH₃)CH₂—, —CH(CH₃)CH(CH₃)—, —C(CH₃)₂CH₂— and —CH(CH₂CH₃)CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group within the alkylalkylene group, a linear alkyl group of 1 to 5 carbon atoms is preferable.

The linear or branched aliphatic hydrocarbon group (chain-like aliphatic hydrocarbon group) may or may not have a substituent. Examples of the substituent include a fluorine atom, a fluorinated alkyl group of 1 to 5 carbon atoms, and an oxygen atom (═O).

As examples of the hydrocarbon group containing a ring, a cyclic aliphatic hydrocarbon group (a group in which two hydrogen atoms have been removed from an aliphatic hydrocarbon ring), and a group in which the cyclic aliphatic hydrocarbon group is bonded to the terminal of the aforementioned chain-like aliphatic hydrocarbon group or interposed within the aforementioned chain-like aliphatic hydrocarbon group, can be given.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic group, a group in which two hydrogen atoms have been removed from a monocycloalkane of 3 to 6 carbon atoms is preferable. Examples of the monocycloalkane include cyclopentane and cyclohexane.

As the polycyclic group, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The cyclic aliphatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

As A, a linear aliphatic hydrocarbon group is preferable, more preferably a linear alkylene group, still more preferably a linear alkylene group of 2 to 5 carbon atoms, and most preferably an ethylene group.

As the hydrocarbon group for B, the same divalent hydrocarbon groups as those described above for A can be used.

As B, a linear or branched aliphatic hydrocarbon group is preferable, and a methylene group or an alkylmethylene group is particularly desirable.

The alkyl group within the alkyl methylene group is preferably a linear alkyl group of 1 to 5 carbon atoms, more preferably a linear alkyl group of 1 to 3 carbon atoms, and most preferably a methyl group.

Specific examples of the structural unit (a1) include structural units represented by general formulas (a1-1) to (a1-4) shown below.

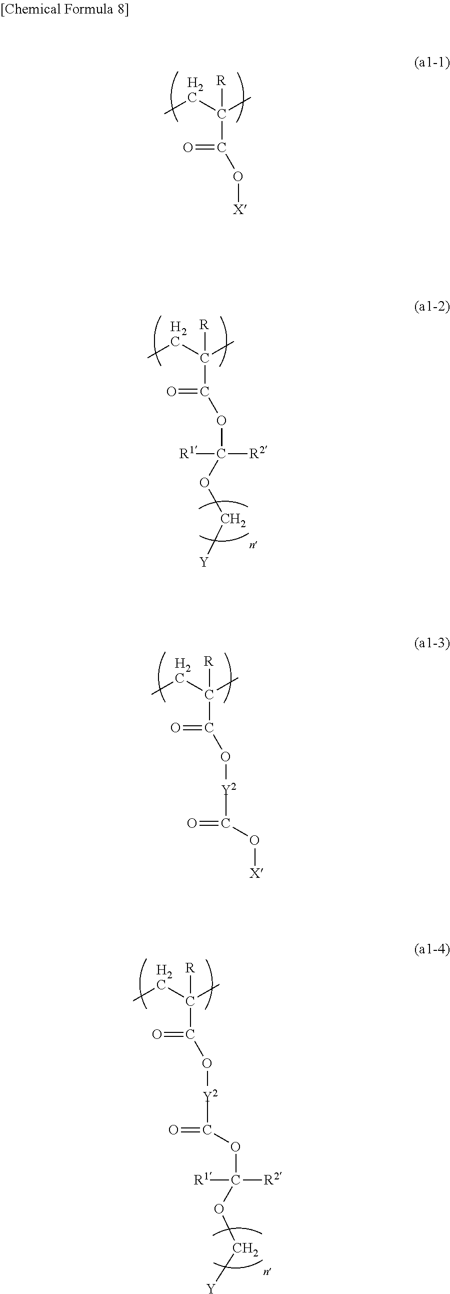

In the formulas, X′ represents a tertiary alkyl ester-type acid dissociable group; Y represents an alkyl group of 1 to 5 carbon atoms or an aliphatic cyclic group; n′ represents an integer of 0 to 3; Y² represents a divalent linking group; R is the same as defined above; and each of R¹′ and R²′ independently represents a hydrogen atom or an alkyl group of 1 to 5 carbon atoms.

Examples of the tertiary alkyl ester-type acid dissociable group for X′ include the same tertiary alkyl ester-type acid dissociable groups as those described above for X¹.

As R¹′, R²′, n′ and Y are respectively the same as defined for R¹′, R²′, n′ and Y in general formula (p1) described above in connection with the “acetal-type acid dissociable group”.

As examples of Y², the same groups as those described above for Y² in general formula (a1-0-2) can be given.

Specific examples of structural units represented by general formula (a1-1) to (a1-4) are shown below.

In the formulae shown below, R^{α} represents a hydrogen atom, a methyl group or a trifluoromethyl group.

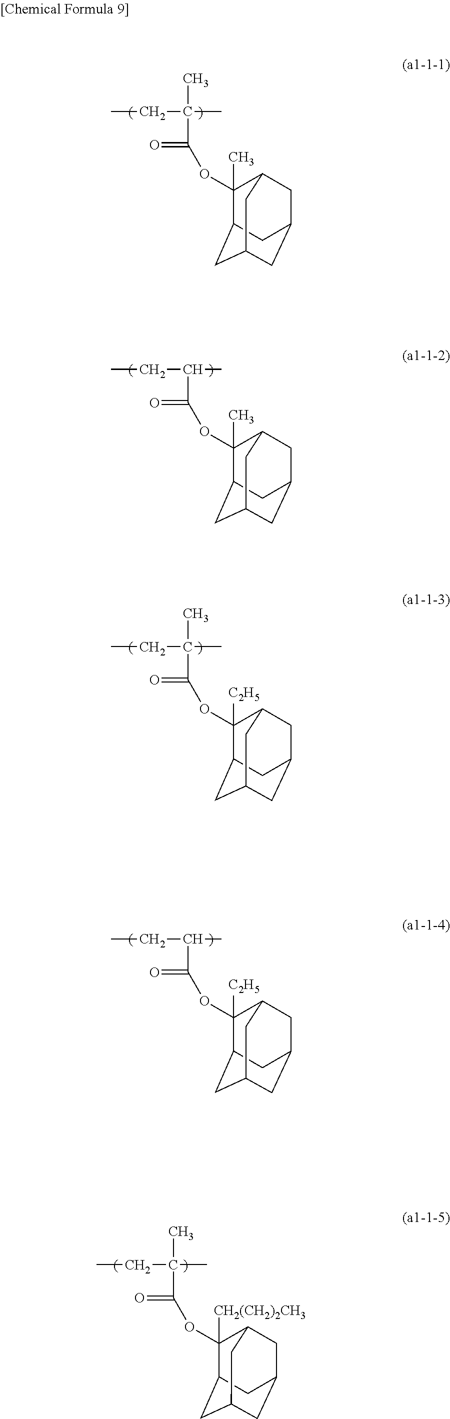

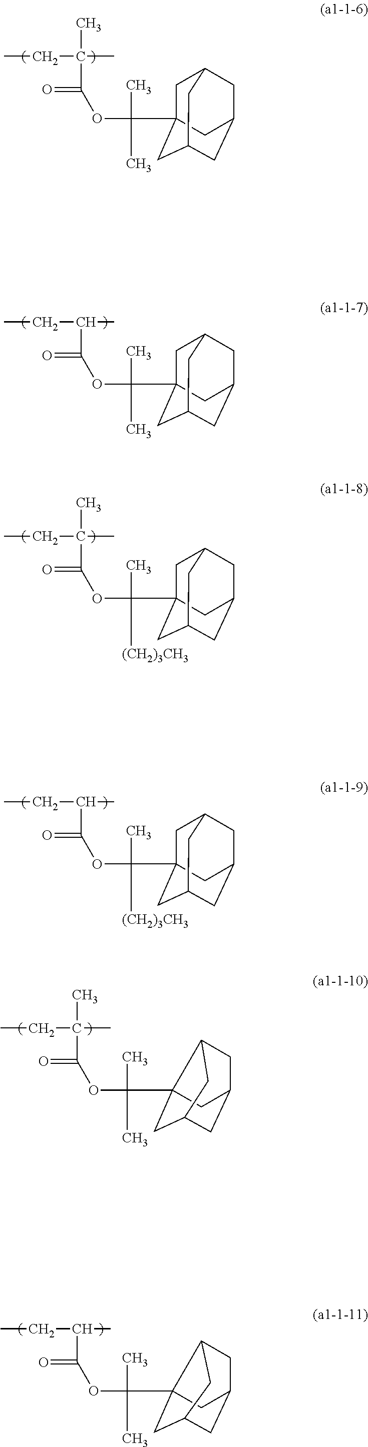

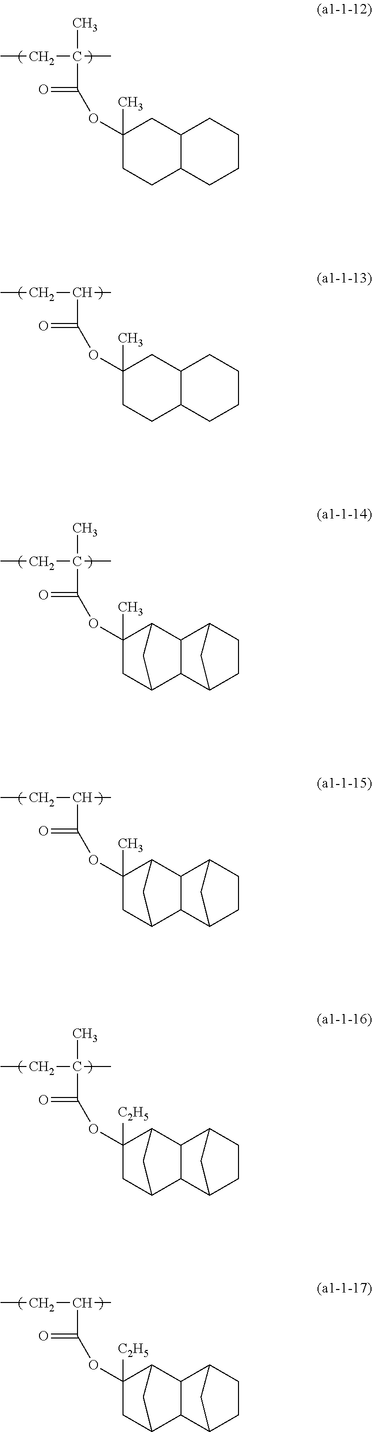

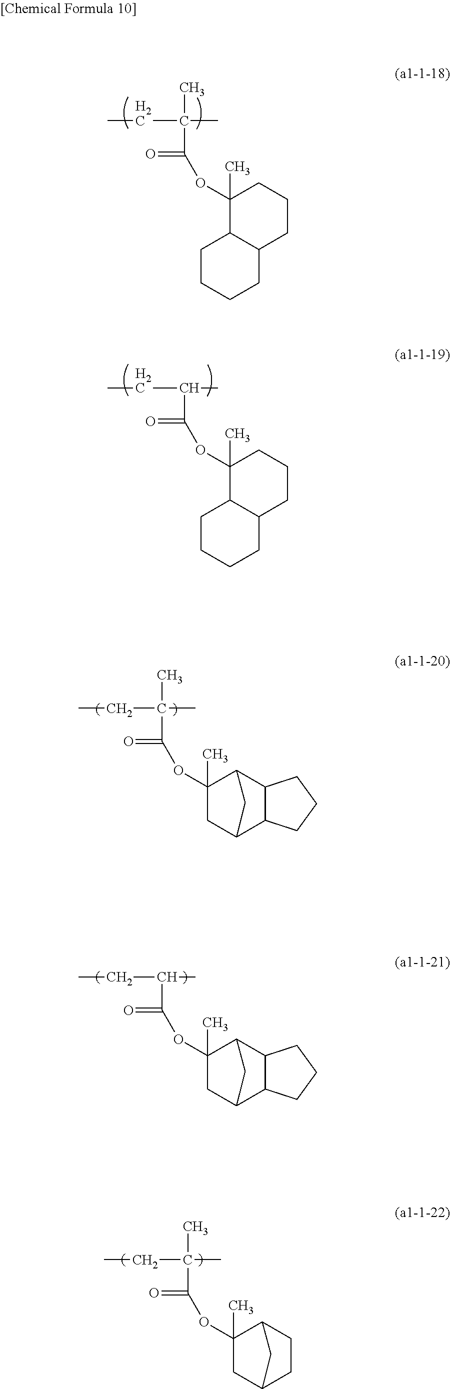

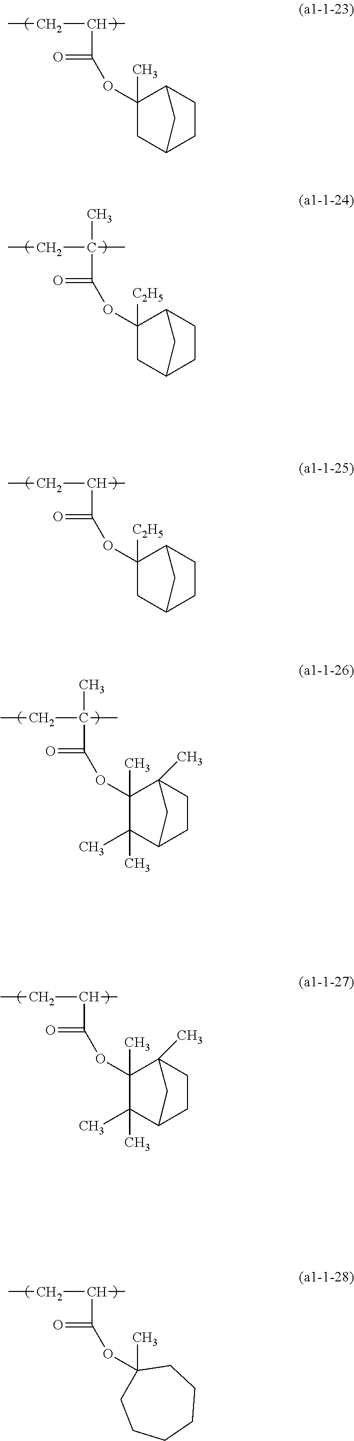

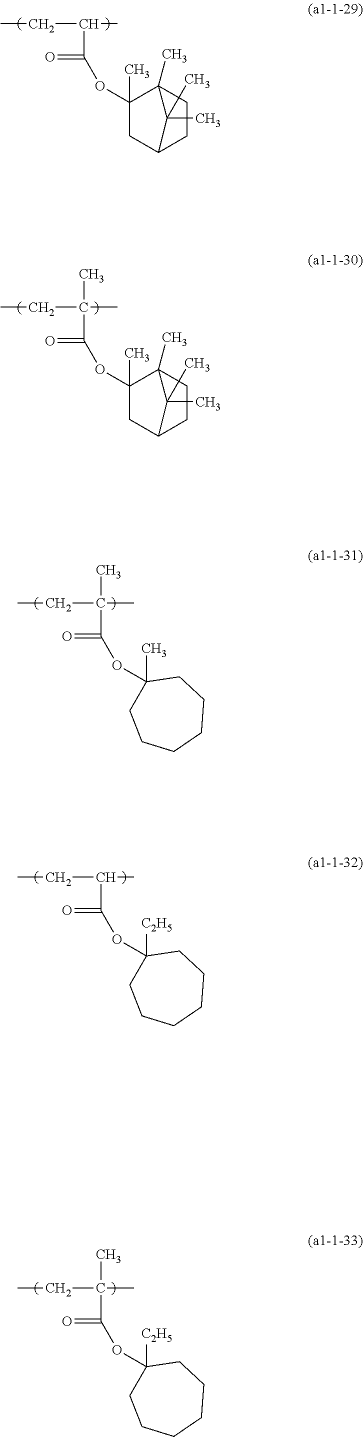

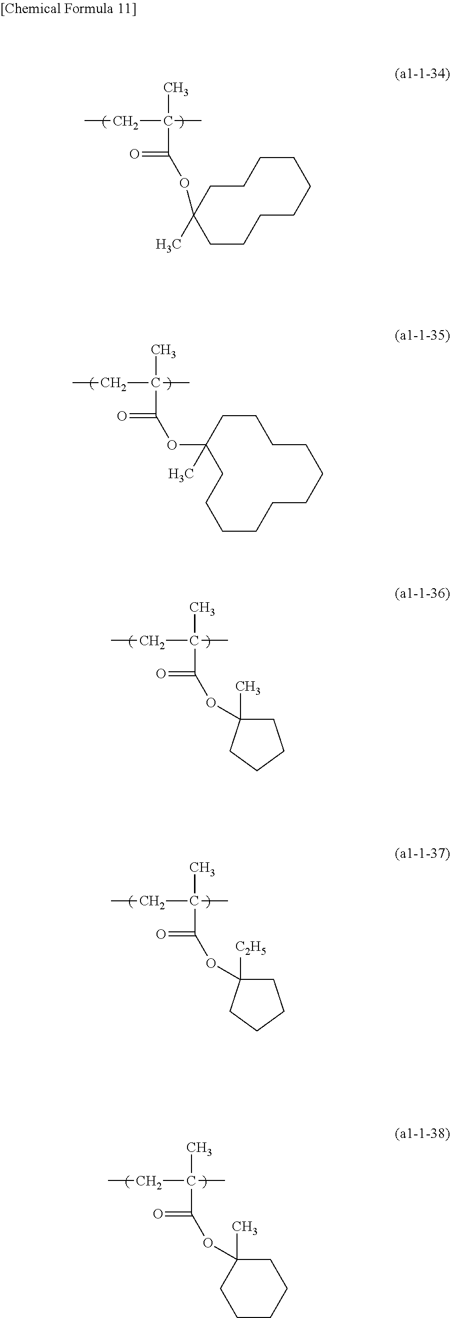

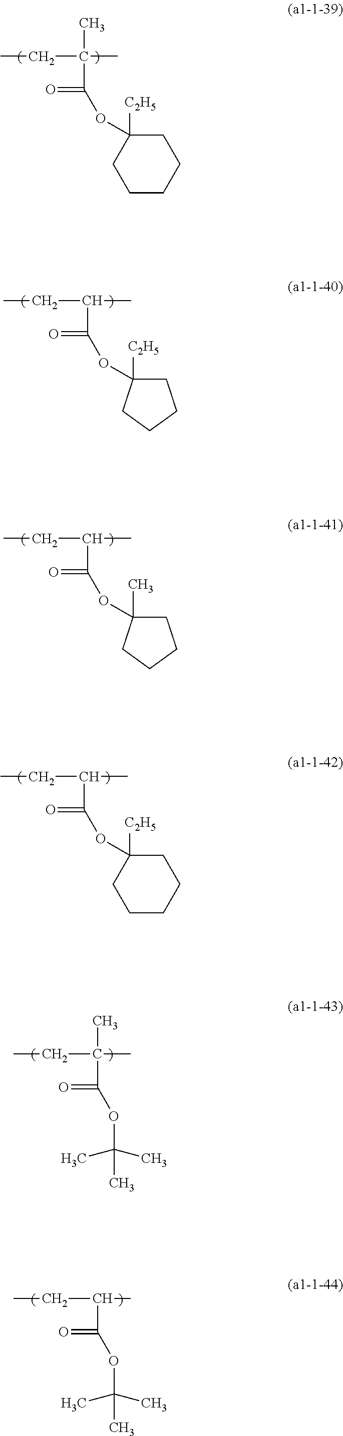

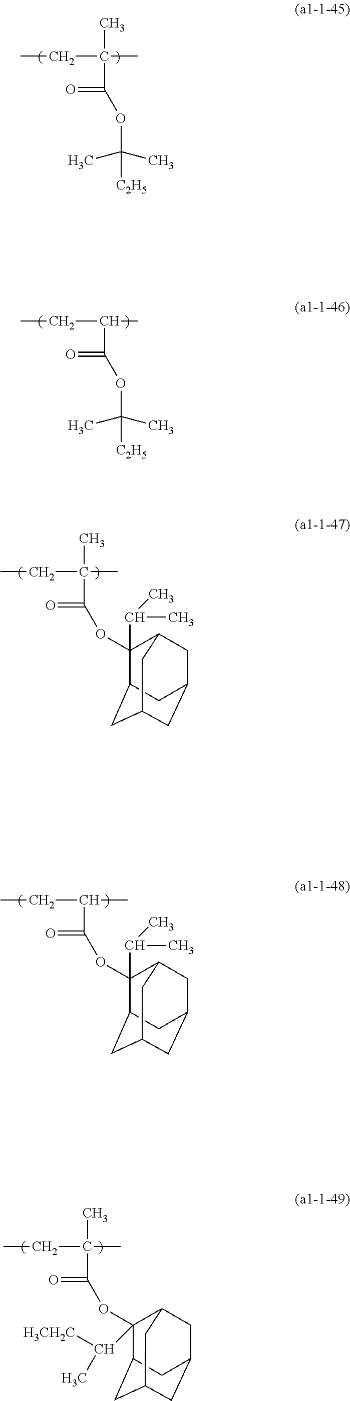

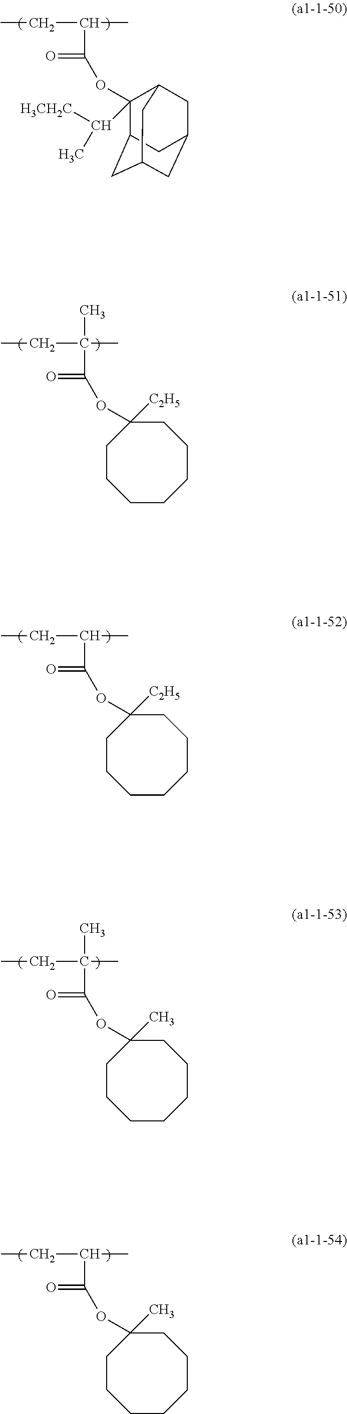

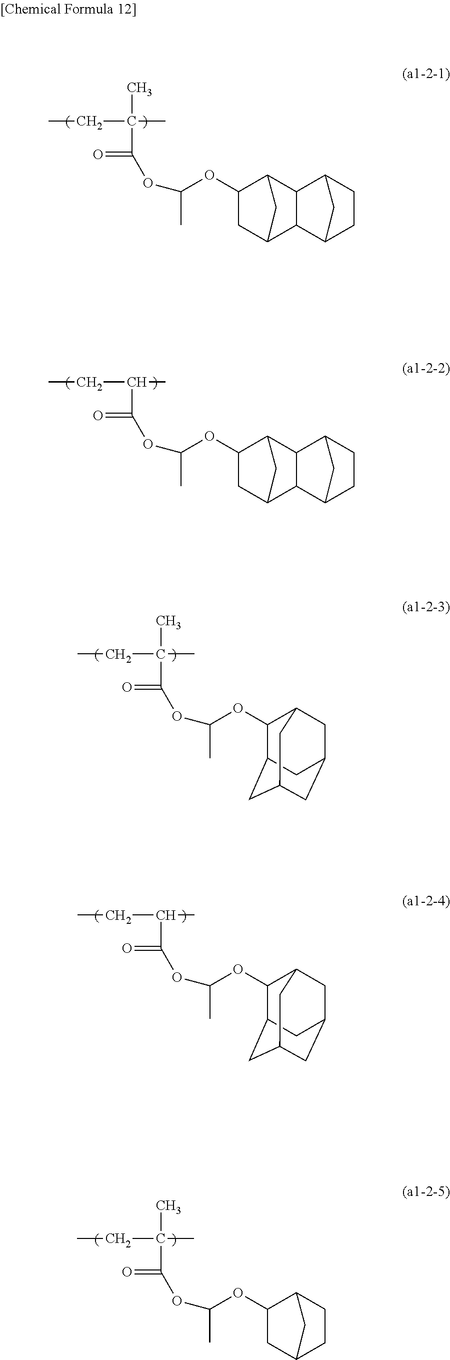

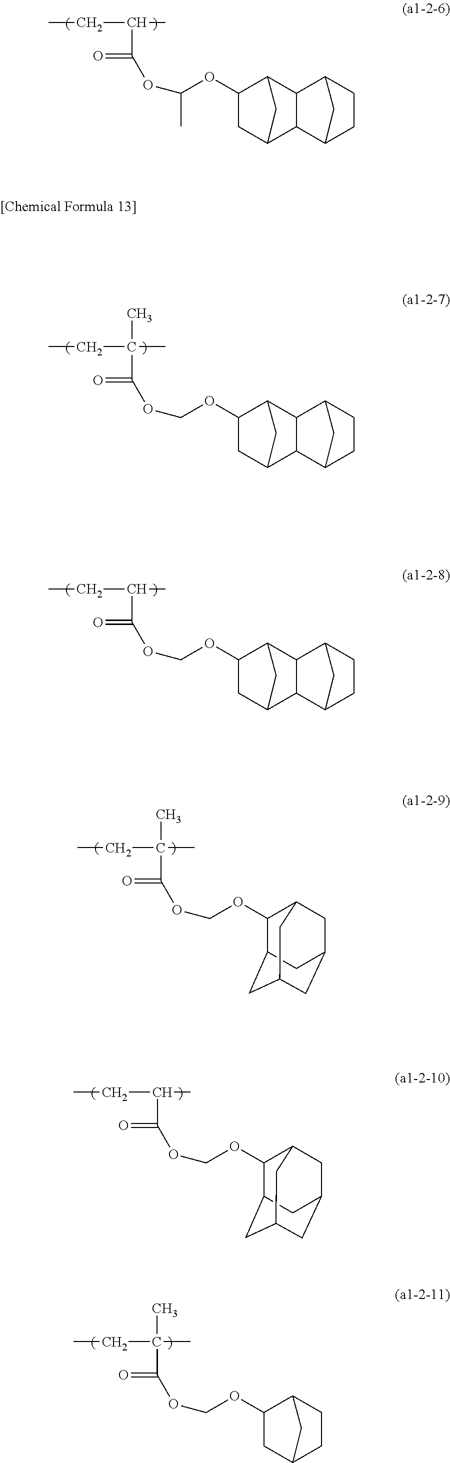

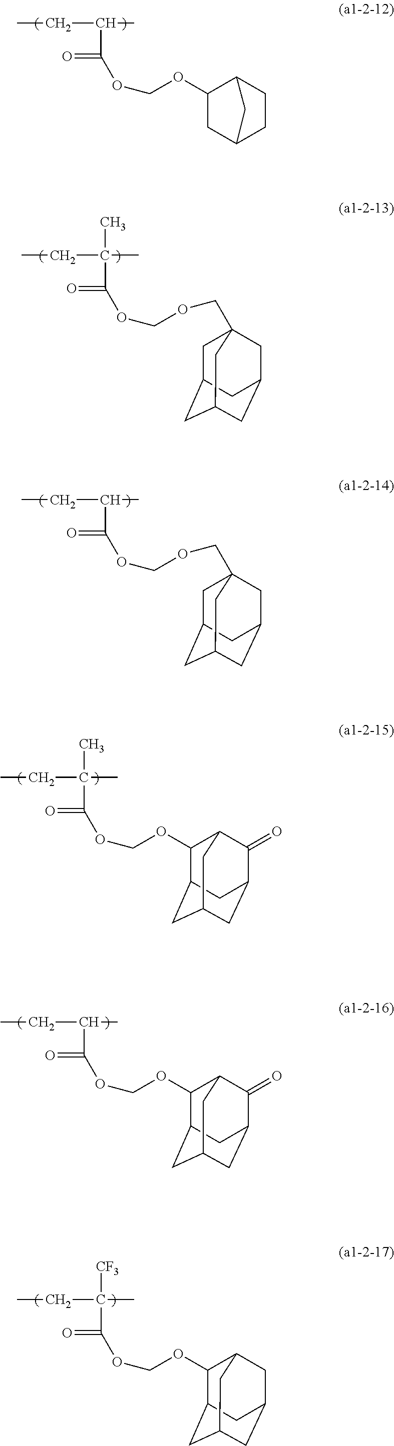

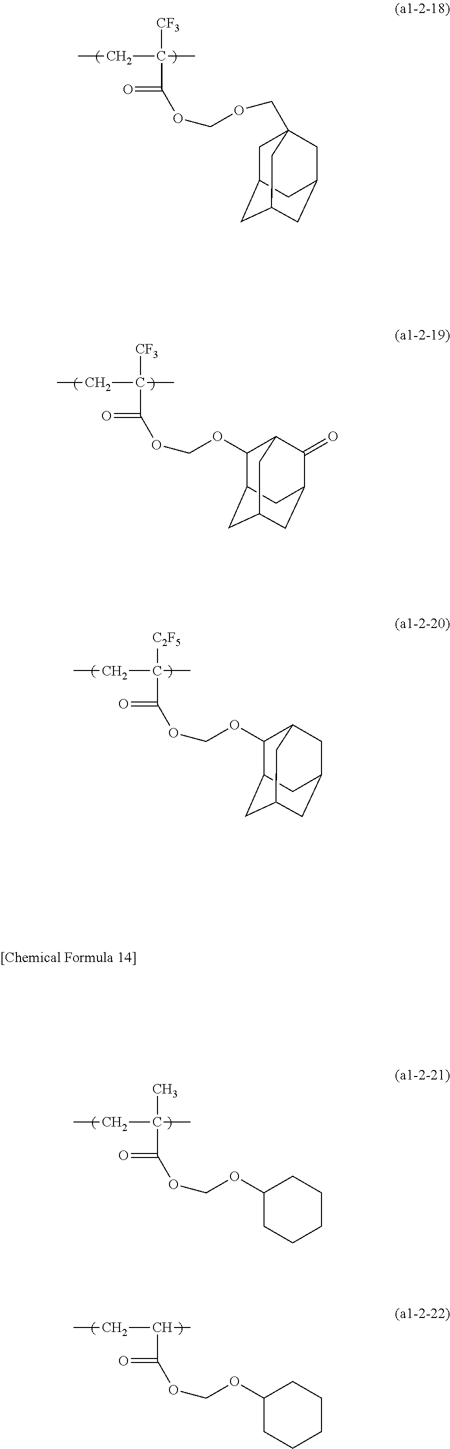

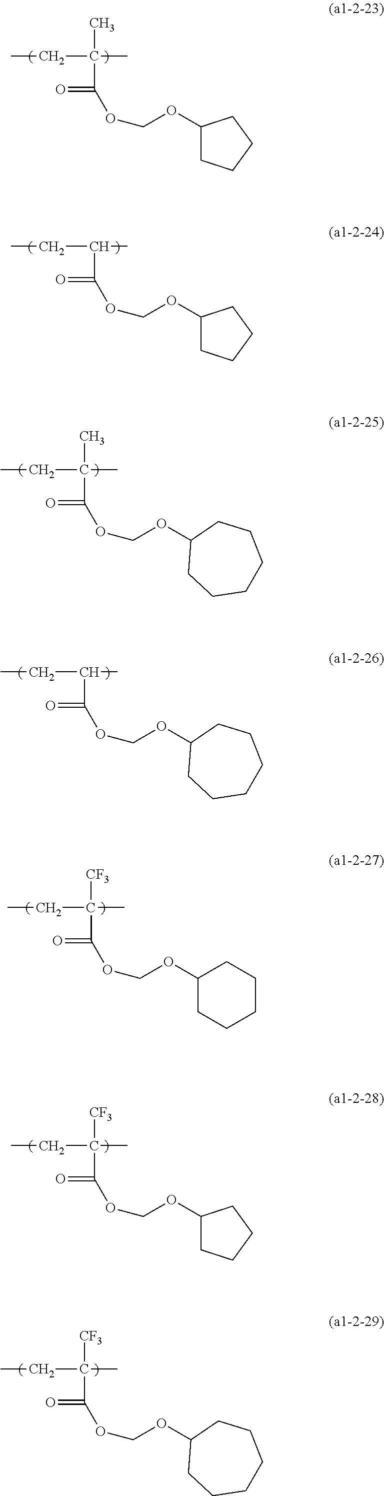

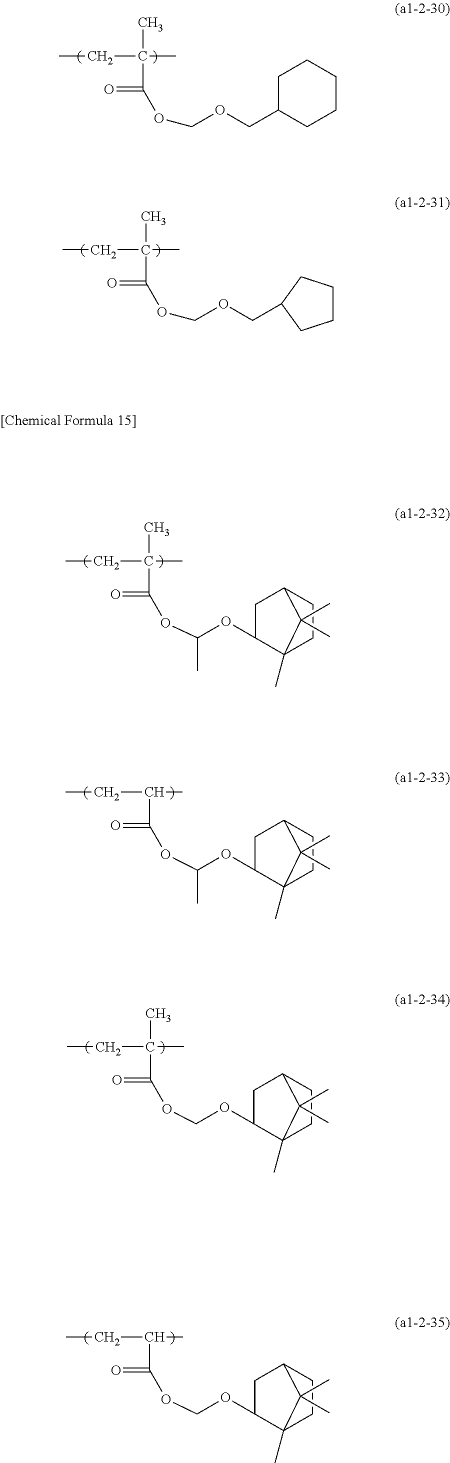

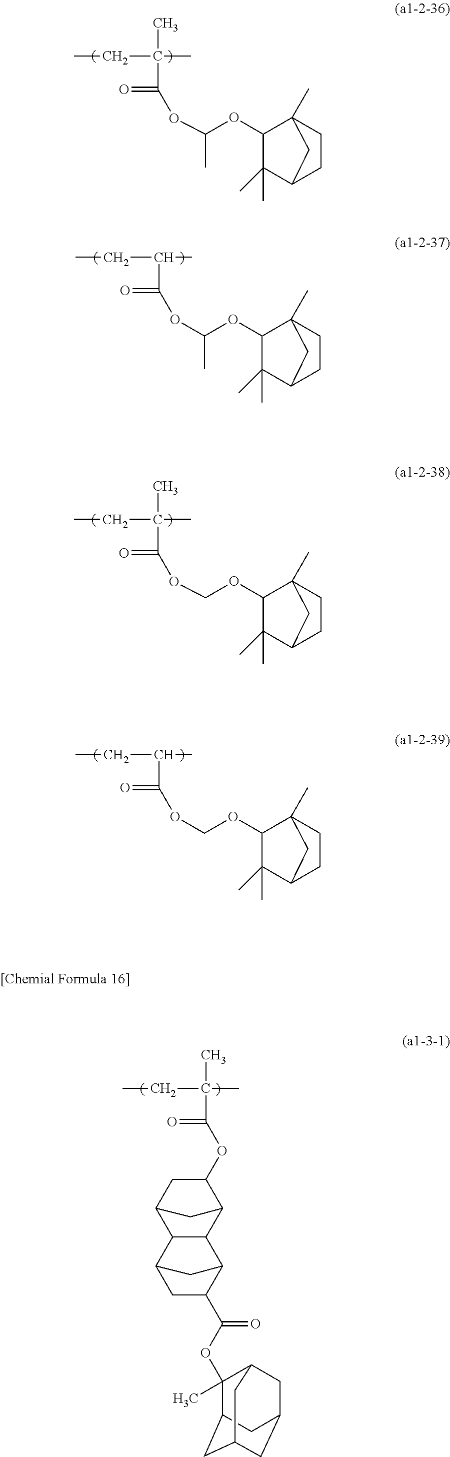

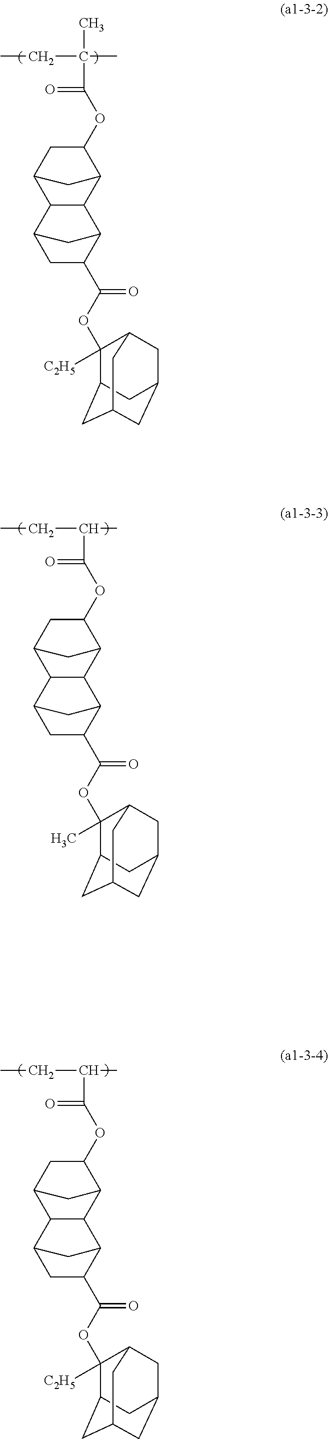

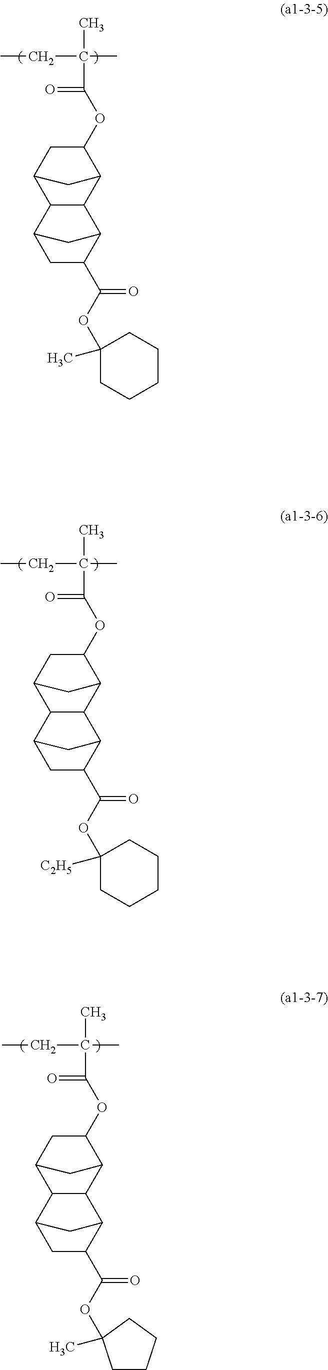

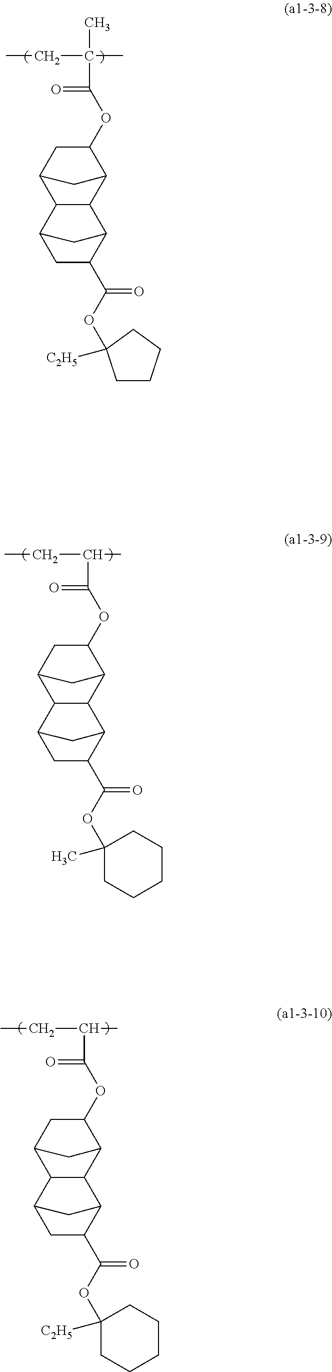

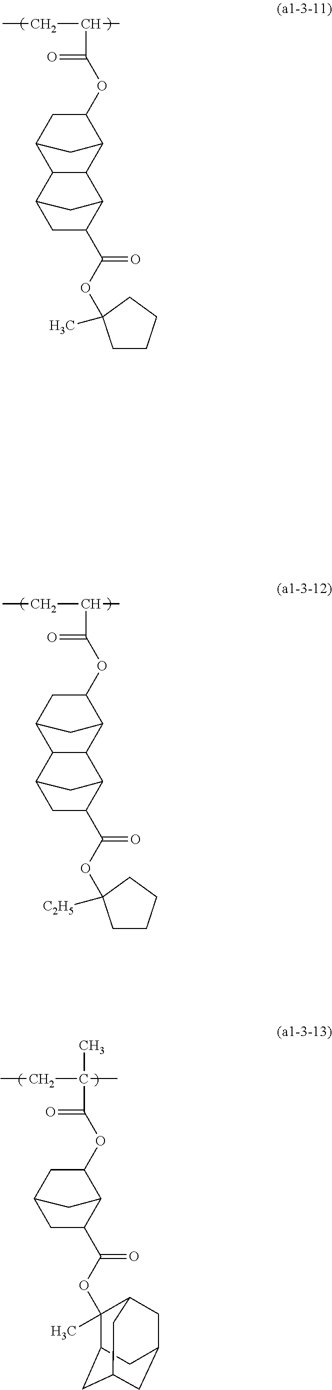

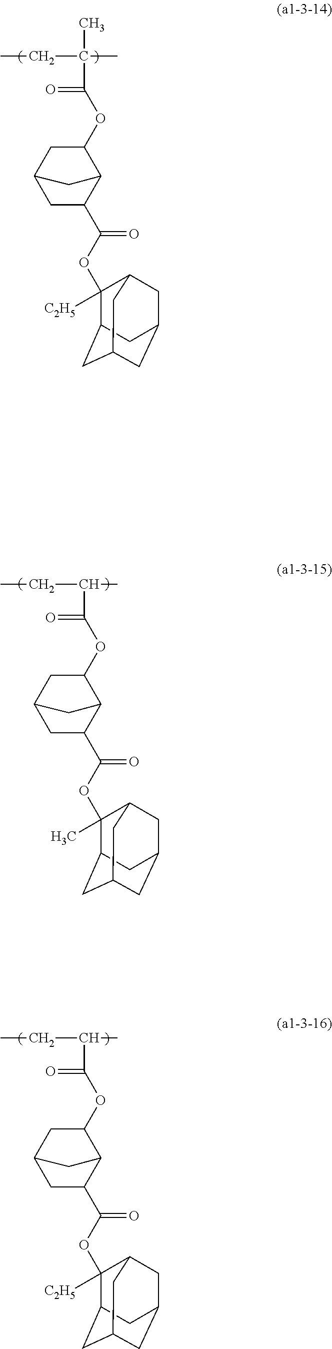

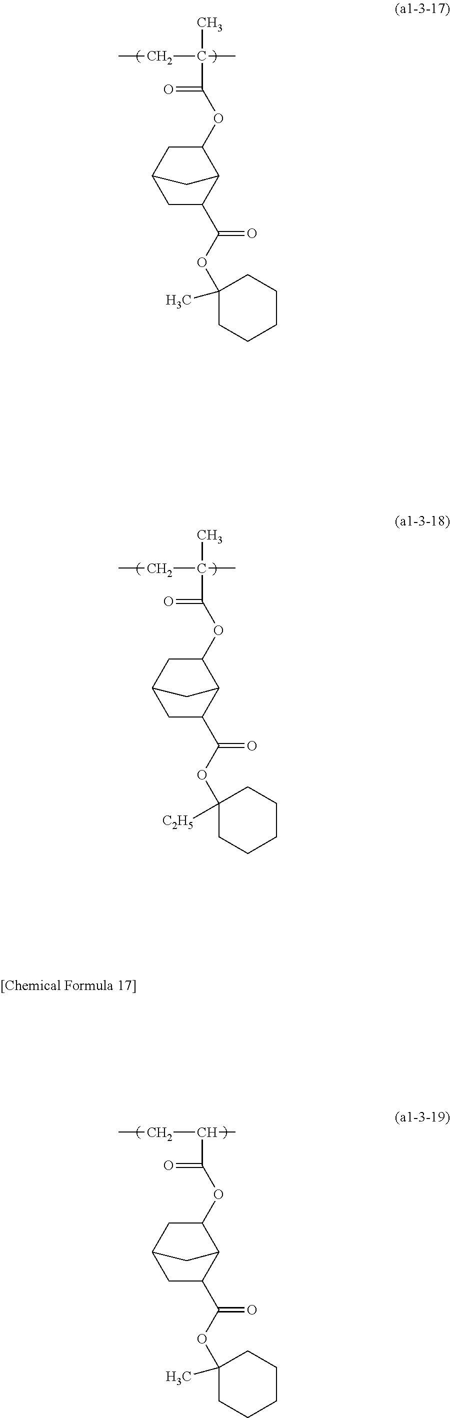

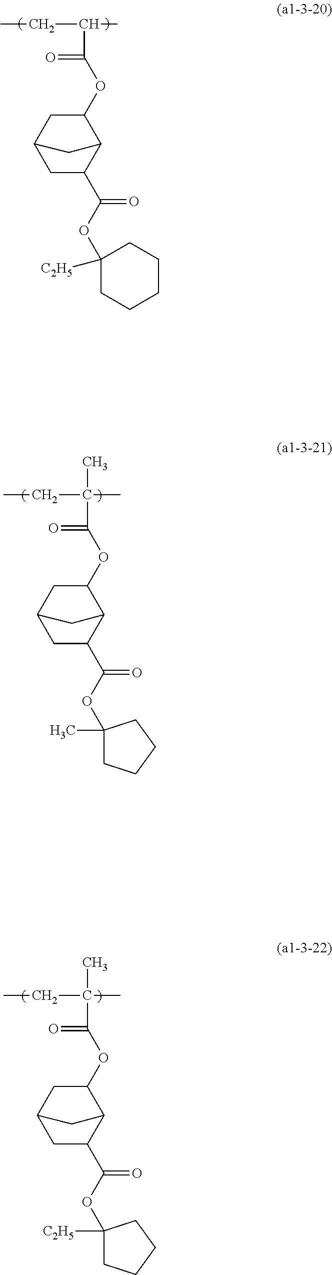

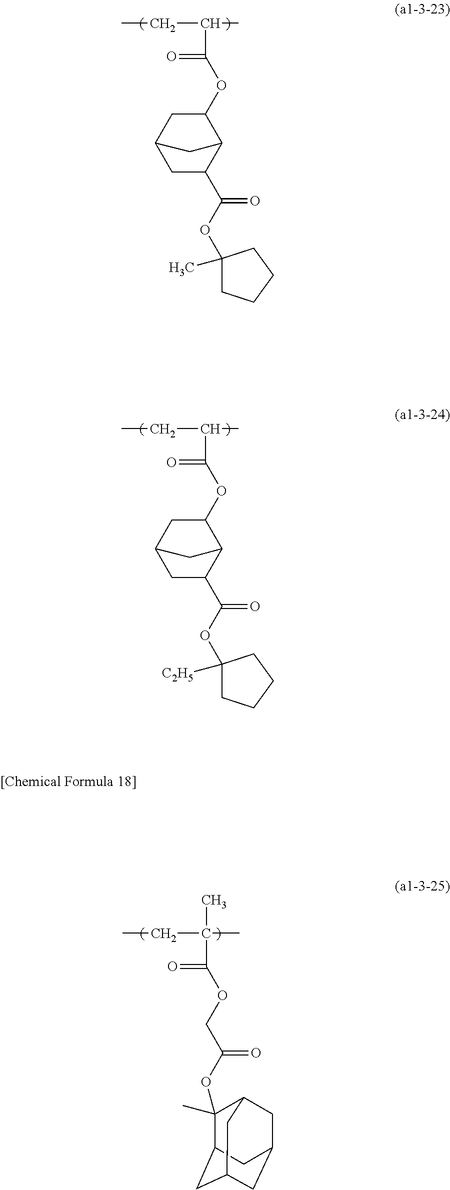

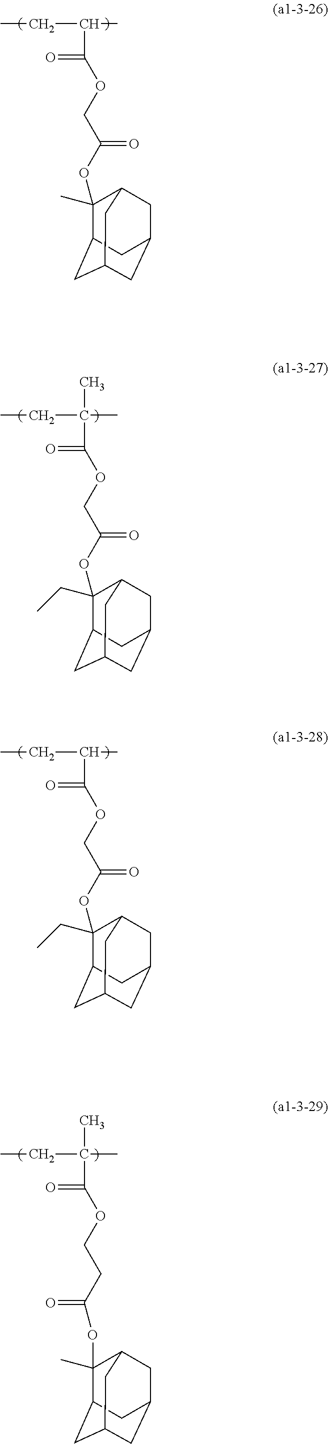

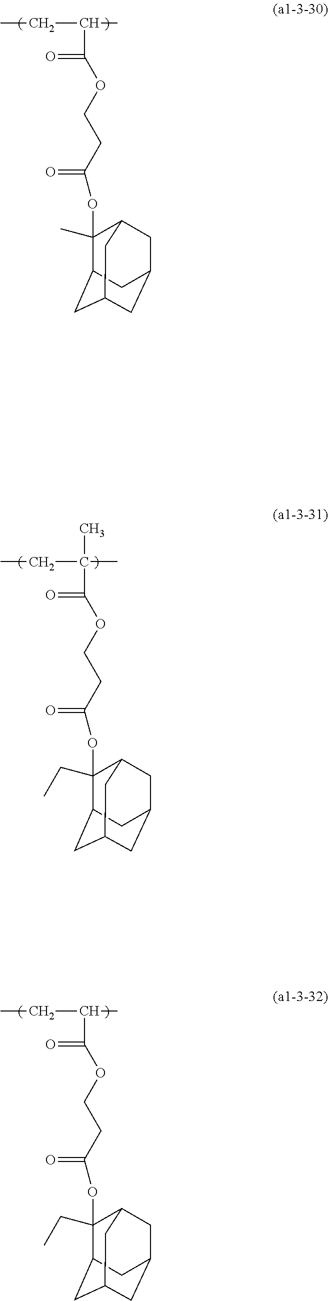

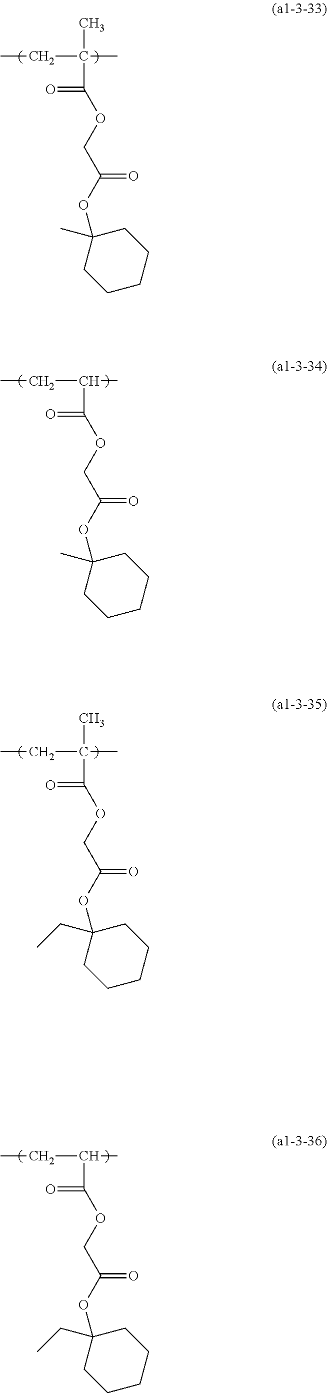

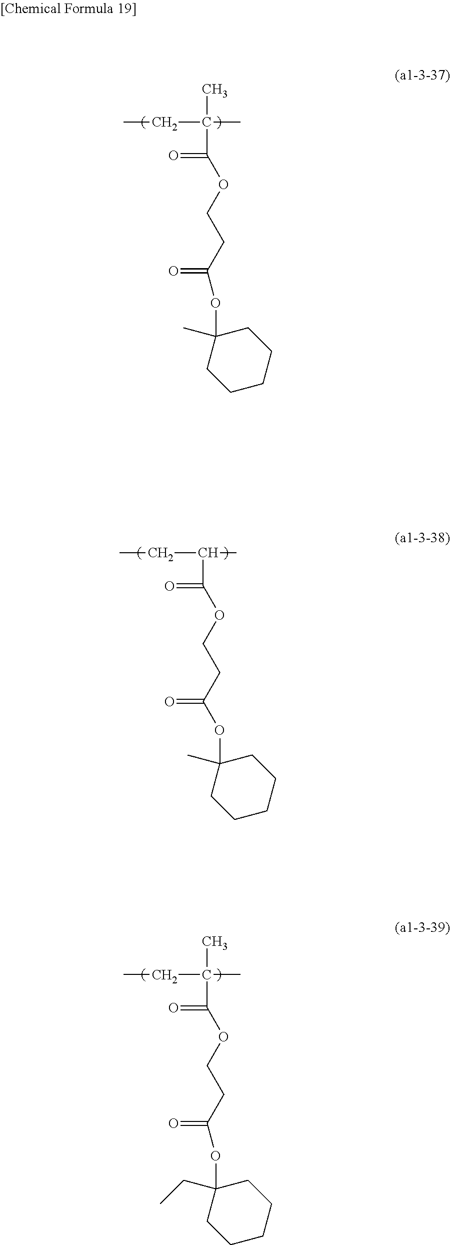

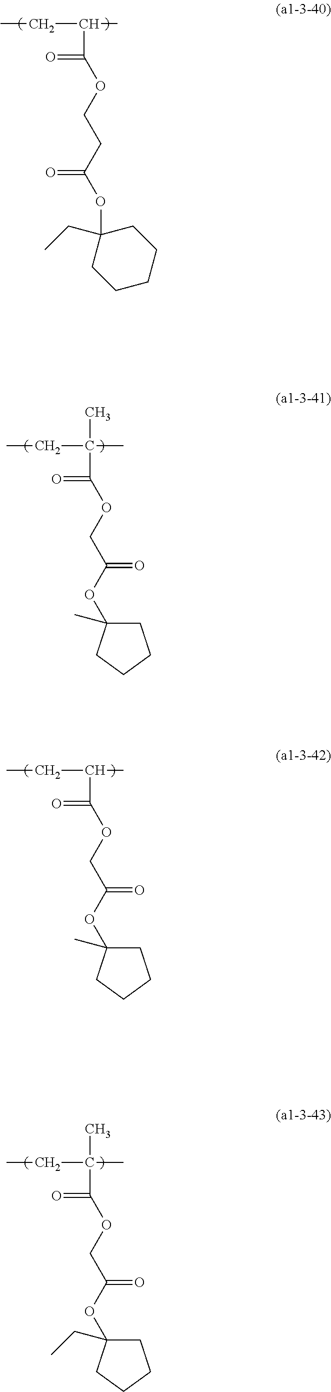

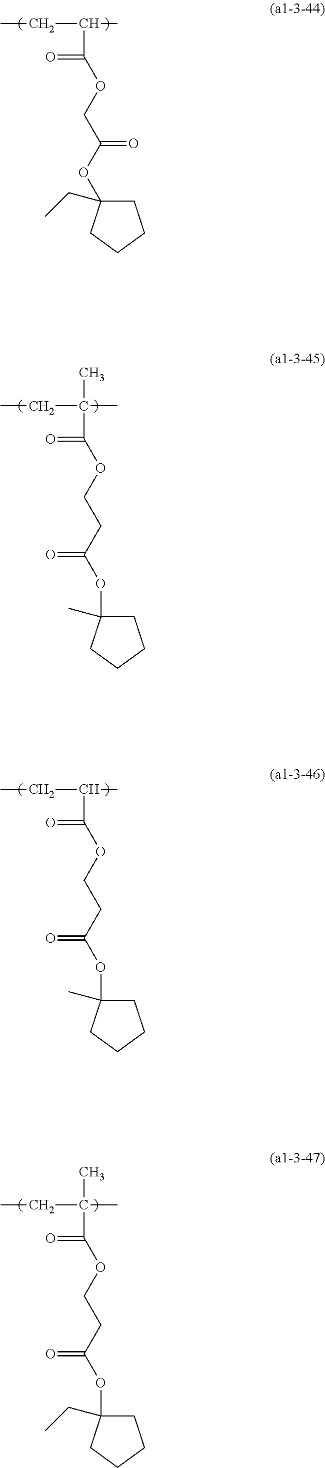

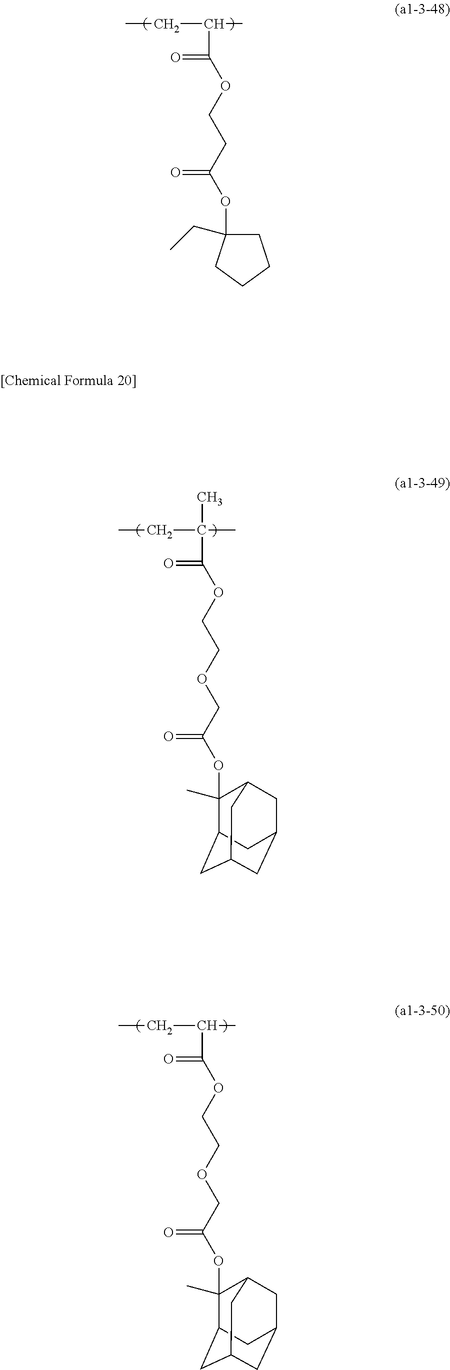

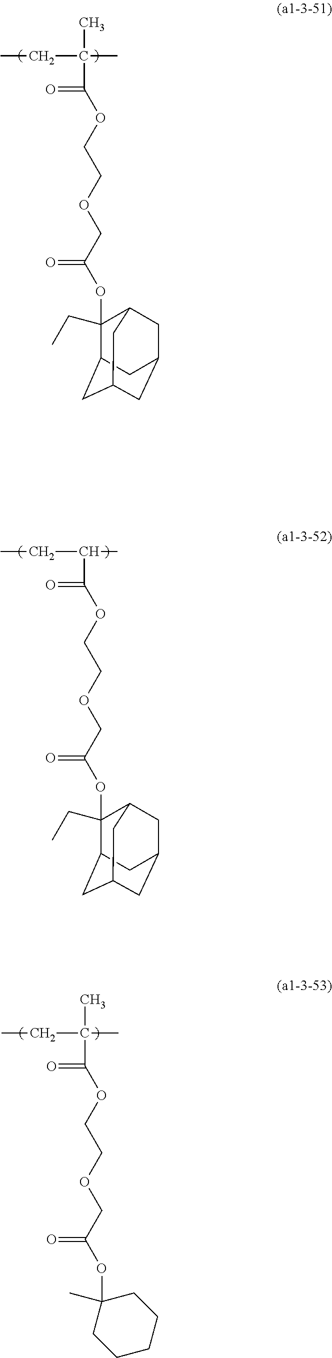

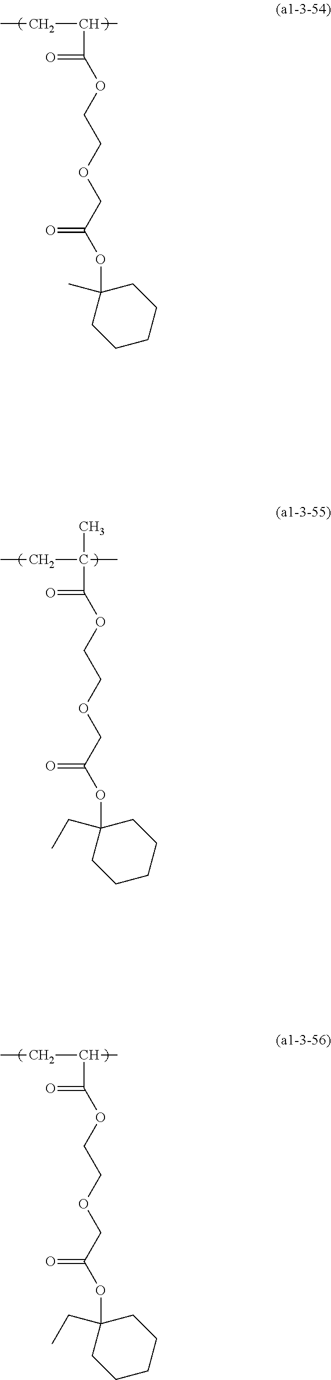

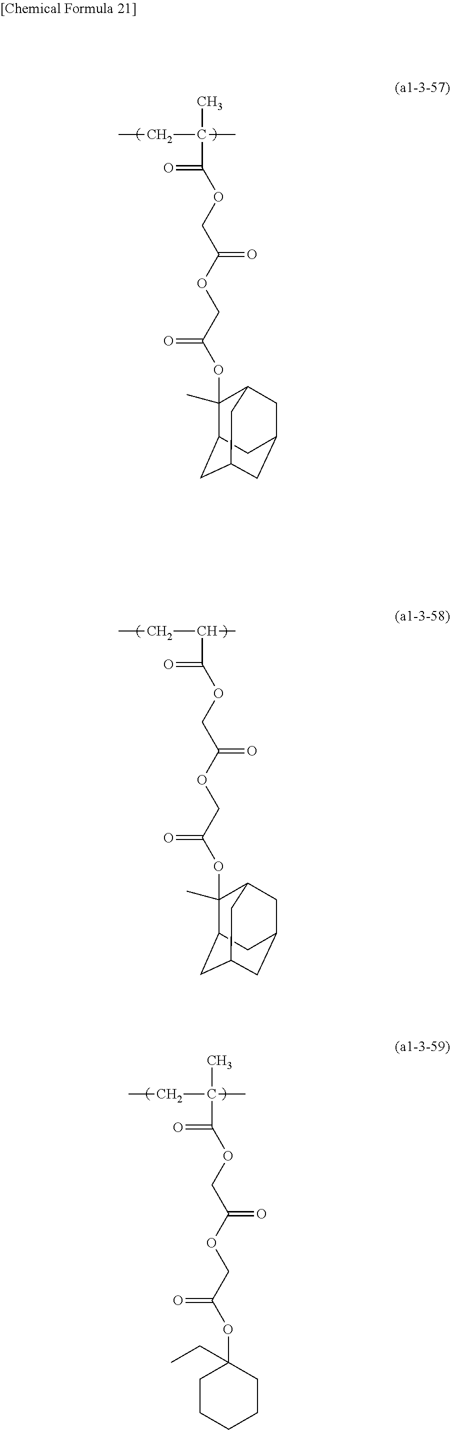

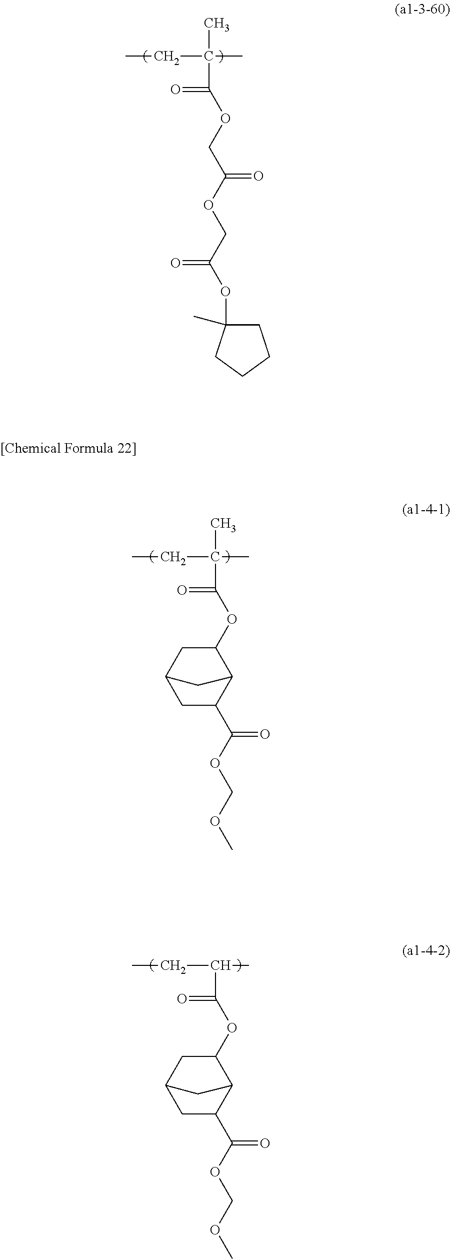

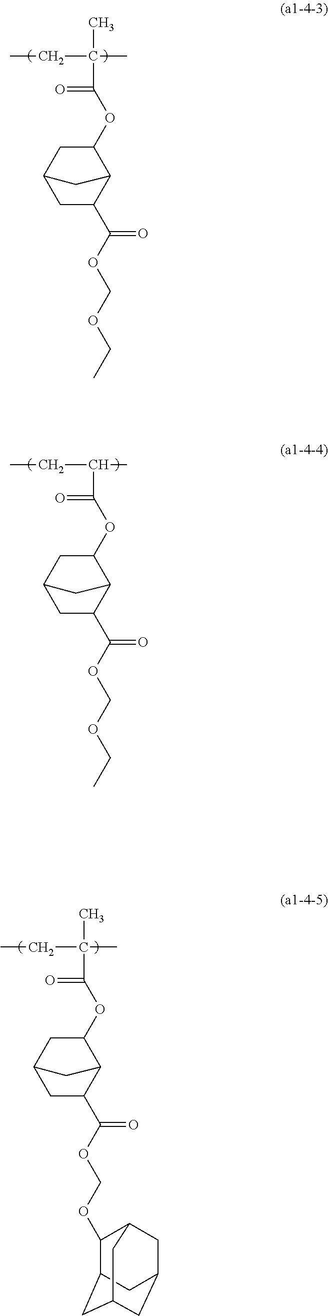

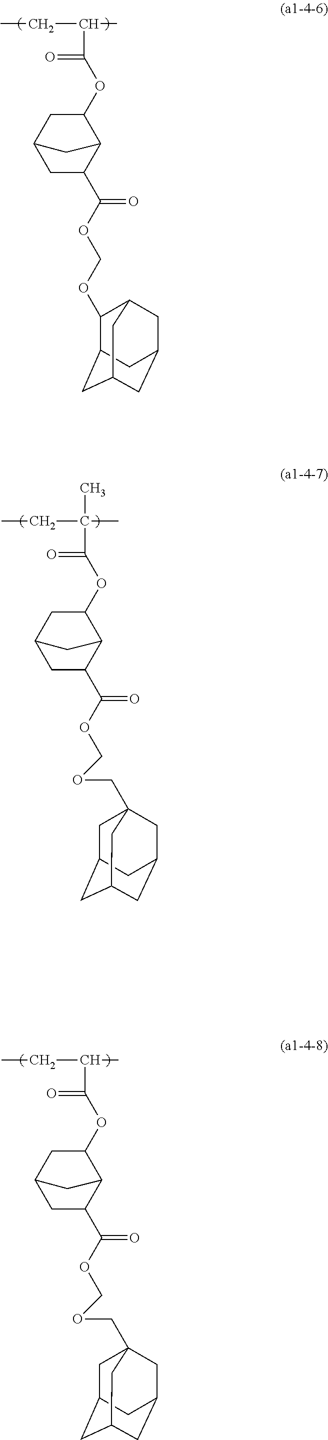

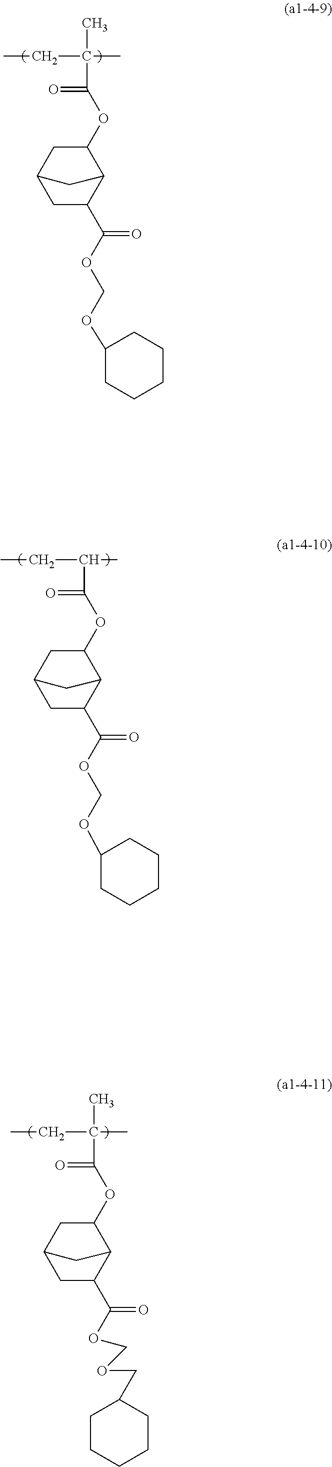

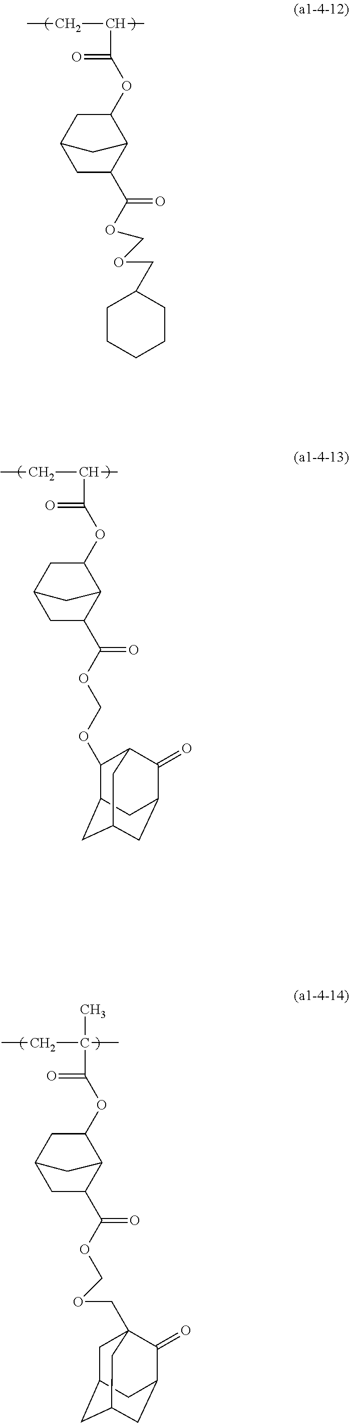

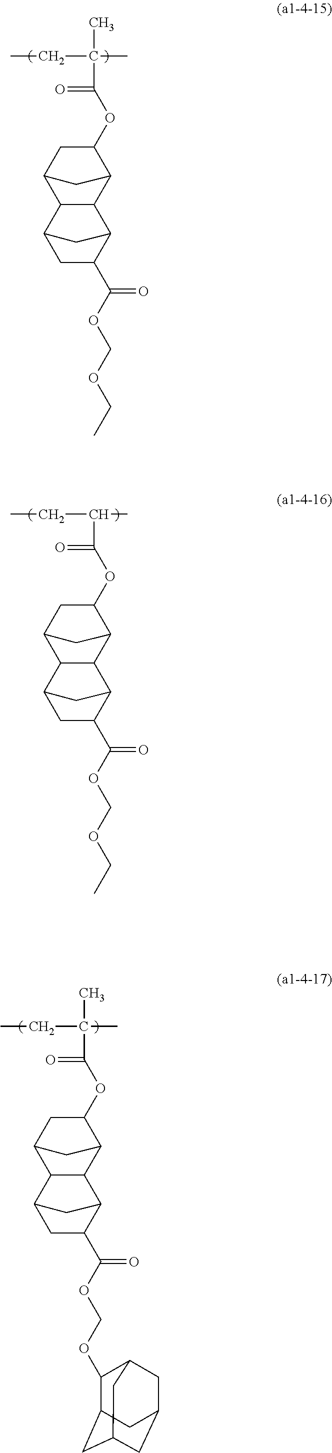

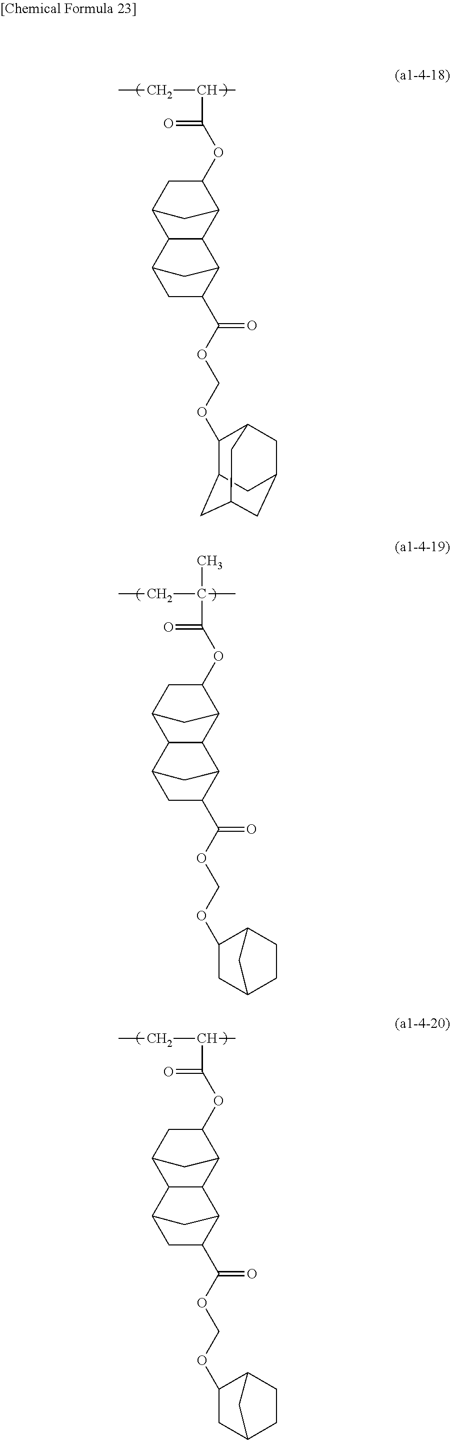

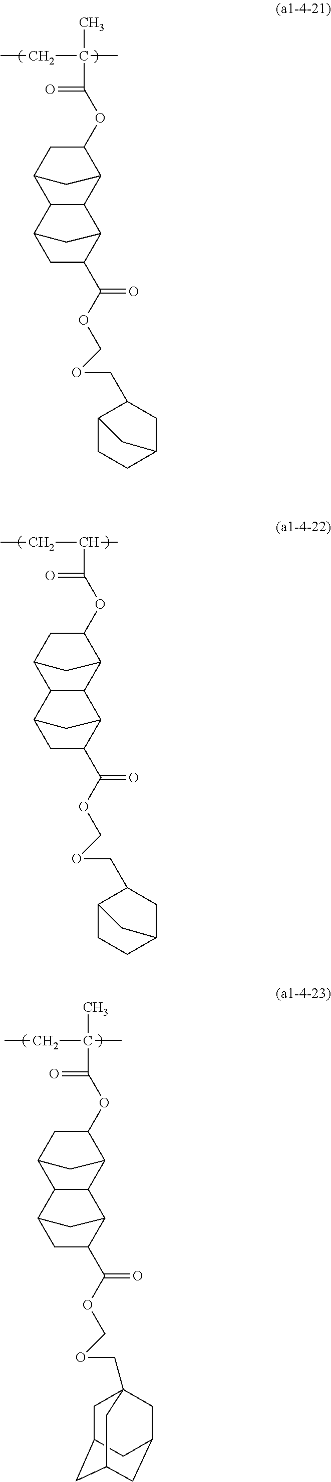

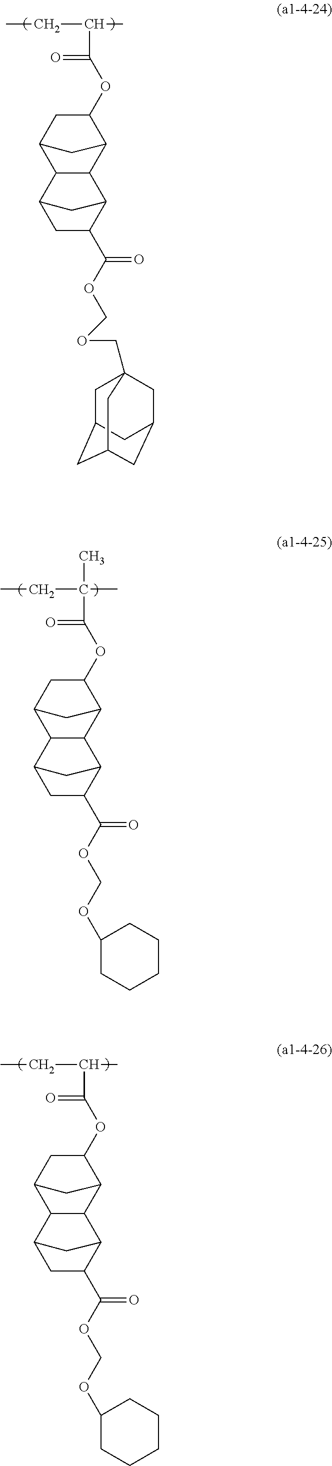

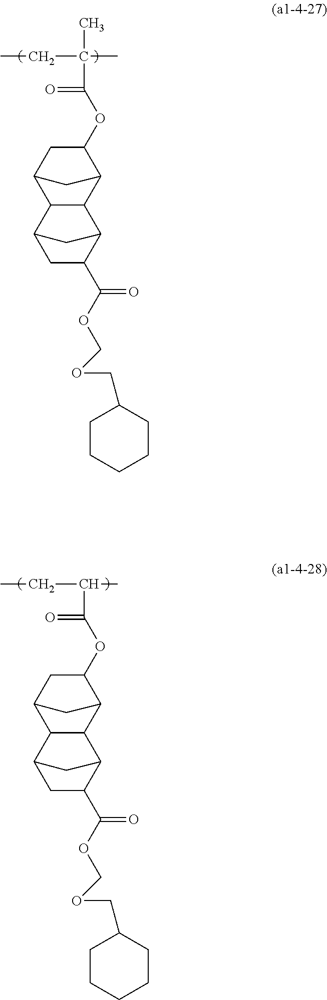

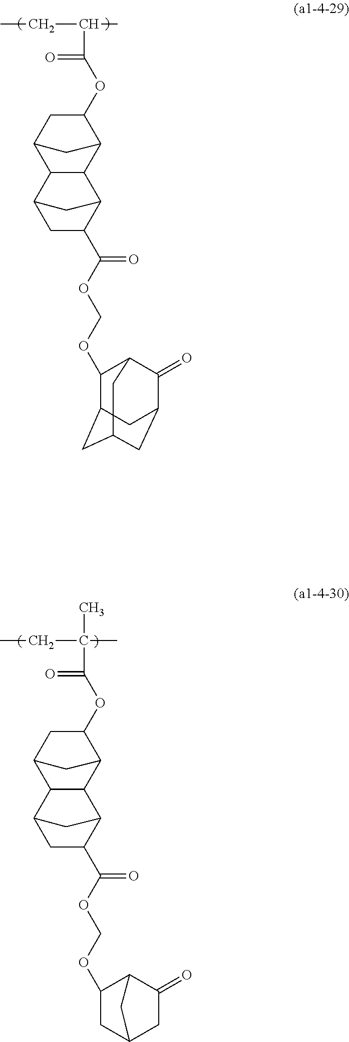

As the structural unit (a1), one type of structural unit may be used, or two or more types may be used in combination.

Among these, structural units represented by general formula (a1-1), (a1-2) or (a1-3) are preferable. More specifically, at least one structural unit selected from the group consisting of structural units represented by formulas (a1-1-1) to (a1-1-7), (a1-1-36) to (a1-1-42), (a1-1-47) to (a1-1-50), (a1-1-51) to (a1-1-54), (a1-2-3), (a1-2-4), (a1-2-9), (a1-2-10), (a1-2-13), (a1-2-14), (a1-2-17), (a1-2-18), (a1-2-20), (a1-2-21) to (a1-2-31), (a1-3-49) to (a1-3-56) and (a1-3-57) to (a1-3-58) is more preferable.

Further, as the structural unit (a1), structural units represented by general formula (a1-1-01) shown below which includes the structural units represented by formulas (a1-1-1) to (a1-1-5) and (a1-1-47) to (a1-1-50), structural units represented by general formula (a1-1-02) shown below which includes the structural units represented by formulas (a1-1-28), (a1-1-31) to (a1-1-34), (a1-1-36) to (a1-1-42) and (a1-1-51) to (a1-1-54), structural units represented by general formula (a1-2-01) shown below which includes the structural units represented by formulas (a1-2-3), (a1-2-4), (a1-2-9), (a1-2-10), (a1-2-13), (a1-2-14), (a1-2-17), (a1-2-18) and (a1-2-20), structural units represented by general formula (a1-2-02) shown below which includes the structural units represented by formulas (a1-2-21) to (a1-2-31), structural units represented by general formula (a1-3-01) shown below which include the structural units represented by formulas (a1-3-57) to (a1-3-58), structural units represented by general formula (a1-3-02) shown below which includes the structural units represented by general formulas (a1-3-59) and (a1-3-60), structural units represented by general formula (a1-3-03) shown below which includes the structural units represented by formulas (a1-3-49) to (a1-3-52), and structural units represented by general formula (a1-3-04) shown below which includes the structural units represented by formulas (a1-3-53) to (a1-3-56) are also preferable.

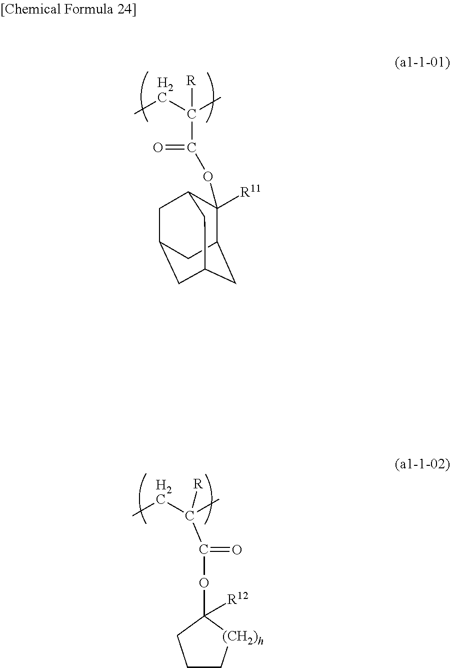

In general formula (a1-1-01), R represents a hydrogen atom, an alkyl group of 1 to 5 carbon atoms or a halogenated alkyl group of 1 to 5 carbon atoms; and R¹¹ represents an alkyl group of 1 to 5 carbon atoms. In general formula (a1-1-02), R is the same as defined above; R¹² represents an alkyl group of 1 to 5 carbon atoms; and h represents an integer of 1 to 6.

In general formula (a1-1-01), R is the same as defined above.

The alkyl group of 1 to 5 carbon atoms for R¹¹ is the same as defined for the alkyl group of 1 to 5 carbon atoms for R, and a methyl group, an ethyl group or an isopropyl group is preferable.

In general formula (a1-1-02), R is the same as defined above.

The alkyl group of 1 to 5 carbon atoms for R¹² is the same as defined for the alkyl group of 1 to 5 carbon atoms for R, and a methyl group, an ethyl group or an isopropyl group is preferable. j is preferably 1 or 2, and most preferably 2.

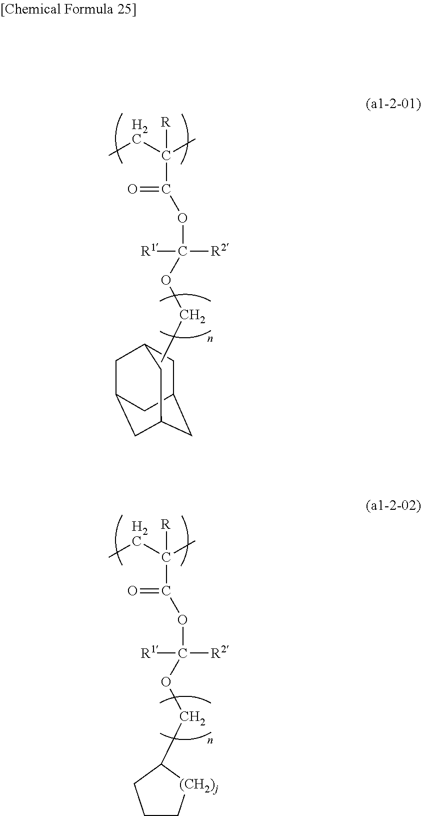

In formula (a1-2-01), R is the same as defined above; and R¹′, R²′ and n are respectively the same as defined above. In formula (a1-2-02), R, R²′ and n are respectively the same as R, R¹′, R²′ and n in formula (a1-2-01); and j represents an integer of 1 to 6.

In general formula (a1-2-01), R is the same as defined above.

R¹′ and R²′ each preferably independently represents a hydrogen atom, a methyl group, or an ethyl group, and more preferably a hydrogen atom or a methyl group, and it is particularly desirable that at least one of R¹′ and R²′ be a hydrogen atom.

n is preferably an integer of 0 to 2, more preferably 0 or 1, and most preferably 0.

In general formula (a1-2-02), R, R¹′, R²′ and n are respectively the same as R, R¹′, R²′ and n in general formula (a1-2-01).

j is preferably 1 or 2, and most preferably 2.

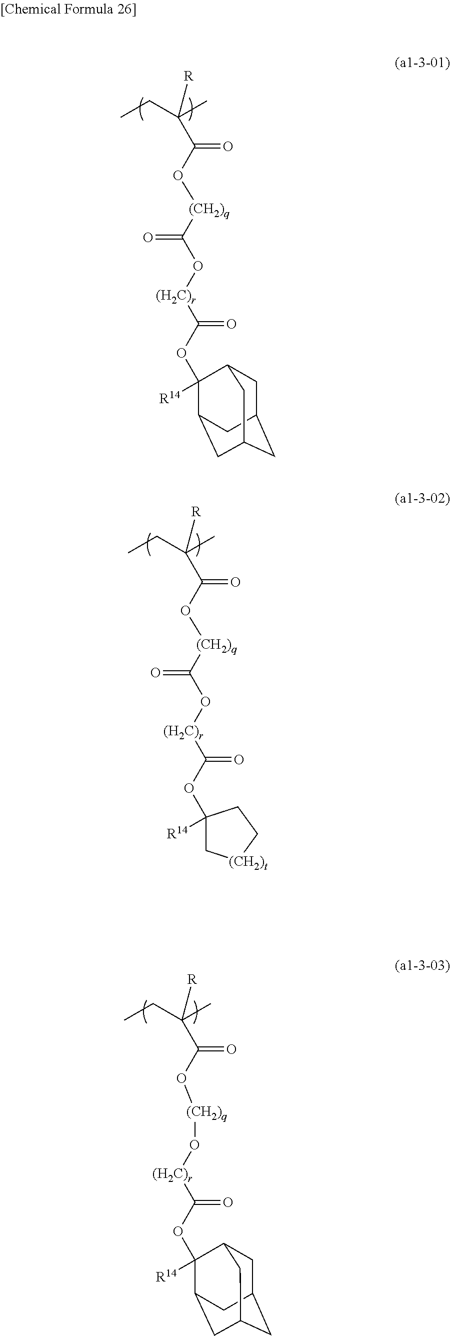

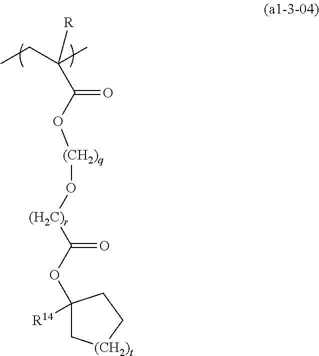

In formula (a1-3-01), R is the same as defined above; R¹⁴ represents an alkyl group of 1 to 5 carbon atoms; q represents an integer of 1 to 10; and r represents an integer of 1 to 10. In formula (a1-3-02), R, R¹⁴, q and r are respectively the same as R, R¹⁴, q and r in formula (a1-3-01); and t represents an integer of 1 to 6. In formula (a1-3-03), R, R¹⁴, q and r are respectively the same as R, R¹⁴, q and r in formula (a1-3-01). In formula (a1-3-04), R, R¹⁴, q, r and t are respectively the same as R, R¹⁴, q, r and t in formula (a1-3-02).

In general formulas (a1-3-01) and (a1-3-03), R is the same as defined above.

The alkyl group of 1 to 5 carbon atoms for R¹⁴ is the same as the alkyl group of 1 to 5 carbon atoms for R above, preferably a methyl group or an ethyl group, and more preferably a methyl group.

q represents an integer of 1 to 10, and is preferably an integer of 1 to 5, and particularly preferably an integer of 1 or 2.

r represents an integer of 1 to 10, and is preferably an integer of 1 to 5, and most preferably an integer of 1 or 2.

In general formulas (a1-3-02) and (a1-3-04), R, R¹⁴, q and r are respectively the same as R, R¹⁴, q and r in formula (a1-3-01).

t represents an integer of 1 to 6, and is preferably an integer of 1 to 4, and more preferably an integer of 1 or 2.

In the component (A1), the amount of the structural unit (a1) based on the combined total of all structural units constituting the component (A1) is preferably 20 to 80 mol %, more preferably 20 to 70 mol %, and still more preferably 25 to 50 mol %. When the amount of the structural unit (a1) is at least as large as the lower limit of the above-mentioned range, a pattern can be easily formed using a negative-tone development resist composition prepared from the component (A1). On the other hand, when the amount of the structural unit (a1) is no more than the upper limit of the above-mentioned range, a good balance can be achieved with the other structural units.

Structural Unit (a2)

The structural unit (a2) is at least one structural unit selected from the group consisting of a structural unit derived from an acrylate ester which contains a 4- to 12-membered, lactone-containing cyclic group and which may have an atom or a substituent other than hydrogen bonded to the carbon atom on the α-position, a structural unit derived from an acrylate ester which contains a 3- to 7-membered, ether-containing cyclic group and which may have an atom or a substituent other than hydrogen bonded to the carbon atom on the α-position, and a structural unit derived from an acrylate ester which contains a 5- to 7-membered, carbonate-containing cyclic group and which may have an atom or a substituent other than hydrogen bonded to the carbon atom on the α-position.

These cyclic compounds are subjected to ring-opening polymerization by using the specific photoacid generator described later. By the ring-opening polymerization, a guide pattern exhibiting excellent heat resistance and solvent resistance can be formed.

<<4- to 12-Membered Lactone-Containing Cyclic Group>>

As the structural unit (a2), a structural unit derived from an acrylate ester containing a 4- to 12-membered, lactone-containing cyclic group (hereafter, referred to as “structural unit (a2-i)”) is preferable.

The term “lactone-containing cyclic group” refers to a cyclic group including one ring containing a —O—C(O)— structure (lactone ring). The term “lactone ring” refers to a single ring containing a —O—C(O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings.

As the structural unit (a2-i), there is no particular limitation, and an arbitrary structural unit may be used.

Specific examples of lactone-containing monocyclic groups include a group in which one hydrogen atom has been removed from a 4- to 6-membered lactone ring, such as a group in which one hydrogen atom has been removed from β-propionolatone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

More specifically, examples of the structural unit (a2-i) include structural units represented by general formulas (a2-0) to (a2-5) shown below.

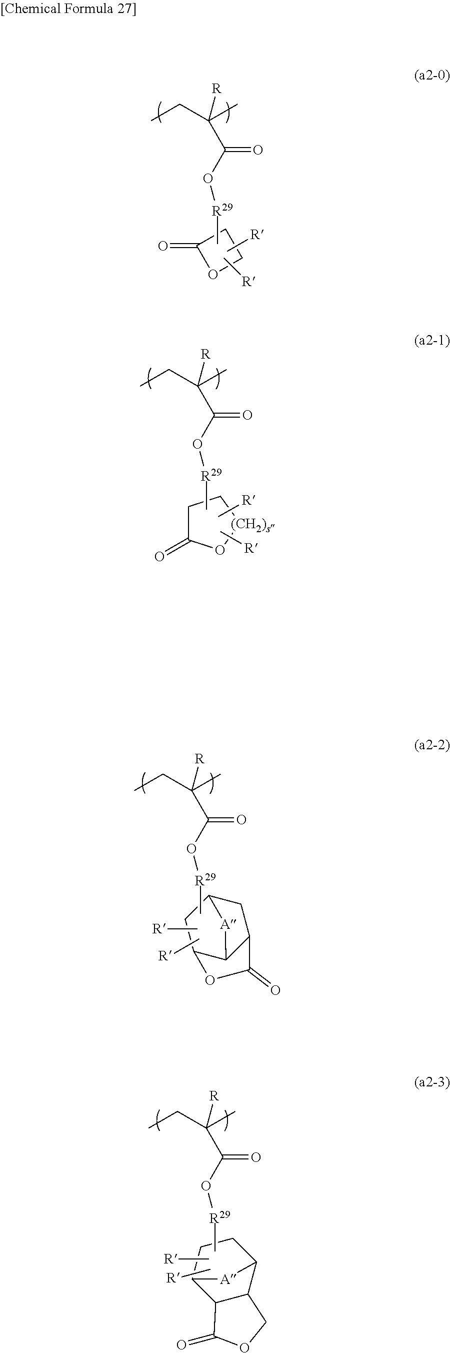

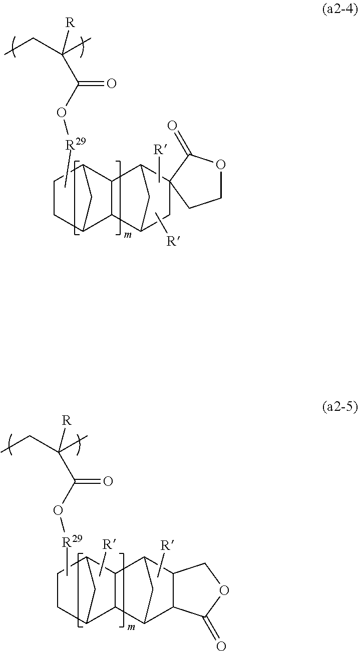

In the formulas, R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, a halogenated alkyl group of 1 to 5 carbon atoms, a cyano group, a hydroxy group, an alkoxy group of 1 to 5 carbon atoms or —COOR″; R²⁹ represents a single bond or a divalent linking group; s″ represents an integer of 0 to 2; A″ represents an oxygen atom, a sulfur atom or an alkylene group of 1 to 5 carbon atoms which may contain an oxygen atom or a sulfur atom; and m represents 0 or 1.

In general formulas (a2-0) to (a2-5), R is the same as defined for R in the structural unit (a1).

Examples of the alkyl group of 1 to 5 carbon atoms for R′ include a methyl group, an ethyl group, a propyl group, an n-butyl group and a tert-butyl group.

Examples of the alkoxy group of 1 to 5 carbon atoms for R′ include a methoxy group, an ethoxy group, an n-propoxy group, an iso-propoxy group, an n-butoxy group and a tert-butoxy group

The halogenated alkyl group of 1 to 5 carbon atoms for R′ is the same as defined above.

As A″, an alkylene group of 1 to 5 carbon atoms or —O— is preferable, more preferably an alkylene group of 1 to 5 carbon atoms, and most preferably a methylene group.

R²⁹ represents a single bond or a divalent linking group. Examples of divalent linking groups include the same divalent linking groups as those described above for Y² in general formula (a1-0-2). Among these, an alkylene group, an ester bond (—C(═O)—O—) or a combination thereof is preferable. The alkylene group as a divalent linking group for R²⁹ is preferably a linear or branched alkylene group. Specific examples include the same linear alkylene groups and branched alkylene groups as those described above for the aliphatic cyclic group A in Y².

s″ is preferably 1 or 2.

Specific examples of structural units represented by general formulas (a2-0) to (a2-5) are shown below. In the formulae shown below, R^{α} represents a hydrogen atom, a methyl group or a trifluoromethyl group.

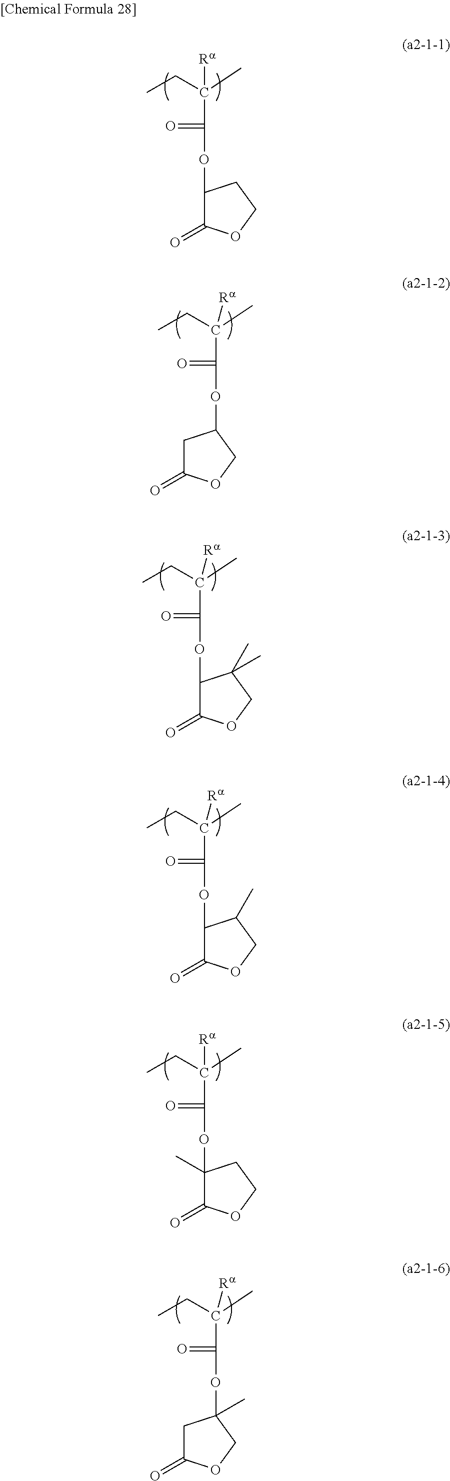

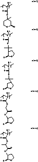

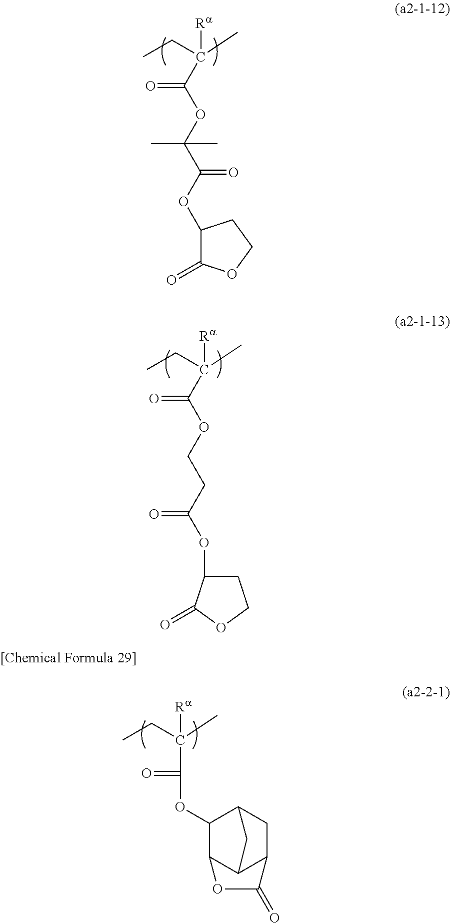

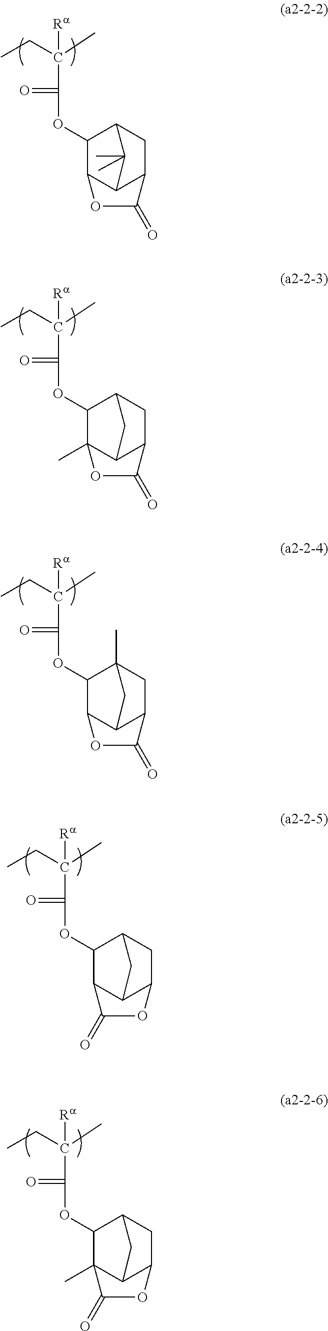

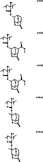

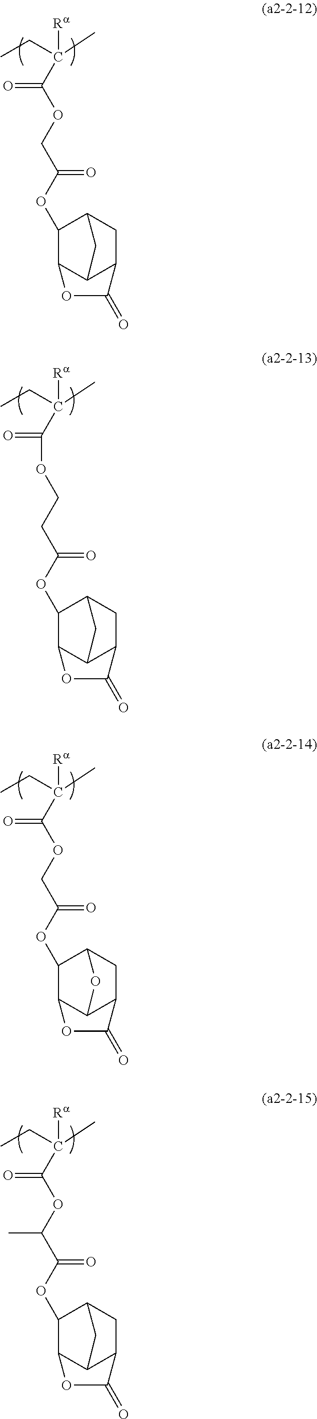

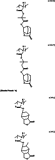

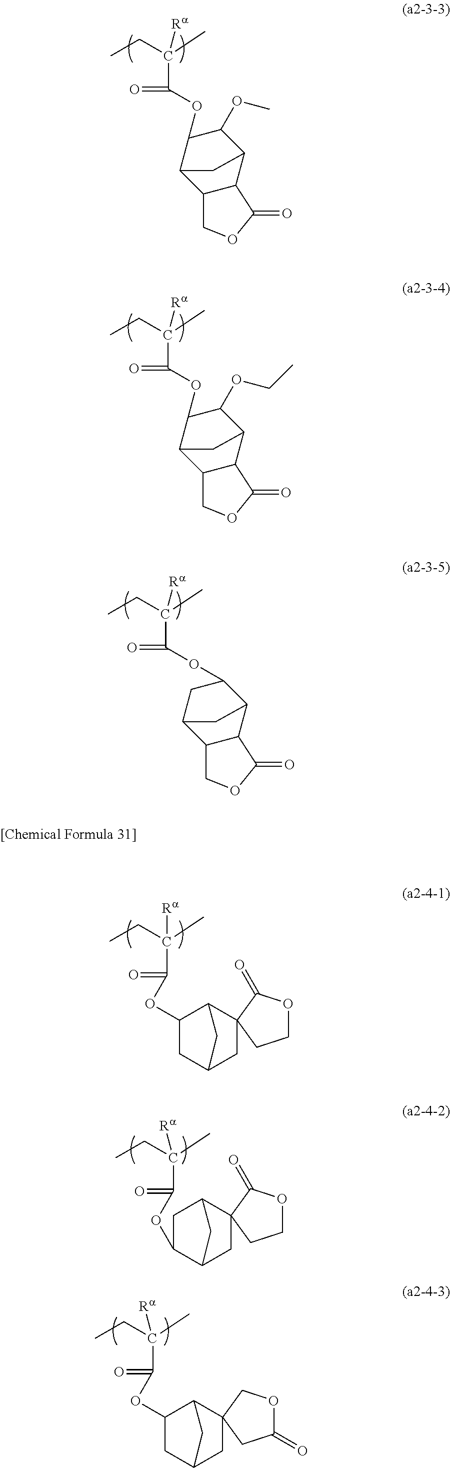

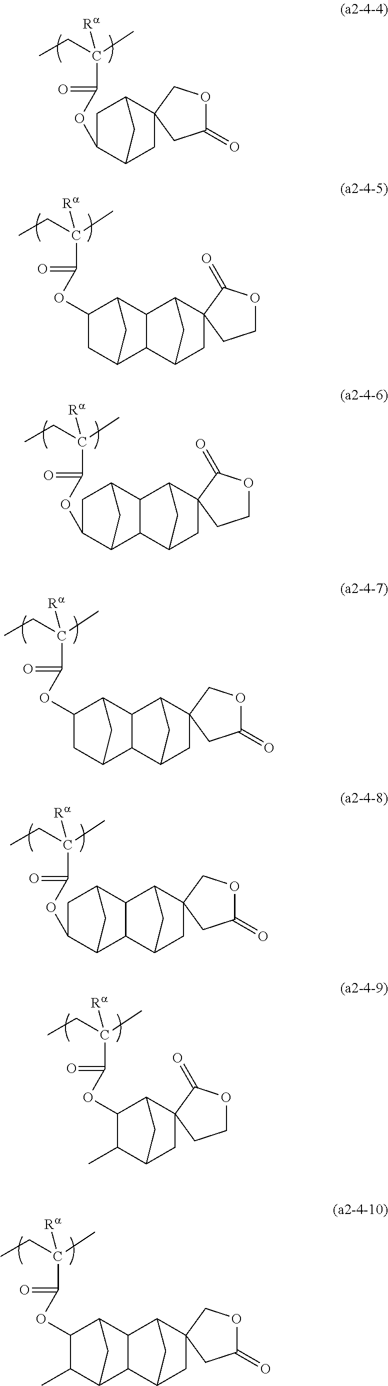

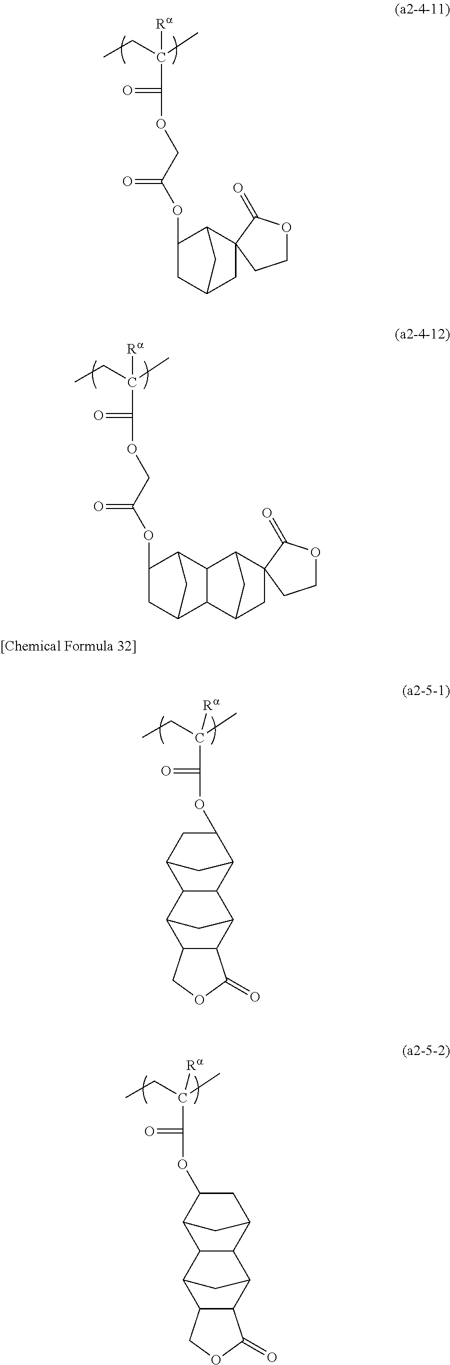

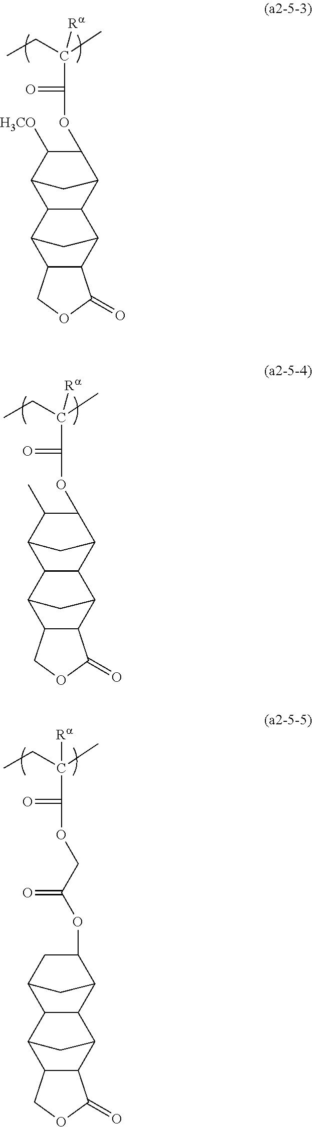

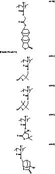

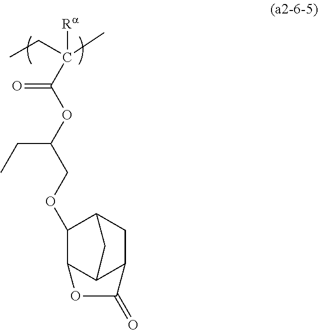

<<3- to 7-Membered Ether-Containing Cyclic Group>>

As the structural unit (a2), a structural unit derived from an acrylate ester containing a 3- to 7-membered, ether-containing cyclic group (hereafter, referred to as “structural unit (a2-ii)”) is preferable.

The term “ether-containing cyclic group” refers to a cyclic group including a structure in which a carbon atom of a cyclic hydrocarbon group has been replaced by an oxygen atom (cyclic ether). The cyclic ether is counted as the first ring. A cyclic ether in which the only ring structure is the cyclic ether is referred to as a monocyclic group, and groups containing other ring structures are described as polycyclic groups regardless of the structure of the other rings.

As the structural unit (a2-ii), there is no particular limitation, and an arbitrary structural unit may be used.

Specific examples of ether-containing cyclic groups include a group in which 1 hydrogen atom has been removed from a 3- to 7-membered cyclic ether, such as a group in which 1 hydrogen atom has been removed from epoxyethane, a group in which 1 hydrogen atom has been removed from oxetane, a group in which 1 hydrogen atom has been removed from tetrahydrofuran, or a group in which 1 hydrogen atom has been removed from tetrahydropyran. Further, specific examples of ether-containing polycyclic groups include groups in which one hydrogen atom has been removed from a cyclic ether-containing bicycloalkane, tricycloalkane or tetracycloalkane.

More specifically, examples of the structural unit (a2-ii) include structural units represented by general formulae (g2-1) to (a2-5) shown below.

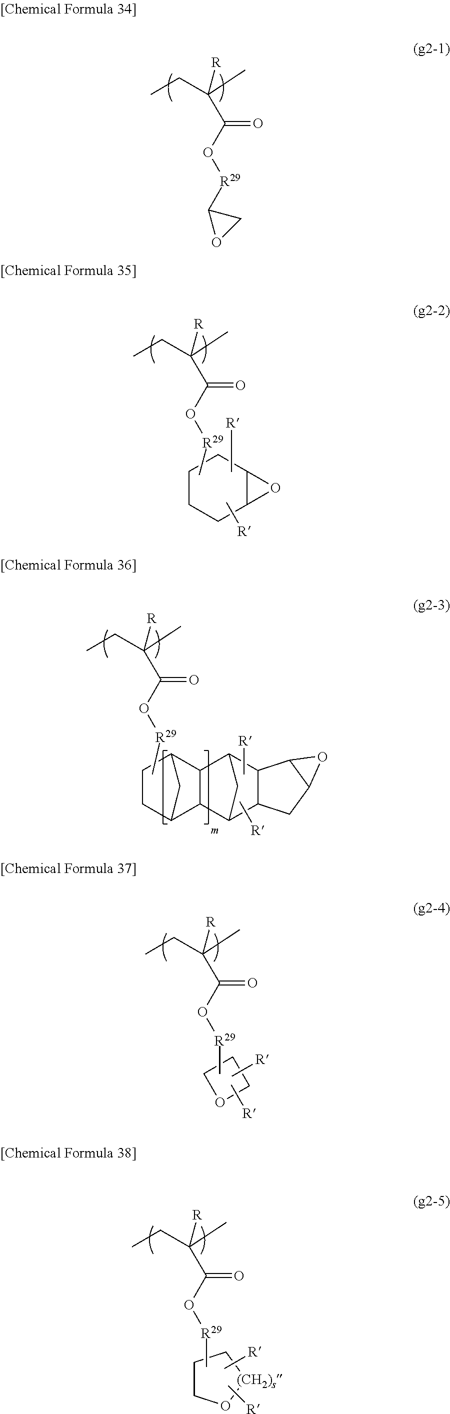

In the formulas, R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, a halogenated alkyl group of 1 to 5 carbon atoms, a cyano group, a hydroxy group, an alkoxy group of 1 to 5 carbon atoms or —COOR″; R²⁹ represents a single bond or a divalent linking group; s″ represents an integer of 0 to 2; and m represents 0 or 1.

In general formulae (g2-1) to (g2-5), R, R′, R²⁹, s″ and m are the same as defined for the aforementioned general formulae (a2-0) to (a2-5).

Specific examples of structural units represented by general formulas (g2-1) to (g2-5) are shown below. In the formulae shown below, R^{α} represents a hydrogen atom, a methyl group or a trifluoromethyl group.

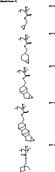

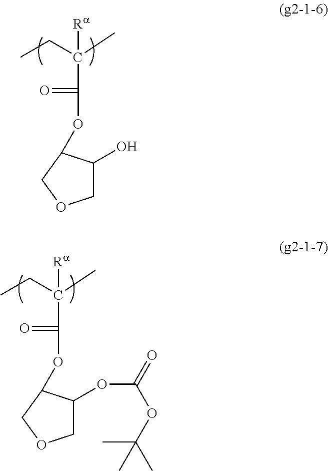

<<5- to 7-Membered Carbonate-Containing Cyclic Group>>

As the structural unit (a2), a structural unit derived from an acrylate ester containing a 5- to 7-membered, carbonate-containing cyclic group (hereafter, referred to as “structural unit (a2-iii)”) is preferable.

The term “carbonate-containing cyclic group” refers to a cyclic group including one ring containing a —O—C(═O)—O— structure (cyclic carbonate).

Specific examples of the structural unit (a2-iii) include a structural unit represented by general formula (g3-1) shown below.

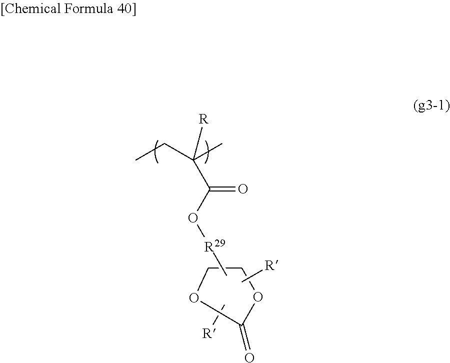

In the formulas, R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, a halogenated alkyl group of 1 to 5 carbon atoms, a cyano group, a hydroxy group, an alkoxy group of 1 to 5 carbon atoms or —COOR″; and R²⁹ represents a single bond or a divalent linking group; s″ represents an integer of 0 to 2.

In general formula (g3-1), R, R′ and R²⁹ are the same as defined for the aforementioned general formulae (a2-0) to (a2-5).

Specific examples of structural units represented by general formula (g3-1) are shown below. In the formulae shown below, R^{α} represents a hydrogen atom, a methyl group or a trifluoromethyl group.

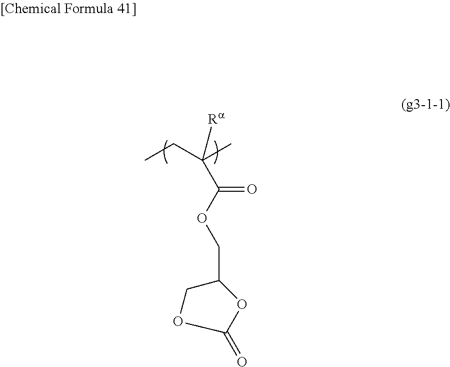

In the component (A1), as the structural unit (a2), one type of structural unit may be used, or two or more types may be used in combination.

As the structural unit (a2), at least one member selected from the group consisting of the aforementioned general formulae (a2-0) to (a2-3), (g2-1), (g2-2) and (g3-1) is preferable. Of these, it is preferable to use at least one structural unit selected from the group consisting of structural units represented by formulae (a2-1-1), (a2-2-1), (a2-3-1), (a2-6-1), (g2-1-1), (g2-1-2) and (g3-1-1).

In the component (A1), the amount of the structural unit (a2) based on the combined total of all structural units constituting the component (A1) is preferably 20 to 80 mol %, more preferably 20 to 70 mol %, and still more preferably 25 to 50 mol %. When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units.

Structural Unit (a0)

The structural unit (a0) is a structural unit derived from an acrylate ester containing an —SO₂— containing cyclic group which may have an atom or a substituent other than hydrogen bonded to the carbon atom on the α-position.

Here, an “—SO₂— containing cyclic group” refers to a cyclic group having a ring containing —SO₂— within the ring structure thereof, i.e., a cyclic group in which the sulfur atom (S) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂— containing cyclic group may be either a monocyclic group or a polycyclic group.

As the —SO₂— containing cyclic group, a cyclic group containing —O—SO₂— within the ring skeleton thereof, i.e., a cyclic group containing a sultone ring in which —O—S— within the —O—SO₂— group forms part of the ring skeleton thereof is particularly desirable.

The —SO₂— containing cyclic group preferably has 3 to 30 carbon atoms, more preferably 4 to 20, still more preferably 4 to 15, and most preferably 4 to 12. Herein, the number of carbon atoms refers to the number of carbon atoms constituting the ring skeleton, excluding the number of carbon atoms within a substituent.

The —SO₂— containing cyclic group may be either a —SO₂— containing aliphatic cyclic group or a —SO₂— containing aromatic cyclic group. A —SO₂— containing aliphatic cyclic group is preferable.

Examples of the —SO₂— containing aliphatic cyclic group include aliphatic cyclic groups in which part of the carbon atoms constituting the ring skeleton has been substituted with a —SO₂— group or a —O—SO₂— group and has at least one hydrogen atom removed from the aliphatic hydrocarbon ring. Specific examples include an aliphatic hydrocarbon ring in which a —CH₂— group constituting the ring skeleton thereof has been substituted with a —SO₂— group and has at least one hydrogen atom removed therefrom; and an aliphatic hydrocarbon ring in which a —CH₂—CH₂— group constituting the ring skeleton has been substituted with a —O—SO₂— group and has at least one hydrogen atom removed therefrom.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic group, a group in which two hydrogen atoms have been removed from a monocycloalkane of 3 to 6 carbon atoms is preferable. Examples of the monocycloalkane include cyclopentane and cyclohexane. As the polycyclic group, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The —SO₂— containing cyclic group may have a substituent. Examples of the substituent include an alkyl group, an alkoxy group, a halogen atom, a halogenated alkyl group, a hydroxy group, an oxygen atom (═O), —COOR″, —OC(═O)R″, a hydroxyalkyl group and a cyano group.

The alkyl group for the substituent is preferably an alkyl group of 1 to 6 carbon atoms. Further, the alkyl group is preferably a linear alkyl group or a branched alkyl group. Specific examples include a methyl group, an ethyl group, a propyl group, an isopropyl group, an n-butyl group, an isobutyl group, a tert-butyl group, a pentyl group, an isopentyl group, a neopentyl group and a hexyl group. Among these, a methyl group or ethyl group is preferable, and a methyl group is particularly desirable.

As the alkoxy group for the substituent, an alkoxy group of 1 to 6 carbon atoms is preferable. Further, the alkoxy group is preferably a linear or branched alkoxy group. Specific examples of the alkoxy group include the aforementioned alkyl groups for the substituent having an oxygen atom (—O—) bonded thereto.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

As examples of the halogenated alkyl group for the substituent, groups in which part or all of the hydrogen atoms of the aforementioned alkyl groups for the substituent have been substituted with the aforementioned halogen atoms can be given. As the halogenated alkyl group, a fluorinated alkyl group is preferable, and a perfluoroalkyl group is particularly desirable.

In the —COOR″ group and the —OC(═O)R″ group, R″ represents a hydrogen atom or a linear, branched or cyclic alkyl group of 1 to 15 carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The hydroxyalkyl group for the substituent preferably has 1 to 6 carbon atoms, and specific examples thereof include the aforementioned alkyl groups for the substituent in which at least one hydrogen atom has been substituted with a hydroxy group.

More specific examples of the —SO₂— containing cyclic group include groups represented by general formulas (3-1) to (3-4) shown below.

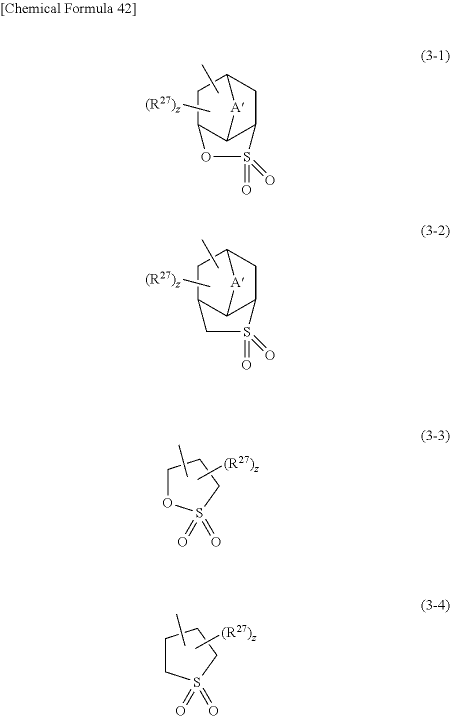

In the formulas, A′ represents an oxygen atom, a sulfur atom or an alkylene group of 1 to 5 carbon atoms which may contain an oxygen atom or a sulfur atom; z represents an integer of 0 to 2; and R²⁷ represents an alkyl group, an alkoxy group, a halogenated alkyl group, a hydroxyl group, —COOR″, —OC(═O)R″, a hydroxyalkyl group or a cyano group, wherein R″ represents a hydrogen atom or an alkyl group.

In general formulas (3-1) to (3-4) above, A′ represents an oxygen atom (—O—), a sulfur atom (—S—) or an alkylene group of 1 to 5 carbon atoms which may contain an oxygen atom or a sulfur atom.

As the alkylene group of 1 to 5 carbon atoms represented by A′, a linear or branched alkylene group is preferable, and examples thereof include a methylene group, an ethylene group, an n-propylene group and an isopropylene group.

Examples of alkylene groups that contain an oxygen atom or a sulfur atom include the aforementioned alkylene groups in which —O— or —S— is bonded to the terminal of the alkylene group or present between the carbon atoms of the alkylene group. Specific examples of such alkylene groups include —O—CH₂—, —CH₂—O—CH₂—, —S—CH₂—, —CH₂—S—CH₂—.

As A′, an alkylene group of 1 to 5 carbon atoms or —O— is preferable, more preferably an alkylene group of 1 to 5 carbon atoms, and most preferably a methylene group.

z represents an integer of 0 to 2, and is most preferably 0.

When z is 2, the plurality of R²⁷ may be the same or different from each other.

As the alkyl group, alkoxy group, halogenated alkyl group, —COOR″, —OC(═O)R″ and hydroxyalkyl group for R²⁷, the same alkyl groups, alkoxy groups, halogenated alkyl groups, —COOR″, —OC(═O)R″ and hydroxyalkyl groups as those described above as the substituent for the —SO₂— containing cyclic group can be mentioned.

Specific examples of the cyclic groups represented by general formulas (3-1) to (3-4) are shown below. In the formulas shown below, “Ac” represents an acetyl group.

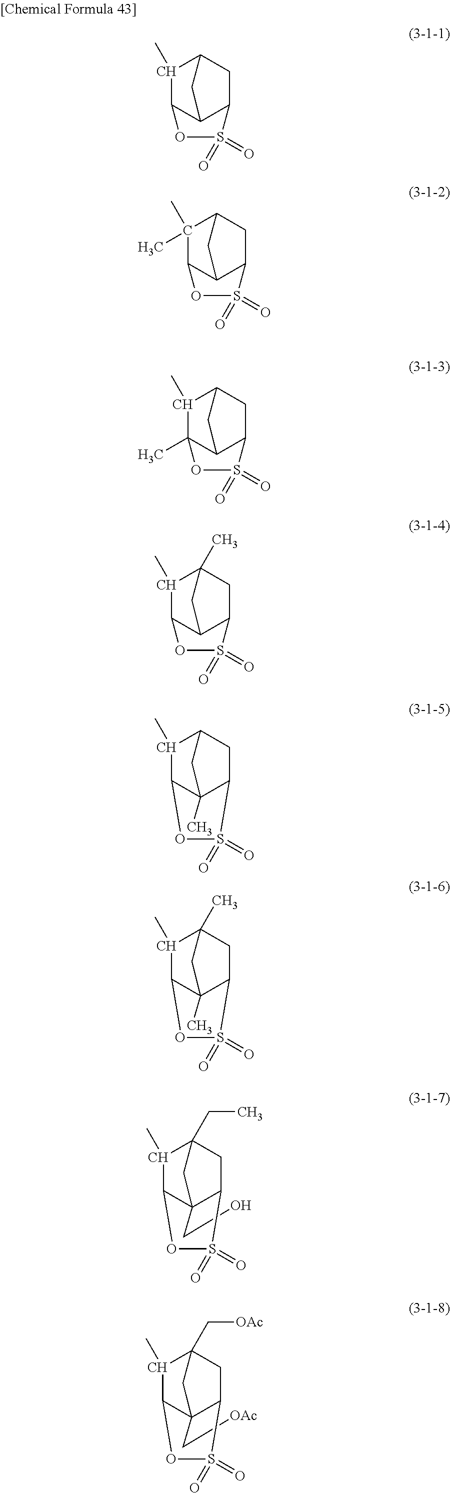

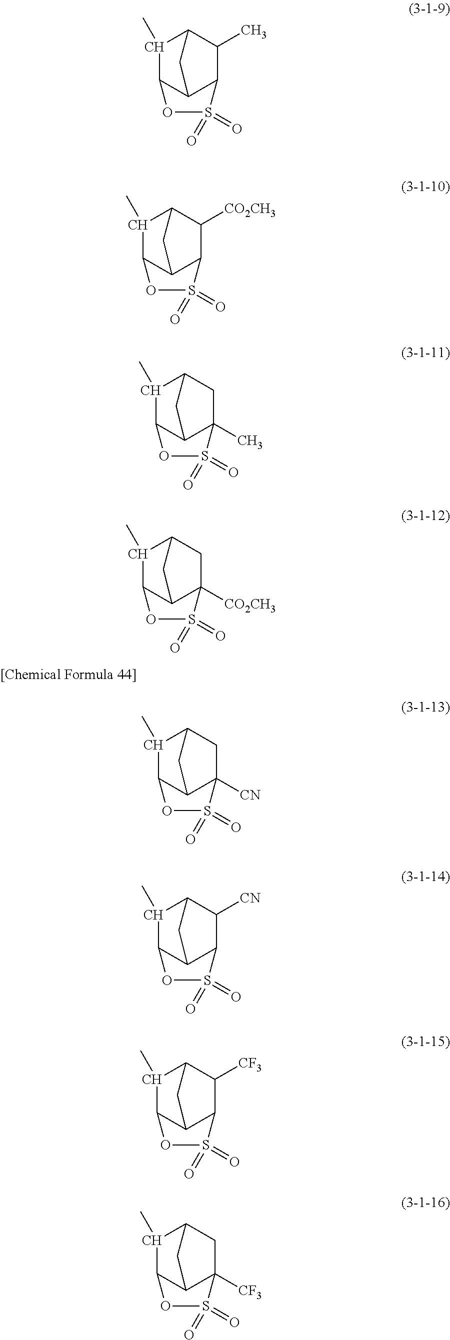

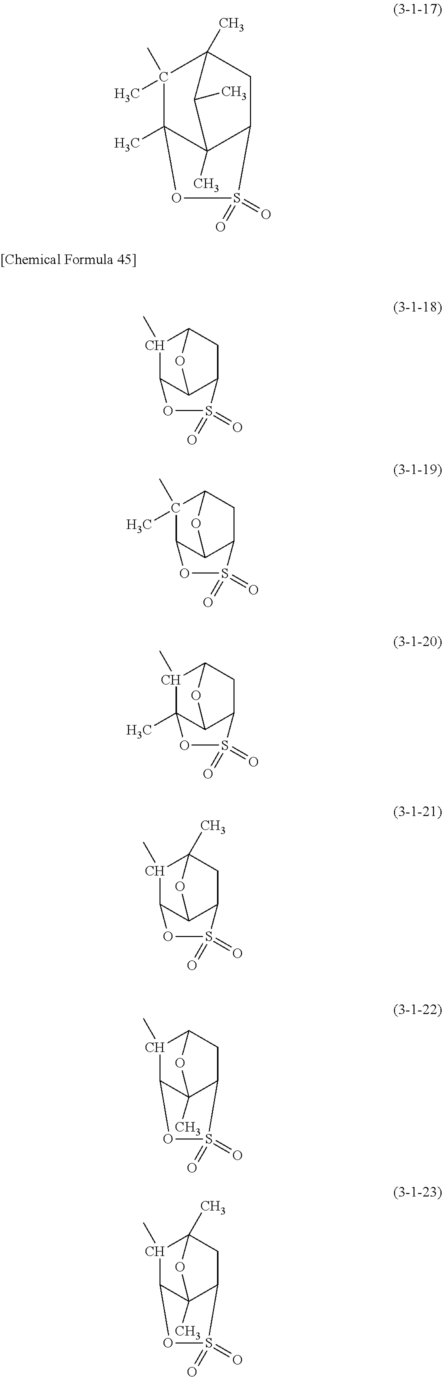

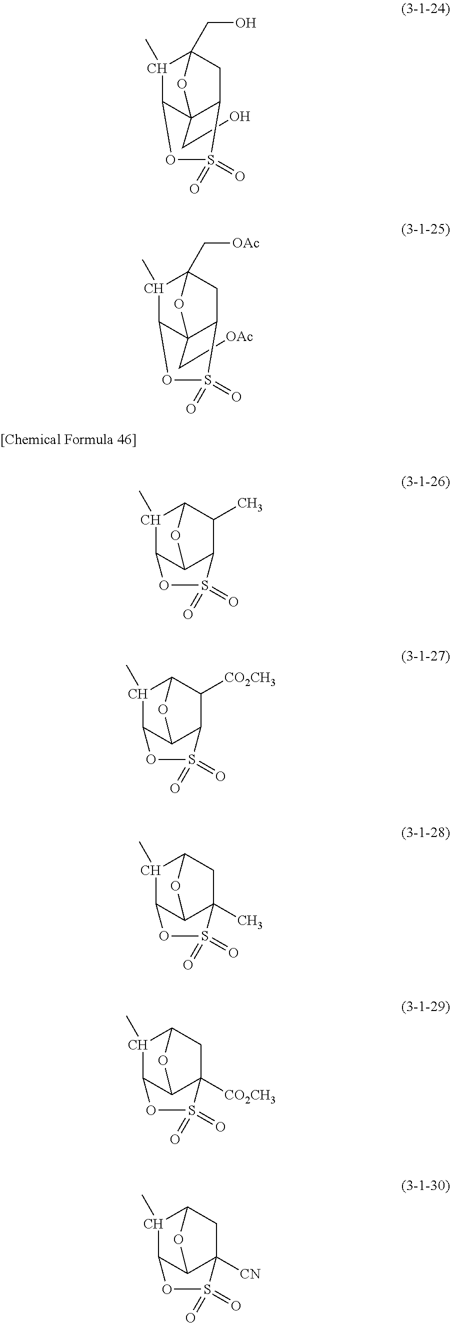

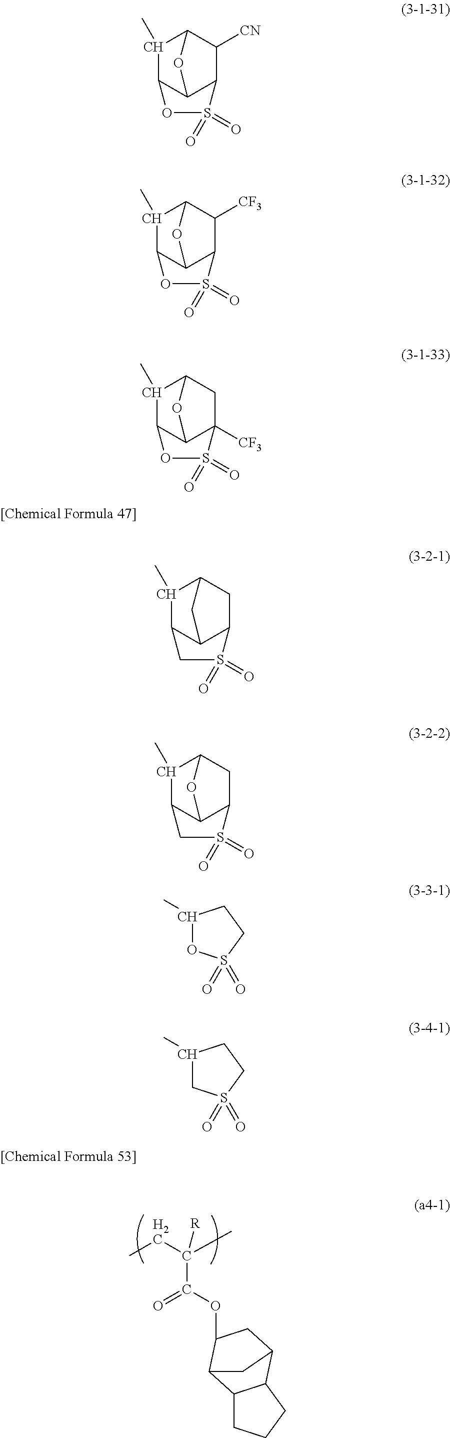

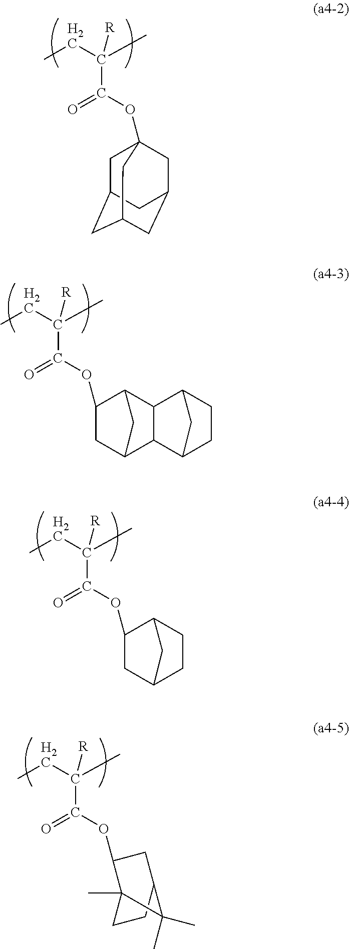

As the —SO₂— containing cyclic group, a group represented by the aforementioned general formula (3-1) is preferable, at least one member selected from the group consisting of groups represented by the aforementioned chemical formulas (3-1-1), (3-1-18), (3-3-1) and (3-4-1) is more preferable, and a group represented by chemical formula (3-1-1) is most preferable.

More specifically, examples of the structural unit (a0) include structural units represented by general formula (a0-0) shown below.

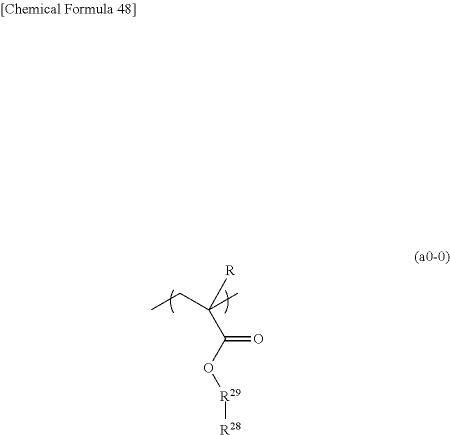

In the formula, R represents a hydrogen atom, an alkyl group of 1 to 5 carbon atoms or a halogenated alkyl group of 1 to 5 carbon atoms; R²⁸ represents a —SO₂— containing cyclic group; and R²⁹ represents a single bond or a divalent linking group.

In genera formula (a0-0), R is the same as defined above.

R²⁸ is the same as defined for the aforementioned —SO₂— containing group.

R²⁹ may be either a single bond or a divalent linking group. In terms of the effects of the present invention, a divalent linking group is preferable.

The divalent linking group for R²⁹ is not particularly limited. For example, the same divalent linking groups as those described for Y² in general formula (a1-0-2) explained above in relation to the structural unit (a1) can be mentioned. Among these, an alkylene group or a divalent linking group containing an ester bond (—C(═O)—O—) is preferable.

As the alkylene group, a linear or branched alkylene group is preferable. Specific examples include the same linear alkylene groups and branched alkylene groups as those described above for the aliphatic hydrocarbon group represented by Y².

As the divalent linking group containing an ester bond, a group represented by general formula: —R³⁰—C(═O)—O— (in the formula, R³⁰ represents a divalent linking group) is particularly desirable. Namely, the structural unit (a0) is preferably a structural unit represented by general formula (a0-0-1) shown below.

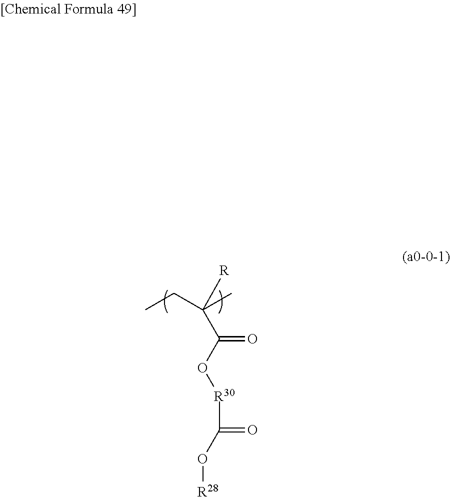

In the formula, R and R²⁸ are the same as defined above; and R³⁰ represents a divalent linking group.

R³⁰ is not particularly limited. For example, the same divalent linking groups as those described for Y² in general formula (a1-0-2) explained above in relation to the structural unit (a1) can be mentioned.

As the divalent linking group for R³⁰, an alkylene group, a divalent alicyclic hydrocarbon group or a divalent linking group containing a hetero atom is preferable.

As the linear or branched alkylene group, the divalent alicyclic hydrocarbon group and the divalent linking group containing a hetero atom, the same linear or branched alkylene group, divalent alicyclic hydrocarbon group and divalent linking group containing a hetero atom as those described above as preferable examples of Y² can be mentioned.

Among these, a linear or branched alkylene group, or a divalent linking group containing an oxygen atom as a hetero atom is more preferable.

As the linear alkylene group, a methylene group or an ethylene group is preferable, and a methylene group is particularly desirable.

As the branched alkylene group, an alkylmethylene group or an alkylethylene group is preferable, and —CH(CH₃)—, —C(CH₃)₂— or —C(CH₃)₂CH₂— is particularly desirable.

As the divalent linking group containing a hetero atom, a divalent linking group containing an ether bond or an ester bond is preferable, and a group represented by the aforementioned formula -A-O—B—, -[A-C(═O)—O]ₘ—B— or -A-O—C(═O)—B— is more preferable.

Among these, a group represented by the formula -A-O—C(═O)—B— is preferable, and a group represented by the formula: —(CH₂)_{c}—C(═O)—O—(CH₂)_{d}— is particularly desirable. c represents an integer of 1 to 5, and preferably 1 or 2. d represents an integer of 1 to 5, and preferably 1 or 2.

In particular, as the structural unit (a0), a structural unit represented by general formula (a0-1-11) or (a0-1-12) shown below is preferable, and a structural unit represented by general formula (a0-1-12) is more preferable.

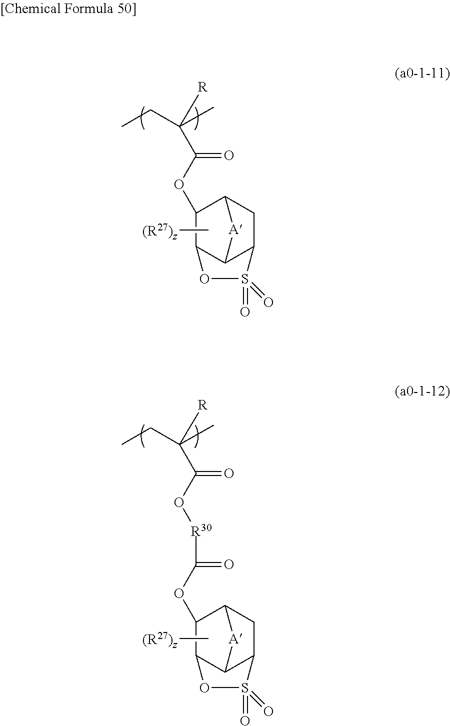

In the formulas, R, A′, R²⁷, z and R³⁰ are the same as defined above.

In general formula (a0-1-11) A′ is preferably a methylene group, an oxygen atom (—O—) or a sulfur atom (—S—).

As R³⁰, a linear or branched alkylene group or a divalent linking group containing an oxygen atom is preferable. As the linear or branched alkylene group and the divalent linking group containing an oxygen atom represented by R³⁰, the same linear or branched alkylene groups and the divalent linking groups containing an oxygen atom as those described above can be mentioned.

As the structural unit represented by general formula (a0-1-12), a structural unit represented by general formula (a0-1-12a) or (a0-1-12b) shown below is particularly desirable.

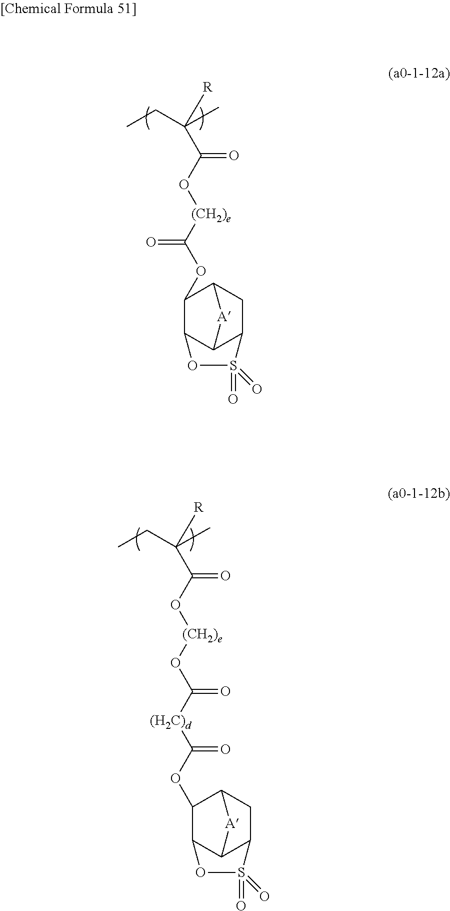

In the formulas, R and A′ are the same as defined above; and each of c to e independently represents an integer of 1 to 3.

In the component (A1), the amount of the structural unit (a0) based on the combined total of all structural units constituting the component (A1) is preferably 1 to 80 mol %, more preferably 10 to 70 mol %, still more preferably 10 to 65 mol %, and most preferably 10 to 60 mol %. When the amount of the structural unit (a0) is at least as large as the lower limit of the above-mentioned range, the effect of using the structural unit (a0) can be satisfactorily achieved. On the other hand, when the amount of the structural unit (a0) is no more than the upper limit of the above-mentioned range, a good balance can be achieved with the other structural units, and various lithography properties such as DOF and CDU and pattern shape can be improved.

Structural Unit (a3)

The structural unit (a3) is a structural unit derived from an acrylate ester containing a polar group-containing aliphatic hydrocarbon group which may have an atom or a substituent other than hydrogen bonded to the carbon atom on the α-position.

When the component (A1) includes the structural unit (a3), the hydrophilicity of the component (A) is improved, and hence, the compatibility of the component (A) with the developing solution is improved. As a result, the alkali solubility of the exposed portions improves, which contributes to favorable improvements in the resolution.

Examples of the polar group include a hydroxyl group, cyano group, carboxyl group, or hydroxyalkyl group in which part of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and polycyclic aliphatic hydrocarbon groups (polycyclic groups). These polycyclic groups can be selected appropriately from the multitude of groups that have been proposed for the resins of resist compositions designed for use with ArF excimer lasers. The polycyclic group preferably has 7 to 30 carbon atoms.

Of the various possibilities, structural units derived from an acrylate ester that include an aliphatic polycyclic group that contains a hydroxyl group, cyano group, carboxyl group or a hydroxyalkyl group in which part of the hydrogen atoms of the alkyl group have been substituted with fluorine atoms are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

When the aliphatic hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid. On the other hand, when the hydrocarbon group is a polycyclic group, structural units represented by formulas (a3-1), (a3-2) and (a3-3) shown below are preferable.

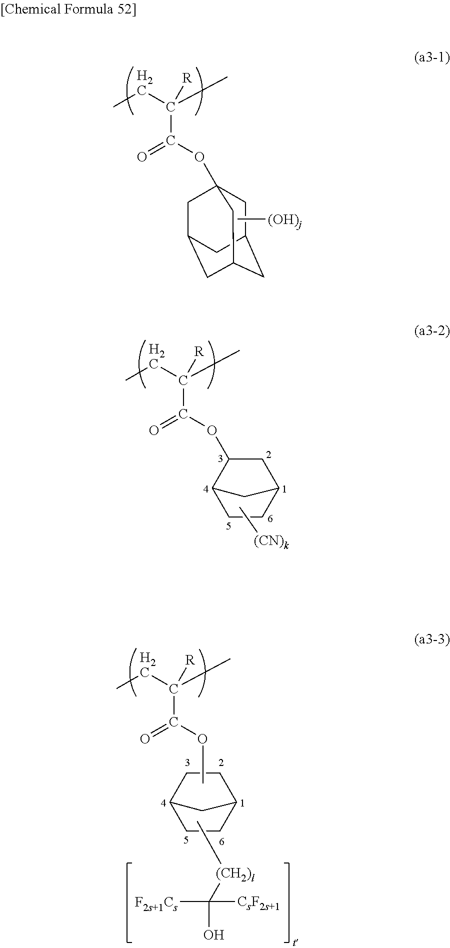

In the formulas, R is the same as defined above; j represents an integer of 1 to 3; k represents an integer of 1 to 3; t′ represents an integer of 1 to 3; 1 represents an integer of 1 to 5; and s represents an integer of 1 to 3.

In formula (a3-1), j is preferably 1 or 2, and more preferably 1. When j is 2, it is preferable that the hydroxyl groups be bonded to the 3rd and 5th positions of the adamantyl group. When j is 1, it is preferable that the hydroxyl group be bonded to the 3rd position of the adamantyl group.

In formula (a3-2), k is preferably 1. The cyano group is preferably bonded to the 5th or 6th position of the norbornyl group.

In formula (a3-3), t′ is preferably 1. l is preferably 1. s is preferably 1. Further, in formula (a3-3), it is preferable that a 2-norbornyl group or 3-norbornyl group be bonded to the terminal of the carboxy group of the acrylic acid. The fluorinated alkyl alcohol is preferably bonded to the 5th or 6th position of the norbornyl group.

In the component (A1), as the structural unit (a3), one type of structural unit may be used, or two or more types may be used in combination.

In the component (A1), the amount of the structural unit (a3) based on the combined total of all structural units constituting the component (A1) is preferably 5 to 50 mol %, more preferably 5 to 40 mol %, and still more preferably 5 to 25 mol %. When the amount of the structural unit (a3) is at least as large as the lower limit of the above-mentioned range, the effect of using the structural unit (a3) can be satisfactorily achieved. On the other hand, when the amount of the structural unit (a3) is no more than the upper limit of the above-mentioned range, a good balance can be achieved with the other structural units.

Structural Unit (a4)

The component (A1) may also have a structural unit (a4) which is other than the above-mentioned structural units (a0) to (a3), as long as the effects of the present invention are not impaired.

As the structural unit (a4), any other structural unit which cannot be classified as one of the above structural units (a0) to (a3) can be used without any particular limitation, and any of the multitude of conventional structural units used within resist resins for ArF excimer lasers or KrF excimer lasers (and particularly for ArF excimer lasers) can be used.

As the structural unit (a4), a structural unit which contains a non-acid-dissociable aliphatic polycyclic group, and is also derived from an acrylate ester is preferable. Examples of this polycyclic group include the same groups as those described above in relation to the aforementioned structural unit (a1), and any of the multitude of conventional polycyclic groups used within the resin component of resist compositions for ArF excimer lasers or KrF excimer lasers (and particularly for ArF excimer lasers) can be used.

In consideration of industrial availability and the like, at least one polycyclic group selected from amongst a tricyclodecyl group, adamantyl group, tetracyclododecyl group, isobornyl group, and norbornyl group is particularly desirable. These polycyclic groups may be substituted with a linear or branched alkyl group of 1 to 5 carbon atoms.

Specific examples of the structural unit (a4) include units with structures represented by general formulas (a4-1) to (a4-5) shown below.

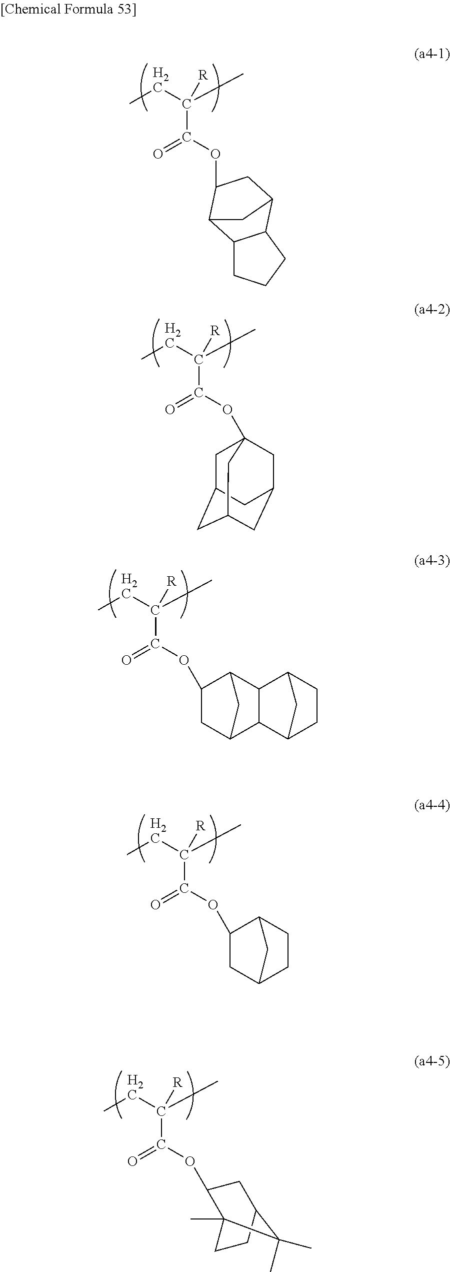

In the formulas, R is the same as defined above.

When the structural unit (a4) is included in the component (A1), the amount of the structural unit (a4) based on the combined total of all the structural units that constitute the component (A1) is preferably within the range from 1 to 30 mol %, and more preferably from 10 to 20 mol %.

In the negative-tone development resist composition, examples of the component (A1) include a copolymer including the structural units (a1) and (a2); a copolymer including the structural units (a1), (a2) and (a0); a copolymer including the structural units (a1), (a2) and (a3); and a copolymer including the structural units (a1), (a2) and (a4).

In the negative-tone development resist composition, as the component (A1), a resin that includes a combination of structural units such as that shown below is particularly desirable.

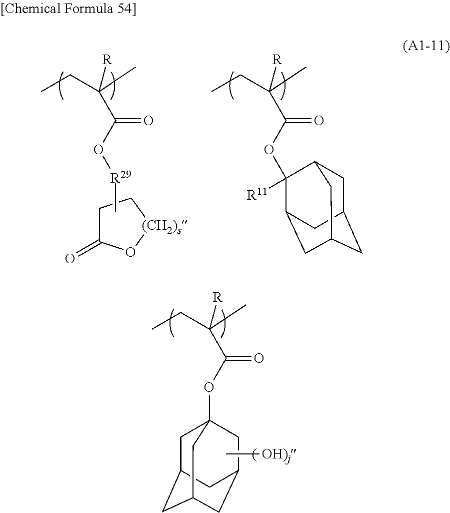

In the formula, R, R¹¹, R²⁹, s″ and j″ are the same as defined above, and the plurality of R may be the same or different from each other.

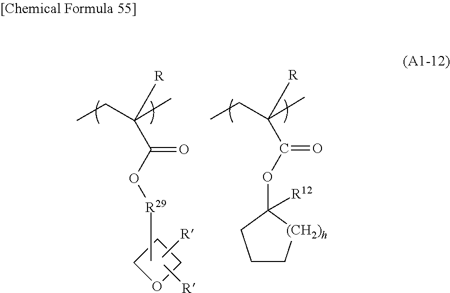

In the formula, R, R′, R¹², R²⁹ and h are the same as defined above, and the plurality of R may be the same or different from each other.

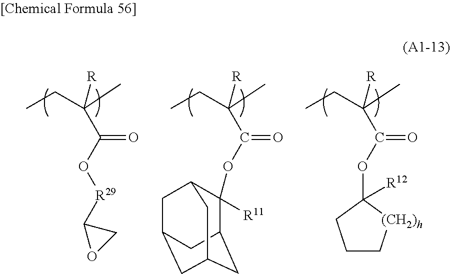

In the formula, R, R¹¹, R¹², R²⁹ and h are the same as defined above, and the plurality of R may be the same or different from each other.

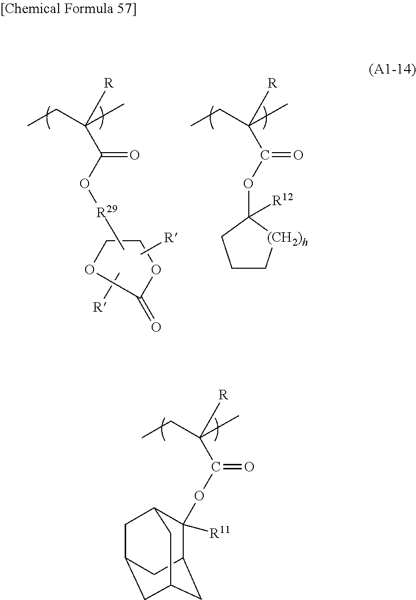

In the formula, R, R′, R¹¹, R¹², R²⁹ and h are the same as defined above, and the plurality of R may be the same or different from each other.

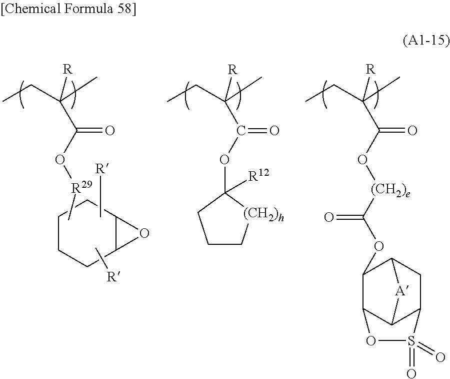

In the formula, R, R′, R¹², R²⁹, h, A′ and e are the same as defined above, and the plurality of R may be the same or different from each other.

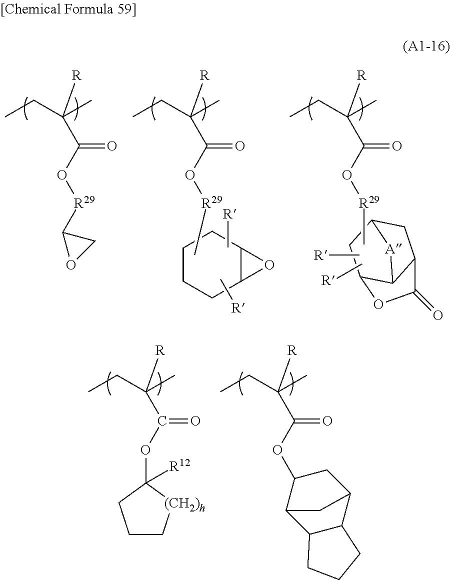

In the formula, R, R′, R¹², R²⁹, h and A″ are the same as defined above, and the plurality of R may be the same or different from each other.

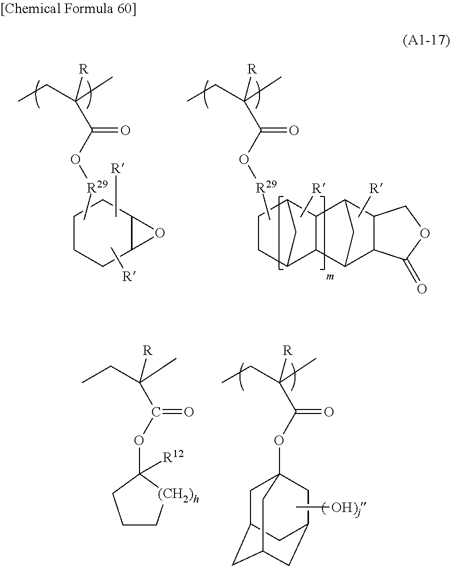

In the formula, R, R′, R¹², R²⁹, h and j″ are the same as defined above, and the plurality of R may be the same or different from each other.

The component (A1) can be obtained, for example, by a conventional radical polymerization or the like of the monomers corresponding with each of the structural units, using a radical polymerization initiator such as azobisisobutyronitrile (AIBN) or dimethyl 2,2′-azobis(isobutyrate).

Furthermore, in the component (A1), by using a chain transfer agent such as HS—CH₂—CH₂—CH₂—C(CF₃)₂—OH, a —C(CF₃)₂—OH group can be introduced at the terminals of the component (A1). Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern).

The weight average molecular weight (Mw) (the polystyrene equivalent value determined by gel permeation chromatography) of the component (A1) is not particularly limited, but is preferably 1,000 to 50,000, more preferably 1,500 to 30,000, and most preferably 2,500 to 20,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) is preferably 1.0 to 5.0, more preferably 1.0 to 3.0, and most preferably 1.2 to 2.5. Here, Mn is the number average molecular weight.

In the negative-tone development resist composition, the amount of the component (A1) can be appropriately adjusted depending on the thickness of the resist film to be formed, and the like.

In the component (A), as the component (A1), one type may be used, or two or more types of compounds may be used in combination.

In the component (A), the amount of the component (A1) based on the total weight of the component (A) is preferably 50% by weight or more, more preferably 80% by weight or more, and may even be 100% by weight.

However, it is preferable that the amount of the structural unit (a1) based on the combined total of structural units constituting the component (A) is adjusted to 20 to 80 mol %.

Further, it is preferable that the amount of the structural unit (a2) based on the combined total of structural units constituting the component (A) is adjusted to 20 to 80 mol %.

In the negative-tone development resist composition, the component (A) may contain “a base component which exhibits decreased solubility in an organic developing solution under action of acid” other than the component (A1) (hereafter, referred to as “component (A2)”).

The component (A2) is not particularly limited, and any of the multitude of conventional base components used within chemically amplified resist compositions for use in positive tone development process with an alkali developing solution (e.g., base resins used within chemically amplified resist compositions for ArF excimer lasers or KrF excimer lasers, preferably ArF excimer lasers) can be used. For example, as a base resin for ArF excimer laser, a base resin having the aforementioned structural unit (a1) as an essential component, and optionally at least one of the aforementioned structural units (a0), (a2) to (a4) can be used. Further, the component (A2) may contain a non-polymer (low molecular weight compound) having a molecular weight of 500 to less than 4,000.

As the component (A2), one type of resin may be used, or two or more types of resins may be used in combination.

<Component (B)>

The component (B) contains an acid generator (B1) which is at least one compound represented by general formula (b1) or (b2) shown below.

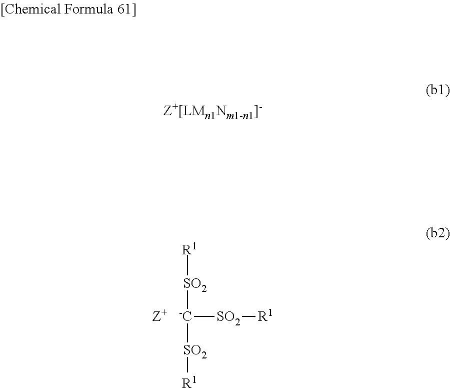

In the formula, L represents an antimony atom, a boron atom or a phosphor atom; M and N each independently represents a fluorine atom, a pentafluorophenyl group or a perfluoroalkyl group of 1 to 5 carbon atoms; when L represents an antimony atom or a boron atom, m1 is 6, and when L represents a phosphorous atom, m1 is 4; n1 represents an integer of 0 to m1; each R¹ independently represents an alkyl group of 1 to 10 carbon atoms having at least one hydrogen atom substituted with fluorine, provided that two R¹ may be mutually bonded to form a ring; and Z⁺ represents an organic cation.

The acid generator (B1) causes ring-opening polymerization of the structural unit (a2). By the ring-opening polymerization, a guide pattern exhibiting excellent heat resistance and solvent resistance can be formed.

In general formula (b1), L represents an antimony atom, a boron atom or a phosphorous atom, and M and N each independently represents a fluorine atom, a pentafluorophenyl group or a perfluoroalkyl group of 1 to 5 carbon atoms.

In the case where L represents an antimony atom, examples of the anion within general formula (b1) include SbF₆⁻, SbFₙ₁J₆₋ₙ₁⁻, SbFₙ₁(CₘF₂ₘ₊₁)₆₋ₙ₁⁻ and SbJₙ₁(CₘF₂ₘ₊₁)₆₋ₙ₁⁻. J represents a pentafluorophenyl group.

In the case where the anion within general formula (b1) is SbFₙ₁J₆₋₁⁻, n1 is preferably 0.

In the case where the anion within general formula (b1) is SbFₙ₁(CₘF₂ₘ₊₁)₆₋ₙ₁⁻, n1 is preferably 3, and m is preferably 2.

In the case where the anion within general formula (b1) is SbFₙ₁(CₘF₂ₘ₊₁)₆₋ₙ₁⁻, n1 is preferably 6, and when n1 is no more than 6, m is preferably 2.

In the case where L represents a phosphorus atom, examples of the anion within general formula (b1) include PF₆⁻, PFₙ₁J₆₋ₙ₁⁻, PFₙ₁(CₘF₂ₘ₊₁)₆₋ₙ₁⁻ and PJₙ₁(CₘF₂ₘ₊₁)⁶⁻ⁿ¹⁻. J represents a pentafluorophenyl group.

In the case where the anion within general formula (b1) is PFₙ₁J₆₋ₙ₁⁻, n1 is preferably 0.

In the case where the anion within general formula (b1) is PFₙ₁(CₘF₂ₘ₊₁)₆₋ₙ₁⁻, n1 is preferably 3, and m is preferably 2.

In the case where the anion within general formula (b1) is PJₙ₁(CₘF₂ₘ₊₁)₆₋ₙ₁⁻, n1 is preferably 6, and when n1 is no more than 5, m is preferably 2.

In the case where L represents a boron atom, examples of the anion within general formula (b1) include BF₄⁻, BFₙ₁J₄₋ₙ₁⁻, BFₙ₁(CₘF₂ₘ₊₁)₄₋ₙ₁⁻ and BJₙ₁(CₘF₂ₘ₊₁)₄₋ₙ₁⁻. J represents a pentafluorophenyl group.

In the case where the anion within general formula (b1) is BFₙ₁J₄₋ₙ₁⁻, n1 is preferably 0 to 2, and n1 is more preferably 0.

In the case where the anion within general formula (b1) is BFₙ₁(CₘF₂ₘ₊₁)₄₋ₙ₁⁻, n1 is preferably 3, and m is preferably 2.

In the case where the anion within general formula (b1) is BJₙ₁(CₘF₂ₘ₊₁)₄₋ₙ₁⁻, n1 is preferably 4, and when n1 is no more than 3, m is preferably 2.

In the aforementioned general formula (b1), Z⁺ represents an organic cation, and is not particularly limited. Examples thereof include an organic cation of a compound represented by general formula (5) shown below.

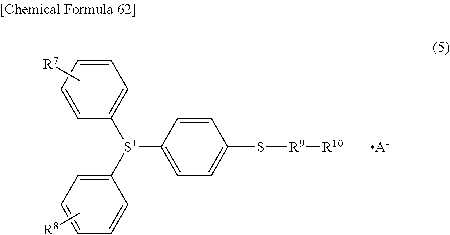

In general formula (5), R⁷ and R⁸ each independently represents a hydrogen atom, a halogen atom, a hydrocarbon group which may contain an oxygen atom or a halogen atom, or an alkoxy group which may have a substituent bonded thereto; R⁹ represents a p-phenylene group which may have one or more hydrogen atoms substituted with a halogen atom or an alkyl group; R¹⁰ represents a hydrogen atom, a hydrocarbon group which may contain an oxygen atom or a halogen atom, a benzoyl group which may have a substituent, or a polyphenyl group which may have a substituent; and A⁻ is represents the anion within the aforementioned general formula (b1).

Examples of compounds represented by the aforementioned general formula (b1) include 4-(2-chloro-4-benzoylphenylthio)phenyldiphenylsulfonium hexafluoroantimonate,
4-(2-chloro-4-benzoylphenylthio)phenylbis(4-fluorophenyl)sulfonium hexafluoroantimonate,
4-(2-chloro-4-benzoylphenylthio)phenylbis(4-chlorophenyl)sulfonium hexafluoroantimonate,
4-(2-chloro-4-benzoylphenylthio)phenylbis(4-methylphenyl)sulfonium hexafluoroantimonate,
4-(2-chloro-4-benzoylphenylthio)phenylbis(4-(β-hydroxyethoxy)phenyl)sulfonium hexafluoroantimonate,
4-(2-methyl-4-benzoylphenylthio)phenylbis(4-fluorophenyl)sulfonium hexafluoroantimonate,
4-(3-methyl-4-benzoylphenylthio)phenylbis(4-fluorophenyl)sulfonium hexafluoroantimonate,
4-(2-fluoro-4-benzoylphenylthio)phenylbis(4-fluorophenyl)sulfonium hexafluoroantimonate,
4-(2-methyl-4-benzoylphenylthio)phenylbis(4-fluorophenyl)sulfonium hexafluoroantimonate,
4-(2,3,5,6-tetramethyl-4-benzoylphenylthio)phenylbis(4-fluorophenyl)sulfonium hexafluoroantimonate,
4-(2,6-dichloro-4-benzoylphenylthio)phenylbis(4-fluorophenyl)sulfonium hexafluoroantimonate,
4-(2,6-dimethyl-4-benzoylphenylthio)phenylbis(4-fluorophenyl)sulfonium hexafluoroantimonate,
4-(2,3-dimethyl-4-benzoylphenylthio)phenylbis(4-fluorophenyl)sulfonium hexafluoroantimonate,
4-(2-methyl-4-benzoylphenylthio)phenylbis(4-chlorophenyl)sulfonium hexafluoroantimonate,
4-(3-methyl-4-benzoylphenylthio)phenylbis(4-chlorophenyl)sulfonium hexafluoroantimonate,
4-(2-fluoro-4-benzoylphenylthio)phenylbis(4-chlorophenyl)sulfonium hexafluoroantimonate,
4-(2-methyl-4-benzoylphenylthio)phenylbis(4-chlorophenyl)sulfonium hexafluoroantimonate,
4-(2,3,5,6-tetramethyl-4-benzoylphenylthio)phenylbis(4-chlorophenyl) hexafluoroantimonate,
4-(2,6-dichloro-4-benzoylphenylthio)phenylbis(4-chlorophenyl)sulfonium hexafluoro antimonate, 4-(2,6-dimethyl-4-benzoylphenylthio)phenylbis(4-chlorophenyl)sulfonium hexafluoroantimonate,
4-(2,3-dimethyl-4-benzoylphenylthio)phenylbis(4-chlorophenyl)sulfonium hexafluoroantimonate, 4-(2-chloro-4-acetylphenylthio)phenyldiphenylsulfonium hexafluoroantimonate,
4-(2-chloro-4-(4-methylbenzoyl)phenylthio)phenyldiphenylsulfonium hexafluoroantimonate,
4-(2-chloro-4-(4-fluorobenzoyl)phenylthio)phenyldiphenylsulfonium hexafluoroantimonate,
4-(2-chloro-4-(4-methoxybenzoyl)phenylthio)phenyl diphenyl sulfonium hexafluoroantimonate, 4-(2-chloro-4-dodecanoylphenylthio)phenyldiphenylsulfonium hexafluoroantimonate,
4-(2-chloro-4-acetylphenylthio)phenylbis(4-fluorophenyl)sulfonium hexafluoroantimonate,
4-(2-chloro-4-(4-methylbenzoyl)phenylthio)phenylbis(4-fluorophenyl)sulfonium hexafluoroantimonate,
4-(2-chloro-4-(4-fluorobenzoyl)phenylthio)phenylbis(4-fluorophenyl)sulfonium hexafluoroantimonate,
4-(2-chloro-4-(4-methoxybenzoyl)phenylthio)phenylbis(4-fluorophenyl)sulfonium hexafluoroantimonate,
4-(2-chloro-4-dodecanoylphenylthio)phenylbis(4-fluorophenyl)sulfonium hexafluoroantimonate,
4-(2-chloro-4-acetylphenylthio)phenylbis(4-chlorophenyl)sulfonium hexafluoroantimonate,
4-(2-chloro-4-(4-methylbenzoyl)phenylthio)phenylbis(4-chlorophenyl)sulfonium hexafluoroantimonate,
4-(2-chloro-4-(4-fluorobenzoyl)phenylthio)phenylbis(4-chlorophenyl)sulfonium hexafluoroantimonate,
4-(2-chloro-4-(4-methoxybenzoyl)phenylthio)phenylbis(4-chlorophenyl)sulfonium hexafluoroantimonate,
4-(2-chloro-4-dodecanoylphenylthio)phenylbis(4-chlorophenyl)sulfonium hexafluoroantimonate, 4-(2-chloro-4-benzoylphenylthio)phenyldiphenylsulfonium hexafluorophosphate, 4-(2-chloro-4-benzoylphenylthio)phenyl diphenyl sulfonium tetrafluoroborate, 4-(2-chloro-4-benzoylphenylthio)phenylbis(4-fluorophenyl)sulfonium hexafluorophosphate,
4-(2-chloro-4-benzoylphenylthio)phenylbis(4-fluorophenyl)sulfonium tetrafluoroborate,
4-(2-chloro-4-benzoylphenylthio)phenylbis(4-chlorophenyl)sulfonium hexafluorophosphate,
4-(2-chloro-4-benzoylphenylthio)phenylbis(4-chlorophenyl)sulfonium tetrafluoroborate, diphenyl[4-(phenylthio)phenyl]sulfonium trifluorotrispentafluoroethylphosphate, diphenyl[4-(p-ter-phenylthio)phenylsulfonium hexafluoroantimonate, diphenyl[4-(p-ter-phenylthio)phenylsulfonium trifluorotrispentafluoroethyl phosphate, and 4-methylphenyl[4-(1-methylethyl)phenyliodonium tetrakis(pentafluorophenyl)borate. Among these compounds, 4-(2-chloro-4-benzoylphenylthio)phenylbis(4-fluorophenyl)sulfonium hexafluoroantimonate (manufactured by ADEKA CORPORATION, Adekaoptomer SP-172), diphenyl[4-(phenylthio)phenyl]sulfonium trifluorotrispentafluoroethylphosphate (manufactured by SAN-APRO Ltd., CPI-210S), diphenyl[4-(p-ter-phenylthio)phenylsulfonium hexafluoroantimonate, diphenyl[4-(p-ter-phenylthio)phenylsulfonium trifluorotrispentafluoroethylphosphate (manufactured by SAN-APRO Ltd., HS-1PG), and 4-methylphenyl[4-(1-methylethyl)]phenyl iodonium tetrakis(pentafluorophenyl)borate (manufactured by Rhodia, PI-2074) are preferable.

Further, in the aforementioned general formula (b2), each R¹ independently represents an alkyl group of 1 to 10 carbon atoms in which at least one hydrogen atom has been substituted with a fluorine atom. The alkyl group has 1 to 10 carbon atoms, preferably 1 to 7 carbon atoms, and more preferably 1 to 3 carbon atoms.

Specific examples of the alkyl group include a linear alkyl group such as methyl, ethyl, propyl, butyl, pentyl or octyl; a branched alkyl group such as isopropyl, isobutyl, sec-butyl or tert-butyl; and a cycloalkyl group such as cyclopropyl, cyclobutyl, cyclopentyl or cyclohexyl. The proportion of the hydrogen atoms of the alkyl group substituted with fluorine is preferably 50% or more, more preferably 80% or more, and most preferably 100%.

With respect to a resist layer formed to contain such acid generator (B1), the sensitivity to active rays and radial rays depends on the substitution ratio of fluorine atoms rather than the number of carbon atoms of the alkyl group. When the substitution ratio is 50% or more, the effect of causing ring-open polymerization of the structural unit (a2) can be satisfactorily achieved, thereby maintaining the photosensitivity of the negative-tone development resist layer.

In particular, R¹ is preferably a linear or branched perfluoroalkyl group (i.e., an alkyl group substituted with fluorine at a substitution ratio of 100%) of 1 to 3 carbon atoms, and specific examples thereof include CF₃, CF₃CF₂, (CF₃)₂CF and CF₃CF₂CF₂. Among these examples, CF₃ group is most preferable. When R¹ is a CF₃ group which is strongly electron-withdrawing, the stability of the carbanion can be enhanced.

In the aforementioned general formula (b2), Z⁺ represents an organic cation, and is not particularly limited. Examples thereof include an organic cation of a compound represented by general formula (10) shown below.

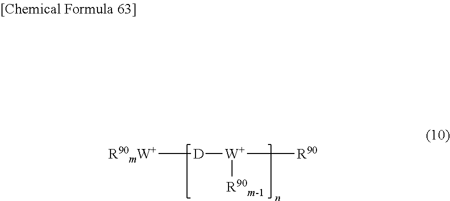

In general formula (10), W represents a sulfur atom, an iodine atom, a phosphorus atom, a carbon atom, a selenium atom or a nitrogen atom having a valency of m; and m represents 1 to 4. In particular, W is a sulfur atom or an iodine atom. In such a case, m is 1 or 2. n represents a repeating number of the structure within the bracket, and is an integer of 0 to 3. R⁹⁰ represents an organic group bonded to W, and is an aryl group of 6 to 30 carbon atoms, a heterocyclic group of 4 to 30 carbon atoms, an alkyl group of 1 to 30 carbon atoms, an alkenyl group of 2 to 30 carbon atoms or an alkynyl group of 2 to 30 carbon atoms. R⁹⁰ may be substituted with at least one member selected from the group consisting of an alkyl group, a hydroxy group, an alkoxy group, an alkylcarbonyl group, an aryl carbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, an alkyleneoxy group, an amino group, a cyano group, a nitro group and a halogen. The number of the R⁹⁰ groups is m+n(m−1)+1, and the plurality of R⁹⁰ may be the same or different from each other. Further, 2 or more R⁹⁰ groups may be directly bonded, or bonded via —O—, —S—, —SO—, —SO₂—, —NH—, —NR⁹¹—, —CO—, —COO—, —CONH—, an alkylene group of 1 to 3 carbon atoms or a phenylene group to W, so as to form a ring structure. R⁹¹ represents an alkyl group of 1 to 5 carbon atoms or an aryl group of 6 to 10 carbon atoms.

D is a structure represented by chemical formula (II) shown below.

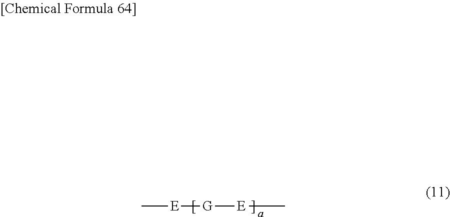

In chemical formula (II), E represents an alkylene group of 1 to 8 carbon atoms, an arylene group of 6 to 20 carbon atoms or a divalent group of a heterocyclic compound of 8 to 20 carbon atoms, and E may be substituted with at least one member selected from the group consisting of an alkyl group of 1 to 8 carbon atoms, an alkoxy group of 1 to 8 carbon atoms, an aryl group of 6 to 10 carbon atoms, a hydroxy group, a cyano group, a nitro group and a halogen. G represents —O—, —S—, —SO—, —SO₂—, —NH—, —NR⁹¹—, —CO—, —COO—, —CONH—, an alkylene group of 1 to 3 carbon atoms or a phenylene group. a represents an integer of 0 to 5. The a+1 of the E groups and the a of the G groups may be the same or different from each other. R⁹¹ is the same as defined above.

As the organic cation of the compound represented by general formula (b2), a iodonium or a sulfonium is particularly desirable. By using an iodonium or a sulfonium as the cation, the adhesiveness of the resist layer on the substrate is enhanced, and the resist layer can be suppressed from being dissolved by the developing solution, thereby enabling to form a finer resist pattern with high precision.

Specific examples of preferable onium ions which constitute the organic cation of the compound represented by general formula (b2) include triphenylsulfonium, tri-p-tolylsulfonium, 4-(phenylthio)phenyldiphenylsulfonium, bis[4-(diphenylsulfonio)phenyl]sulfide, bis[4-{bis[4-(2-hydroxyethoxy)phenyl]sulfonio}phenyl]sulfide, bis{4-[bis(4-fluorophenyl)sulfonio]phenyl}sulfide, 4-(4-benzoyl-2-chlorophenylthio)phenylbis(4-fluorophenyl)sulfonium, 4-(4-benzoylphenylthio)phenyldiphenylsulfonium, 7-isopropyl-9-oxo-10-thia-9,10-dihydroanthracene-2-yldi-p-tolylsulfonium, 7-isopropyl-9-oxo-10-thia-9,10-dihydroanthracene-2-yldiphenylsulfonium, 2-[(diphenyl)sulfonio]thioxanthone, 4-[4-(4-tert-butylbenzoyl)phenylthio]phenyldi-p-tolylsulfonium, 4-(4-benzoylphenylthio)phenyldiphenylsulfonium, diphenylphenacylsulfonium, 4-hydroxyphenylmethylbenzylsulfonium, 2-naphthylmethyl(1-ethoxycarbonyl)ethylsulfonium, 4-hydroxyphenylmethylphenacylsulfonium, octadecylmethylphenacylsulfonium, bis(4-tert-butylphenyl)iodonium, diphenyliodonium, di-p-tolyliodonium, bis(4-dodecylphenyl)iodonium, bis(4-methoxyphenyl)iodonium, (4-octyloxyphenyl)phenyliodonium, bis(4-decyloxy)phenyliodonium, 4-(2-hydroxytetradecyloxy)phenylphenyliodonium, 4-isopropylphenyl(p-tolyl)iodonium and 4-isobutylphenyl(p-tolyl)iodonium.

As the compound represented by general formula (b2), among the cation polymerization initiators (b) of the onium-type which satisfy the above requirements, compounds represented by chemical formulae (b4) and (b5) shown below are particularly desirable.

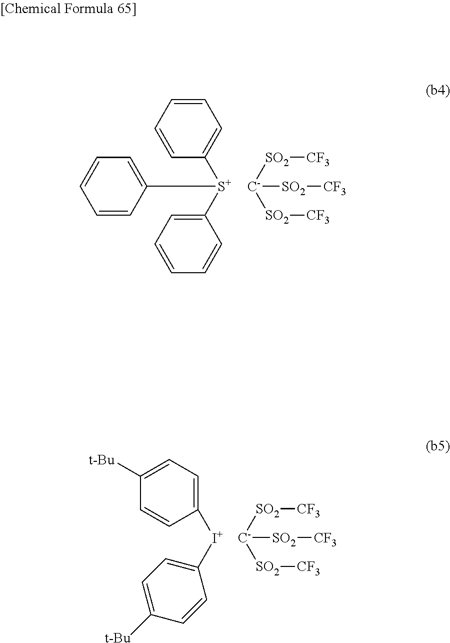

As the component (B), one type of compound may be used, or two or more types of compounds may be mixed together for use.

In the negative-tone development resist composition, the amount of the component (B1) based on the entire component (B) is preferably 5% by weight or more, still more preferably 60% by weight or more, and may be even 100% by weight.

When the amount of the component (B1) is at least as large as the lower limit of the above-mentioned range, the shape of the resist pattern becomes excellent. Further, in the negative-tone development resist composition, the amount of the component (B1), relative to 100 parts by weight of the component (A) is preferably 0.1 to 70 parts by weight, still more preferably 1 to 50 parts by weight, and most preferably 5 to 20 parts by weight.

In the component (B), an acid generator (B2) other than the component (B1) (hereafter, referred to as component (B2)) may be used in combination with the component (B1), as long as the properties of the component (B1) are not impaired.

As the component (B2), there is no particular limitation as long as it is other than the component (B1), and any of the known acid generators used in conventional chemically amplified resist compositions can be used.

### <Optional Components>

The negative-tone development resist composition of the present invention may contain a nitrogen-containing organic compound (D) (hereafter referred to as the component (D)) as an optional component.

As the component (D), there is no particular limitation as long as it functions as an acid diffusion control agent, i.e., a quencher which traps the acid generated from the component (B) upon exposure. A multitude of these components (D) have already been proposed, and any of these known compounds may be used.

In general, a low molecular weight compound (non-polymer) is used as the component (D). Examples of the component (D) include an aliphatic amine and an aromatic amine. Among these, an aliphatic amine is preferable, and a secondary aliphatic amine or tertiary aliphatic amine is particularly desirable. The term “aliphatic cyclic group” refers to a monocyclic group or polycyclic group that has no aromaticity. An aliphatic amine is an amine having one or more aliphatic groups, and the aliphatic groups preferably have 1 to 20 carbon atoms.

Examples of these aliphatic amines include amines in which at least one hydrogen atom of ammonia (NH₃) has been substituted with an alkyl group or hydroxyalkyl group of no more than 20 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, tri-n-octanolamine, stearyldiethanolamine and laurildiethanolamine. Among these, trialkylamines and/or alkylalcoholamines are preferable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine and tris[2-{2-(2-hydroxyethoxy)ethoxy}ethyl]amine.

Examples of aromatic amines include aniline, N,N-dibutylaniline, pyridine, 4-dimethylaminopyridine, pyrrole, indole, pyrazole, imidazole and derivatives thereof, as well as diphenylamine, triphenylamine, tribenzylamine, 2,6-diisopropylaniline, 2,2′-dipyridyl and 4,4′-dipyridyl.

These compounds can be used either alone, or in combinations of two or more different compounds.

The component (D) is typically used in an amount within a range from 0.01 to 5.0 parts by weight, relative to 100 parts by weight of the component (A). When the amount of the component (D) is within the above-mentioned range, the shape of the resist pattern and the post exposure stability of the latent image formed by the pattern-wise exposure of the resist layer are improved.

Furthermore, in the negative-tone development resist composition according to the present invention, for preventing any deterioration in sensitivity, and improving the resist pattern shape and the post exposure stability of the latent image formed by the pattern-wise exposure of the resist layer, at least one compound (E) (hereafter referred to as “component (E)”) selected from the group consisting of organic carboxylic acids and phosphorus oxo acids and derivatives thereof can be added.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid. Among these, phosphonic acid is particularly desirable.

Examples of phosphorus oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenylphosphonic acid, diphenyl phosphonate and dibenzyl phosphonate.

Examples of phosphinic acid derivatives include phosphinic acid esters such as phenylphosphinic acid.

As the component (E), one type may be used alone, or two or more types may be used in combination.

The component (E) is typically used in an amount within a range from 0.01 to 5.0 parts by weight, relative to 100 parts by weight of the component (A).

If desired, other miscible additives can also be added to the negative-tone development resist composition according to the present invention. Examples of such miscible additives include additive resins for improving the performance of the resist film, surfactants for improving the applicability, dissolution inhibitors, plasticizers, stabilizers, colorants, halation prevention agents, and dyes.

The negative-tone development resist composition according to the present invention can be prepared by dissolving the materials for the resist composition in an organic solvent (hereafter, sometimes referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone; ketones such as acetone, methyl ethyl ketone (MEK), cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene; and dimethylsulfoxide (DMSO).

These solvents can be used individually, or in combination as a mixed solvent.

Among these, PGMEA, PGME, γ-butyrolactone and EL are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2.

Specifically, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME weight ratio is preferably from 1:9 to 9:1, more preferably from 2:8 to 8:2, and still more preferably 3:7 to 7:3.

Further, as the component (S), a mixed solvent of at least one of PGMEA and EL with γ-butyrolactone is also preferable. The mixing ratio (former:latter) of such a mixed solvent is preferably from 70:30 to 95:5.

The amount of the component (S) is not particularly limited, and is appropriately adjusted to a concentration which enables coating of a coating solution to a substrate In general, the organic solvent is used in an amount such that the solid content of the resist composition becomes within the range from 1 to 20% by weight, and preferably from 2 to 15% by weight.

<Formation of Phase Separation Structure of the Layer Containing the Block Copolymer>

Firstly, a layer containing the block copolymer is formed on the surface of the substrate. More specifically, the block copolymer dissolved in a suitable organic solvent is applied to the surface of the substrate using a spinner or the like.

As the organic solvent for dissolving the block copolymer, any organic solvent which is capable of dissolving the block copolymer to be used and forming a uniform solution can be used, and an organic solvent having high compatibility with all of the polymers constituting the block copolymer can be used. As the organic solvent, one type of solvent can be used, or two or more types may be used in combination.

Examples of the organic solvent for dissolving the block copolymer include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene.

For example, when a PS-PMMA block copolymer is used as the block copolymer, it is preferable to dissolve the block copolymer in an aromatic organic solvent such as toluene.

The thickness of the layer containing the block copolymer which is formed on the surface of the substrate depends on the molecular weight of the block copolymer (polymer period). In general, application is conducted within the range of 0.5 to 4.0 times the polymer period.

In the present invention, the lower limit of the thickness of the layer containing the block copolymer is not particularly limited, as long as it is sufficient for causing phase separation. In consideration of the strength of the nanostructure and the uniformity of the substrate having the nanostructure formed, the thickness of the layer is preferably 3 nm or more, and more preferably 5 nm or more.

The substrate having the layer containing the block copolymer formed is subjected to a heat treatment, and a phase separation structure in which at least a part of the surface of the substrate is exposed is formed by a selective removal of the block copolymer in a later step. The heat treatment is preferably conducted at a temperature at least as high as the glass transition temperature of the block copolymer used and lower than the heat decomposition temperature. Further, the heat treatment is preferably conducted in a low reactive gas such as nitrogen.

<Selective Removal of Phase of Polymer P_{B} in Phase Separation Structure>

Subsequently, after the formation of the phase separation structure, the phase of polymer P_{B} exposed (13a in FIG. 1) is selectively removed from the layer containing the block copolymer formed on the substrate. As a result, only the phase of the polymer P_{A} (13b in FIG. 1) remains on the exposed surface of the substrate. Further, the phase of the polymer P_{B} which was continuously formed from the surface of the substrate to the surface of the layer containing the block copolymer is removed, so that the surface of the substrate is exposed.

The selective removal treatment is not particularly limited, as long as it is a treatment capable of decomposing and removing the polymer P_{B} without affecting the polymer P_{A}. The selective removal treatment can be appropriately selected from any methods for removing a resin film, depending on the types of the polymer P_{A} and the polymer P_{B}. Further, when a neutralization film is formed on the surface of the substrate in advance, the neutralization film is removed together with the phase of the polymer P_{B}. Furthermore, when a guide pattern is formed on the surface of the substrate in advance, like the polymer P_{A}, the guide pattern is not removed. Examples of the removal treatment include an oxygen plasma treatment, an ozone treatment, a UV irradiation treatment, a heat decomposition treatment and a chemical decomposition treatment.

As described above, according to the present invention, there can be produced a substrate provided with a nano structure on the substrate surface by using phase separation of a block copolymer, wherein the nanostructure is designed more freely with respect to the position and the orientation.

### EXAMPLES

As follows is a description of examples of the present invention, although the scope of the present invention is in no way limited by these examples.

In Tables 1 and 2, the monomers used in the synthesis of polymers 1 to 12, the compositional ratio (unit:mol %) of the monomers and the molecular weight of the synthesized monomers are indicated. Resist compositions of Examples 1 to 9 and Comparative Examples 1 to 7 were prepared in accordance with the formulations shown in Tables 4 and 5 (unit:part by weight). In the resist compositions of Examples 1 to 9 and Comparative Examples 1 to 7, as the solvent, 2,500 to 3,000 parts by weight of propyleneglycol monomethylether acetate (PGMEA) was used.

With respect to the monomers indicated in Tables 1 and 2, the details are shown in Table 3.

In Tables 4 and 5, the photoacid generators are as follows.

HS-1PG: Diphenyl[4-(p-ter-phenylthio)phenyl]sulfonium trifluorotrispentafluoroethylphosphate (manufactured by San-Apro Ltd.)

SP-172: 4-(2-chloro-4-benzoylphenylthio)phenylbis(4-fluorophenyl)sulfonium hexafluoroantimonate (manufactued by ADEKA Corporation)

PI-2074: 4-methylphenyl[4-(1-methylethyl)phenyliodonium tetrakis(pentafluorophenyl)borate (manufactued by Rhodia)

CGT TPS C1: Triphenylsulfonium tris[(trifluoromethyl)sulfonyl]methane (manufactured by BASF Corp.)

PAG 103: [2-(propylsulfonyloxyimino)-2,3-dihydrothiophene-3-ylidene](o-tolyl)acetonitrile (manufactured by Ciba Specialty Chemicals)

ZK-0138: Dinaphthylphenylsulfonium perfluorobutylsulfate (manufactured by Dainippon Sumitomo Pharma Co., Ltd.)

In Tables 1 and 2, ANSM indicates a compound represented by formula (III) shown below.

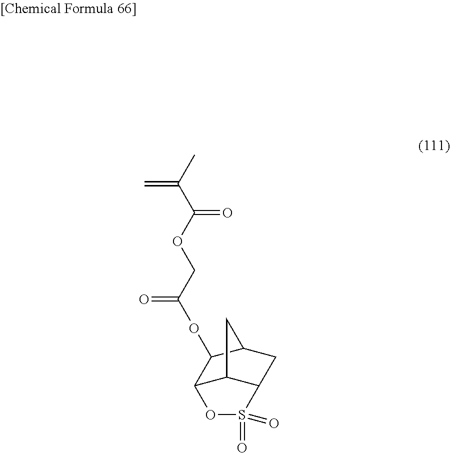 [SMILES: C=C(C)C(=O)OCC(=O)OC1C2CC3C1OS(=O)(=O)C3C2]

TABLE 1

| | | Polymer 1 | Polymer 2 | Polymer 3 | Polymer 4 | Polymer 5 | Polymer 6 |
|---|---|---|---|---|---|---|---|
| Composition of | G lactone | 40 | | | | | |
| synthesized | HAMβ | | 50 | | | | |
| polymer | GMA | | | 50 | | | 10 |
| | GCMA | | | | 50 | | |
| | M100 | | | | | 50 | 10 |
| | N lactone | | | | | | 30 |
| | To lactone | | | | | | |
| | 1-ethylcyclohexyl methacrylate | | 50 | 30 | 25 | 40 | 40 |
| | 2-methyl-2-adamantyl | 40 | | | 25 | | |
| | methacrylate | | | | | | |
| | 2-isopropyl-2-adamantyl | | | 20 | | | |
| | methacrylate | | | | | | |
| | ANSM | | | | | 10 | |
| | 3-hydroxy-1-adamantyl | 20 | | | | | |
| | methacrylate | | | | | | |
| | Tricyclodecane methacrylate | | | | | | 10 |

| | | | | | | |
|---|---|---|---|---|---|---|
| Mw | 10000 | 10000 | 10000 | 10000 | 10000 | 10000 |

TABLE 2

| | | Polymer 7 | Polymer 8 | Polymer 9 | Polymer 10 | Polymer 11 | Polymer 12 |
|---|---|---|---|---|---|---|---|
| Composition of | G lactone | | 100 | | | | |
| synthesized | HAMβ | | | | | | |
| polymer | GMA | | | | | | |
| | GCMA | | | | | | |
| | M100 | 20 | | | | 50 | |
| | N lactone | | | | | | |
| | To lactone | 30 | | | | | |
| | 1-ethylcyclohexyl methacrylate | 40 | | | 50 | | |
| | 2-methyl-2-adamantyl | | | 100 | | | |
| | methacrylate | | | | | | |
| | 2-isopropyl-2-adamantyl | | | | | | |
| | methacrylate | | | | | | |
| | ANSM | | | | 30 | 30 | |
| | 3-hydroxy-1-adamantyl | 10 | | | 20 | 10 | 100 |
| | methacrylate | | | | | | |
| | Tricyclodecane methacrylate | | | | | 10 | |

| | | | | | | |
|---|---|---|---|---|---|---|
| Mw | 10000 | 10000 | 10000 | 10000 | 10000 | 10000 |

TABLE 3

| OSAKA ORGANIC | | | OSAKA ORGANIC | | Maruzen | |
|---|---|---|---|---|---|---|
| CHEMICAL | CHISSO | Tokyo Chemical | CHEMICAL | Daicel Chemical | Petrochemical | Mitsubishi Rayon |
| INDUSTRY LTD | CORPORATION | Industry Co., Ltd. | INDUSTRY LTD | Industries, Ltd. | Co., Ltd. | Co., Ltd. |
| G lactone | HAMβ | GMA | GCMA | M100 | N lactone | To lactone |
| 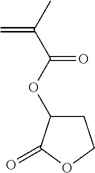 | 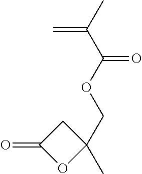 | 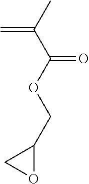 | 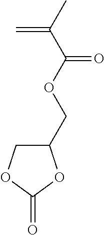 | 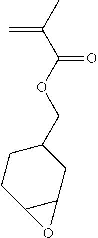 | 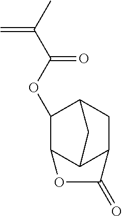 [SMILES: C=C(C)C(=O)OC1C2CC3C(=O)OC1C3C2] | 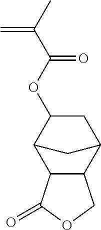 [SMILES: C=C(C)C(=O)OC1CC2CC1C1C(=O)OCC21] |

TABLE 4

| | | Example 1 | Example 2 | Example 3 | Example 4 | Example 5 | Example 6 | Example 7 | Example 8 | Example 9 |
|---|---|---|---|---|---|---|---|---|---|---|
| Synthesized | Polymer 1 | 100 | 100 | 100 | | | | | | |
| polymer | Polymer 2 | | | | 100 | | | | | |
| | Polymer 3 | | | | | 100 | | | | |
| | Polymer 4 | | | | | | 100 | | | |
| | Polymer 5 | | | | | | | 100 | | |
| | Polymer 6 | | | | | | | | 100 | |
| | Polymer 7 | | | | | | | | | 100 |
| | Polymer 8 | | | | | | | | | |
| | Polymer 9 | | | | | | | | | |
| | Polymer 10 | | | | | | | | | |
| | Polymer 11 | | | | | | | | | |
| | Polymer 12 | | | | | | | | | |
| Photoacid | HS-1PG | 10 | 10 | | | | 10 | 10 | 10 | 10 |
| generator | SP-172 | | | 10 | | | | | | |
| | PI-2074 | | | | 10 | | | | | |
| | CGI TPS C1 | | | | | 10 | | | | |
| | PAG103 | | | | | | | | | |
| | ZK-0138 | | | | | | | | | |
| Amine | Tri-n-pentylamine | | 0.2 | | | | | | | |
| Acid | Salicylic acid | | 0.3 | | | | | | | |
| Evaluation results | Insolubility in THF | A | A | A | A | A | A | A | A | A |
| | (1% solution) | | | | | | | | | |
| | 200 nm space | A | A | A | A | A | A | A | A | A |
| | resolution | | | | | | | | | |
| | 200° C. heat resistance | A | A | A | A | A | A | A | A | A |
| | Perpendicular lamellar | A | A | A | A | A | A | A | A | A |

TABLE 5

| | | Comparative | Comparative | Comparative | Comparative | Comparative | Comparative | Comparative |
|---|---|---|---|---|---|---|---|---|
| | | Example 1 | Example 2 | Example 3 | Example 4 | Example 5 | Example 6 | Example 7 |
| Synthesized | Polymer 1 | | | | | | 100 | 100 |
| polymer | Polymer 2 | | | | | | | |
| | Polymer 3 | | | | | | | |
| | Polymer 4 | | | | | | | |
| | Polymer 5 | | | | | | | |
| | Polymer 6 | | | | | | | |
| | Polymer 7 | | | | | | | |
| | Polymer 8 | 100 | | | | | | |
| | Polymer 9 | | 100 | | | | | |
| | Polymer 10 | | | 100 | | | | |
| | Polymer 11 | | | | 100 | | | |
| | Polymer 12 | | | | | 100 | | |
| Photoacid | HS-1PG | 10 | 10 | 10 | 10 | 10 | | |
| generator | SP-172 | | | | | | | |
| | PI-2074 | | | | | | | |
| | CGI TPS C1 | | | | | | | |
| | PAG103 | | | | | | 10 | |
| | ZK-0138 | | | | | | | 10 |
| Amine | Tri-n-pentylamine | | | | | | | |
| Acid | Salicylic acid | | | | | | | |
| Evaluation results | Insolubility in | A | B | B | A | B | B | B |
| | THF (1% | | | | | | | |
| | solution) | | | | | | | |
| | 200 nm space | B | B | A | B | B | A | A |
| | resolution | | | | | | | |
| | 200° C. heat | — | — | B | — | — | B | B |
| | resistance | | | | | | | |
| | Perpendicular | — | — | B | — | — | B | B |
| | lamellar | | | | | | | |

[Evaluation of Guide Pattern Formability (Line/Space Resolution)]

A surface treatment composition (a copolymer of styrene/3,4-epoxycyclohexylmethane methacrylate/trimethoxysilane methacrylate=35/60/5 having a molecular weight of 40,000) adjusted to a concentration of 3 to 5% was spin-coated on an 8-inch silicon substrate by adjusting the number of rotation to obtain a film thickness of 10 nm, followed by a bake treatment at 250° C. for 10 minutes.

Subsequently, the resist composition prepared above was spin-coated on the 8-inch silicon substrate by adjusting the number of rotation to obtain a film thickness of 150 nm, followed by a bake treatment at 110° C. for 60 seconds.

Using an ArF exposure apparatus NSR-S302 (manufactured by Nikon Corporation, NA (numerical aperture)=0.60, 2/3 annular illumination), the resist film was exposed with a 200 nm line/space pattern. Thereafter, a PEB treatment was conducted at 110° C. for 60 seconds, followed by a paddle development using butyl acetate.

A resist composition with which a 200 nm line/space was observed to be formed was evaluated “A”, and a resist composition with which a 200 nm line/space was observed to be not formed was evaluated “B”. The results are indicated in Tables 4 and 5 under [200 nm space resolution].

[Evaluation of Solvent Resistance]

A 1% THF solution was applied to the line/space pattern formed in the above [Evaluation of guide pattern formability (line/space resolution)]. A pattern which was not dissolved was evaluated “A”, and a pattern which was dissolved was evaluated “B”. The results are indicated in Tables 4 and 5 under [THF insoluble (1% solution)]. With respect to the examples in which a line/space pattern was not formed in the above [Evaluation of guide pattern formability (line/space resolution)], the result is indicated “-”.

[Evaluation of Heat Resistance]

A substrate on which a line/space pattern was formed in the above [Evaluation of guide pattern formability (line/space resolution)] was placed on a hot plate at 200° C. A pattern which did not suffer flow was evaluated “A”, and a pattern which suffered flow was evaluated “B”. The results are indicated in Tables 4 and 5 under [200° C. heat resistance]. With respect to the examples in which a line/space pattern was not formed in the above [Evaluation of guide pattern formability (line/space resolution)], the result is indicated “-”.

[Evaluation of Perpendicular Lamellar Formability]

On a substrate having a line/space pattern formed in the above [Evaluation of guide pattern formability (line/space resolution)], a toulene solution (17.5 mg/ml) of a PS-PMMA block copolymer 1 (manufactured by Polymer Source Inc.; molecular weight of PS: 53,000; molecular weight of PMMA: 54,000; polydispersity index (PDI): 1.16) was spin-coated (number of rotation: 1,000 rpm, 60 seconds), followed by drying with heat at 110° C. for 60 seconds.

Subsequently, the substrate was heated at 200° C. for 6 hours while flowing nitrogen, thereby forming a phase-separated structure. Thereafter, using TCA-3822 (product name; manufactured by Tokyo Ohka Kogyo Co., Ltd.), the substrate was subjected to an oxygen plasma treatment (200 sccm, 40 Pa, 200 W, 30 seconds), thereby selectively removing the phase constituted of PMMA. The surface of the obtained substrate was observed using a scanning electron microscope SEMS4700 (manufactured by Hitachi, Ltd.). A resin composition in which a perpendicular lamellar was observed was evaluated “A”, and a resin composition in which a perpendicular lamellar was not observed was evaluated “B”. The results are indicated in Tables 4 and 5 under [perpendicular lamellar]. With respect to the examples in which a line/space pattern was not formed in the above [Evaluation of guide pattern formability (line/space resolution)], the result is indicated “-”.

From the results shown above, it is apparent that, by using the negative-tone development resist composition of the present invention, a guide pattern having excellent solvent resistance and heat resistance can be formed.

### INDUSTRIAL APPLICABILITY

According to the present invention, there can be produced a substrate provided with a nano structure on the substrate surface by using phase separation of a block copolymer, wherein the nanostructure is designed more freely with respect to the position and the orientation. Therefore, the present invention is extremely useful in industry.

### BRIEF DESCRIPTION OF THE DRAWINGS

11: substrate, 12: layer of undercoat agent, 14: guide pattern, 13: layer containing block copolymer, 13a: Phase constituted of polymer P_{B}, 13b: Phase constituted of polymer P_{A}

1. A negative tone-development resist composition for forming a guide pattern usable in a phase separation of a layer containing a block copolymer having a plurality of polymers bonded formed on a substrate, the negative tone-development resist composition comprising:
a base component (A) which exhibits increased polarity by action of acid, and decreased solubility in a developing solution containing an organic solvent, and
an acid-generator component (B) which generates acid upon exposure,
the base component (A) comprising a resin component (A1) comprising:
a structural unit (a1) derived from an acrylate ester which contains an acid dissociable group and which may have an atom or a substituent other than hydrogen bonded to the carbon atom on the α-position, and
at least one structural unit (a2) selected from the group consisting of a structural unit (a2-i) derived from an acrylate ester which contains a 4- to 12-membered, lactone-containing cyclic group and which may have an atom or a substituent other than hydrogen bonded to the carbon atom on the α-position, a structural unit a structural unit (a2-ii) derived from an acrylate ester which contains a 3- to 7-membered, ether-containing cyclic group and which may have an atom or a substituent other than hydrogen bonded to the carbon atom on the α-position, and a structural unit (a2-iii) derived from an acrylate ester which contains a 5- to 7-membered, carbonate-containing cyclic group and which may have an atom or a substituent other than hydrogen bonded to the carbon atom on the α-position, and
the acid generator-component (B) comprising an acid generator (B1) comprising at least one compound represented by general formula (b1) or (b2) shown below: 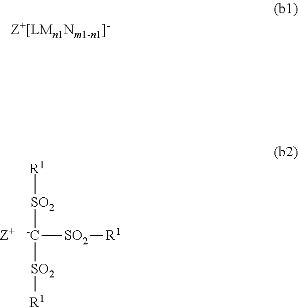
wherein L represents an antimony atom, a boron atom or a phosphor atom; M and N each independently represents a fluorine atom, a pentafluorophenyl group or a perfluoroalkyl group of 1 to 5 carbon atoms; when L represents an antimony atom or a boron atom, m1 is 6, and when L represents a phosphorous atom, m1 is 4; n1 represents an integer of 0 to m1; each R¹ independently represents an alkyl group of 1 to 10 carbon atoms having at least one hydrogen atom substituted with fluorine, provided that two R¹ may be mutually bonded to form a ring; and Z⁺ represents an organic cation.

2. The negative tone-development resist composition for forming a guide pattern according to claim 1, wherein the amount of the structural unit (a1) based on the combined total of all structural units constituting the base component (A) is 20 to 80 mol %.

3. The negative tone-development resist composition for forming a guide pattern according to claim 1, wherein the amount of the structural unit (a2) based on the combined total of all structural units constituting the base component (A) is 20 to 80 mol %.

4. The negative tone-development resist composition for forming a guide pattern according to claim 1, wherein the resin component (A1) further comprises a structural unit (a0) derived from an acrylate ester containing an —SO₂— containing cyclic group which may have an atom or a substituent other than hydrogen bonded to the carbon atom on the α-position.

5. The negative tone-development resist composition for forming a guide pattern according to claim 1, wherein the resin component (A1) further comprises a structural unit (a3) derived from an acrylate ester containing a polar group-containing aliphatic hydrocarbon group which may have an atom or a substituent other than hydrogen bonded to the carbon atom on the α-position.

6. A method of forming a guide pattern, comprising:
using a negative-tone development resist composition for forming a guide pattern according to claim 1 to form a resist film on a substrate;
exposing the resist film; and
developing the resist film using a developing solution containing the organic solvent to form a guide pattern.

7. A method of forming a pattern of a layer containing a block copolymer, the method comprising:
applying an undercoat agent to a substrate to form a layer of the undercoat agent;
using a negative-tone development resist composition for forming a guide pattern according to claim 1 to form a resist film on a surface of the layer of the undercoat agent;
exposing the resist film;
developing the resist film using a developing solution containing the organic solvent to form a guide pattern;
forming a layer containing a block copolymer having a plurality of polymers bonded on a surface of the layer of the undercoat agent having the guide pattern formed thereon, followed by subjecting the layer containing the block copolymer to phase separation;
and selectively removing a phase of at least one polymer of the plurality of copolymers constituting the block copolymer.

8. The negative tone-development resist composition for forming a guide pattern according to claim 1, wherein the acid generator (B1) comprises a compound represented by general formula (5) shown below: 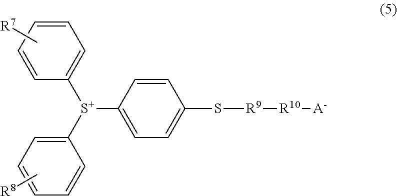
wherein R⁷ and R⁸ each independently represents a hydrogen atom, a halogen atom, a hydrocarbon group which may contain an oxygen atom or a halogen atom, or an alkoxy group which may have a substituent bonded thereto; R⁹ represents a p-phenylene group which may have one or more hydrogen atoms substituted with a halogen atom or an alkyl group; R¹⁹ represents a hydrogen atom, a hydrocarbon group which may contain an oxygen atom or a halogen atom, a benzoyl group which may have a substituent, or a polyphenyl group which may have a substituent; and A⁻ represents the anion [LMₙ₁Nₘ₁₋ₙ₁]⁻ within general formula (b1).

9. The negative tone-development resist composition for forming a guide pattern according to claim 1, wherein the acid generator (B1) comprises a compound represented by general formula (b2), and Z⁺ represents an organic cation represented by general formula (10) shown below: 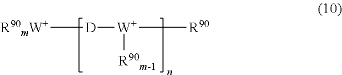
wherein W represents a sulfur atom, an iodine atom, a phosphorus atom, a carbon atom, a selenium atom or a nitrogen atom having a valency of m; m represents 1 to 4; n represents an integer of 0 to 3; R⁹⁰ represents an aryl group of 6 to 30 carbon atoms, a heterocyclic group of 4 to 30 carbon atoms, an alkyl group of 1 to 30 carbon atoms, an alkenyl group of 2 to 30 carbon atoms or an alkynyl group of 2 to 30 carbon atoms, provided that R⁹⁰ may be substituted with at least one member selected from the group consisting of an alkyl group, a hydroxy group, an alkoxy group, an alkylcarbonyl group, an aryl carbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, an alkyleneoxy group, an amino group, a cyano group, a nitro group and a halogen; and D is a structure represented by chemical formula (II) shown below: 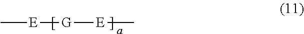
wherein E represents an alkylene group of 1 to 8 carbon atoms, an arylene group of 6 to 20 carbon atoms or a divalent group of a heterocyclic compound of 8 to 20 carbon atoms, and E may be substituted with at least one member selected from the group consisting of an alkyl group of 1 to 8 carbon atoms, an alkoxy group of 1 to 8 carbon atoms, an aryl group of 6 to 10 carbon atoms, a hydroxy group, a cyano group, a nitro group and a halogen; G represents —O—, —S—, —SO—, —SO₂—, —NH—, —NR⁹¹—, —CO—, —COO—, —CONH—, an alkylene group of 1 to 3 carbon atoms or a phenylene group; a represents an integer of 0 to 5; and R⁹¹ represents an alkyl group of 1 to 5 carbon atoms or an aryl group of 6 to 10 carbon atoms.

10. The negative tone-development resist composition for forming a guide pattern according to claim 1, wherein the structural unit (a2-i) comprises at least one member selected from the group consisting of structural units represented by general formulae (a2-0) to (a2-5) shown below: 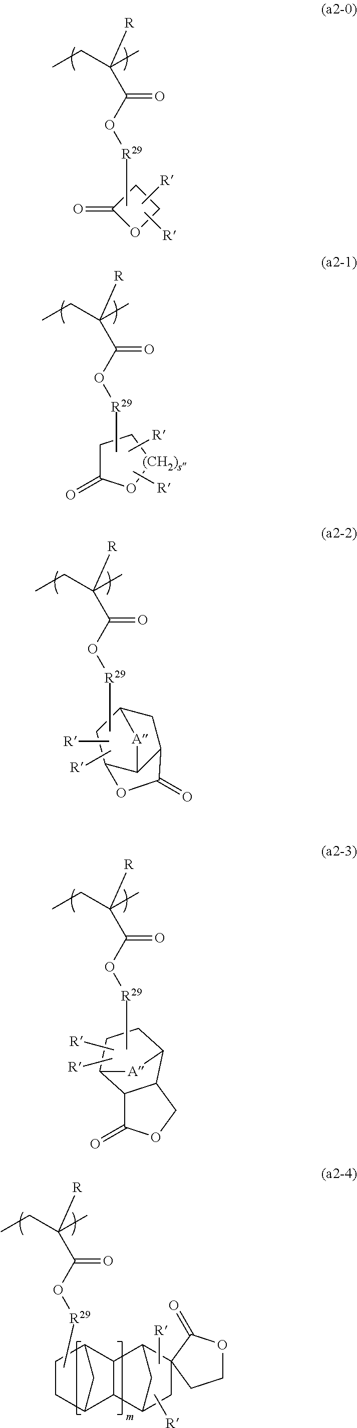 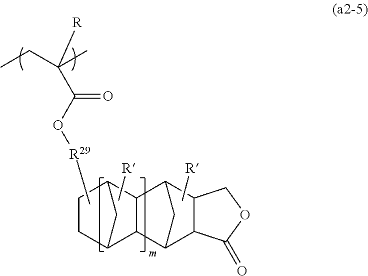
wherein R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, a halogenated alkyl group of 1 to 5 carbon atoms, a cyano group, a hydroxy group, an alkoxy group of 1 to 5 carbon atoms or —COOR″; R²⁹ represents a single bond or a divalent linking group; s″ represents an integer of 0 to 2; A″ represents an oxygen atom, a sulfur atom or an alkylene group of 1 to 5 carbon atoms which may contain an oxygen atom or a sulfur atom; and m represents 0 or 1.

11. The negative tone-development resist composition for forming a guide pattern according to claim 1, wherein the structural unit (a2-ii) comprises at least one member selected from the group consisting of structural units represented by general formulae (g2-1) to (g2-5) shown below: 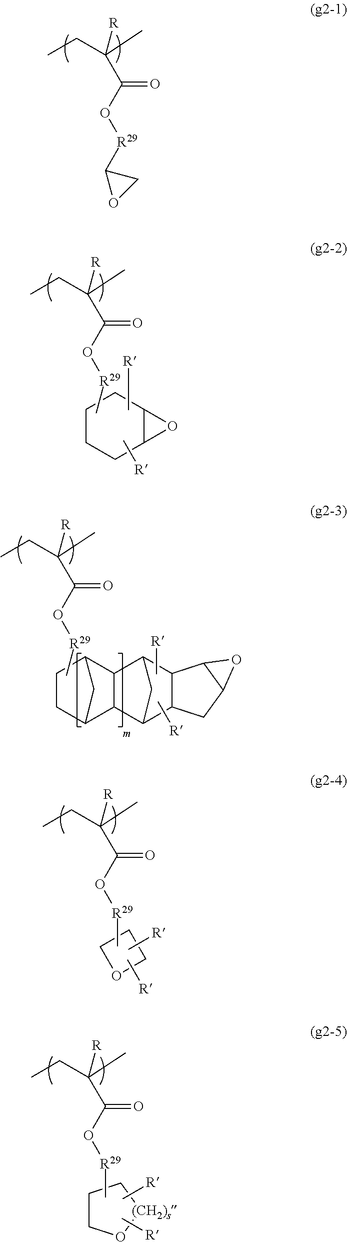
wherein R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, a halogenated alkyl group of 1 to 5 carbon atoms, a cyano group, a hydroxy group, an alkoxy group of 1 to 5 carbon atoms or —COOR″; R″ represents a hydrogen atom or a linear, branched or cyclic alkyl group of 1 to 15 carbon atoms; R²⁹ represents a single bond or a divalent linking group; s″ represents an integer of 0 to 2; and m represents 0 or 1.

12. The negative tone-development resist composition for forming a guide pattern according to claim 1, wherein the structural unit (a2-iii) comprises at least one member selected from the group consisting of structural units represented by general formula (g3-1) shown below: 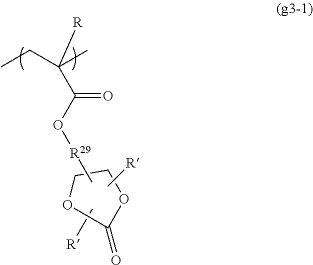
wherein R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, a halogenated alkyl group of 1 to 5 carbon atoms, a cyano group, a hydroxy group, an alkoxy group of 1 to 5 carbon atoms or —COOR″; and R²⁹ represents a single bond or a divalent linking group; s″ represents an integer of 0 to 2.

13. The negative tone-development resist composition for forming a guide pattern according to claim 4, wherein the structural unit (a0) contains an —SO₂— containing cyclic group represented by any one of general formulae (3-1) to (3-4) shown below: 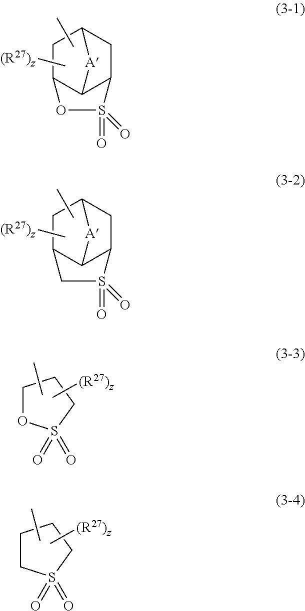
wherein A′ represents an oxygen atom, a sulfur atom or an alkylene group of 1 to 5 carbon atoms which may contain an oxygen atom or a sulfur atom; z represents an integer of 0 to 2; and R²⁷ represents an alkyl group, an alkoxy group, a halogenated alkyl group, a hydroxyl group, —COOR″, —OC(═O)R″, a hydroxyalkyl group or a cyano group, wherein R″ represents a hydrogen atom or an alkyl group.

14. The negative tone-development resist composition for forming a guide pattern according to claim 4, wherein the structural unit (a0) is represented by general formula (a0-0) shown below: 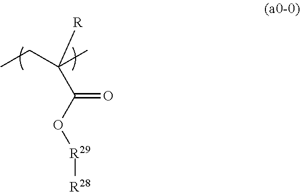
wherein R represents a hydrogen atom, an alkyl group of 1 to 5 carbon atoms or a halogenated alkyl group of 1 to 5 carbon atoms; R²⁸ represents a —SO₂— containing cyclic group; and R²⁹ represents a single bond or a divalent linking group.

15. The negative tone-development resist composition for forming a guide pattern according to claim 14, wherein the structural unit (a0) is represented by general formula (a0-0-1) shown below: 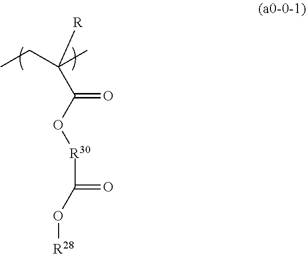
wherein R represents a hydrogen atom, an alkyl group of 1 to 5 carbon atoms or a halogenated alkyl group of 1 to 5 carbon atoms; R²⁸ represents a —SO₂— containing cyclic group; and R³⁰ represents a divalent linking group.

16. The negative tone-development resist composition for forming a guide pattern according to claim 1, wherein the resin component (A1) comprises at least one member selected from the group consisting of copolymers represented by general formulae (A1-11) to (A1-17) shown below: 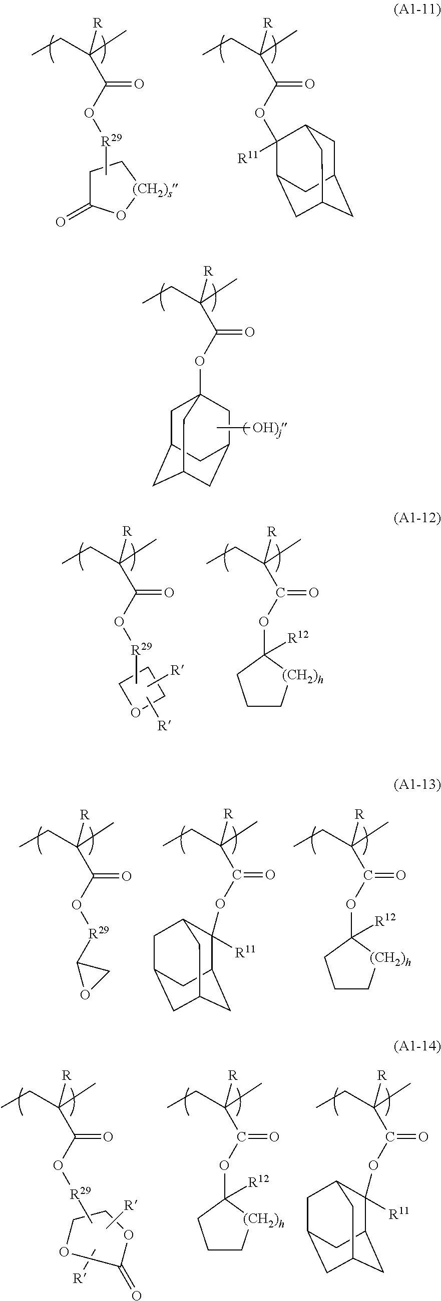 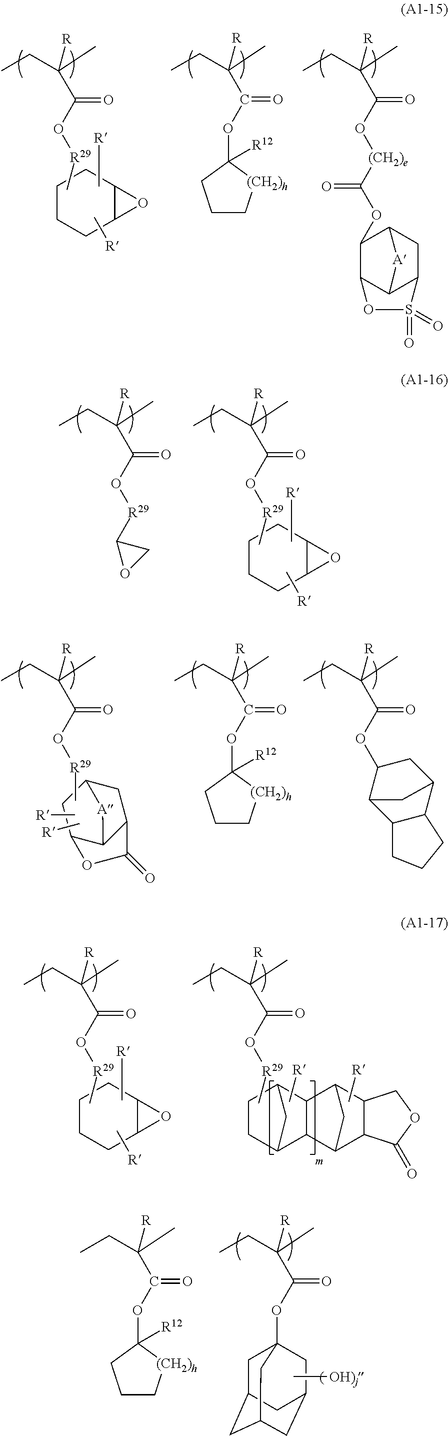
wherein each R independently represents a hydrogen atom, an alkyl group of 1 to 5 carbon atoms or a halogenated alkyl group of 1 to 5 carbon atoms; R¹¹ represents an alkyl group of 1 to 5 carbon atoms; R²⁹ represents a single bond or a divalent linking group; s″ represents an integer of 0 to 2; s″ represents an integer of 0 to 2; j″ represents an integer of 1 to 3; each R′ independently represents a hydrogen atom, an alkyl group of 1 to 5 carbon atoms, a halogenated alkyl group of 1 to 5 carbon atoms, a cyano group, a hydroxy group, an alkoxy group of 1 to 5 carbon atoms or —COOR″; R″ represents a hydrogen atom or a linear, branched or cyclic alkyl group of 1 to 15 carbon atoms; R¹² represents an alkyl group of 1 to 5 carbon atoms; h represents an integer of 1 to 6; A′ represents an oxygen atom, a sulfur atom or an alkylene group of 1 to 5 carbon atoms which may contain an oxygen atom or a sulfur atom; and e represents an integer of 1 to 3.
